(19) United States
(12) Patent Application Publication
(10) Pub. No.: US 2026/0125404 A1
(43) Pub. Date: May 7, 2026

(54) HIGH PURITY MONOORGANO TIN COMPOUNDS AND METHODS FOR PREPARATION THEREOF

(71) Applicants: Gelest, Inc., Morrisville, PA (US); Mitsubishi Chemical Corporation, Tokyo (JP)

(72) Inventors: Li YANG, Belle Mead, NJ (US); Christopher Michael Caroff, Yardley, PA (US); Yuta Hioki, Tokyo (JP); Noriaki Kiya, Kitakyushu-shi (JP); Koki Ishii, Tokyo (JP); Thao Nguyen, Fairless Hills, PA (US)

(21) Appl. No.: 19/437,117

(22) Filed: Dec. 30, 2025

Related U.S. Application Data
(62) Division of application No. 18/934,327, filed on Nov. 1, 2024.
(60) Provisional application No. 63/599,038, filed on Nov. 15, 2023.
(60) Provisional application No. 63/603,833, filed on Nov. 29, 2023.
(60) Provisional application No. 63/604,355, filed on Nov. 30, 2023.

(30) Foreign Application Priority Data
Sep. 27, 2024 (JP) 2024-169096

(51) Int. Cl. C07F 7/22

(52) U.S. Cl. CPC C07F 7/2284

(57) ABSTRACT

Monoorgano tin compounds having chemical formula R′SnX₃ and high purity are described. R′ is an optionally substituted hydrocarbyl group, X is selected from NR₂ and OR, and each R is independently a linear or branched alkyl group having about 1 to about 10 carbon atoms. Methods for synthesizing and purifying these compounds are also provided. The monoorgano tin compounds may be used for the formation of high-resolution EUV lithography patterning precursors and are attractive due to their high purity and minimal concentration of diorgano tin impurities.

### CROSS-REFERENCE TO RELATED APPLICATIONS

This application claims priority to U.S. provisional application No. 63/599,038, filed Nov. 15, 2023; U.S. provisional application No. 63/603,833, filed Nov. 29, 2023; U.S. provisional application No. 63/604,355, filed Nov. 30, 2023; and Japanese application number 2024-169096, filed Sep. 27, 2024, the disclosures of which are herein incorporated by reference in their entireties.

### BACKGROUND OF THE INVENTION

In recent years, with a paradigm shift toward an advanced information society, there is a demand for handling a larger amount of information at a higher speed and with higher accuracy. Therefore, technologies related to semiconductor devices such as integrated circuits using semiconductors have been rapidly advancing.

The evolution of semiconductor design requires the formation of features on a semiconductor substrate material that are finer than ever before, and the individual features have a size of about 22 nanometers (nm) or less and may have a size of less than 10 nm in some cases. One of the problems in producing devices having such fine features is the ability to reliably and reproducibly form a photolithography mask having a sufficient resolution. In order to realize a feature size smaller than the wavelength of light, it is necessary to use a complicated high-resolution technology such as multi-patterning. Therefore, the development of a photolithography technology using light having a shorter wavelength, such as extreme ultraviolet radiation (EUV) having a wavelength of 10 nm to 15 nm (for example, 13.5 nm), is important.

In recent years, liquid chemical vapor deposition (CVD) materials such as organotin compounds have been used, particularly as resists for EUV application, and thus, extremely high purity materials are required in order to improve the quality of film formation. The synthesis of tin compounds containing one organic group (hereinafter, also referred to as “monoalkyl tin compounds”) that are preferably used among the class of organotin compounds has been reported (see, for example, PCT International Publication No. WO 2019/199467, PCT International Publication No. WO 2022/165088, U.S. Patent Application Publication No. 2023/0391804, and Hanssgen et al. (Journal of Organometallic Chemistry, 293(2), 191-5 (1985)).

As semiconductor fabrication continues to advance, feature sizes continue to shrink, driving the need for new processing methods. Certain organotin compounds have been shown to be useful in the deposition of tin oxide hydroxide coatings in applications such as extreme ultraviolet (EUV) lithography techniques. For example, tin compounds containing small hydrocarbon rings (such as those containing 3-5 ring atoms), small aromatic rings (such as those containing 5-6 ring atoms), and/or ether substituents provide radiation sensitive Sn—C bonds that can be used to pattern structures lithographically.

Materials used in microelectronic fabrication are required to be extremely pure with tight limits placed on organic contamination (e.g., reaction by-products), metallic contamination, and particulate contamination. Purity requirements are stringent in general, and particularly for lithography applications because the chemical is in contact with the semiconductor substrates and the organometallic impurities in compounds such as diisopropylbis(dimethylamino)tin, (iPr)₂Sn(NMe₂)₂, can affect the properties of the resultant film. Exact targets for purities are determined by a variety of factors, including performance metrics, but typical minimum purity targets are 3N+. Residual metals present in the chemicals can be deposited onto the semiconductor substrate and degrade the electrical performance of the device being fabricated. Typical specifications for metals are less than 10 ppb for individual metals and total metal not to exceed ˜100 ppb.

The processing and performance of semiconductor materials may also be sensitive to dialkyl tin contaminants. Dialkyl tin impurities such as R₂Sn(NMe₂)₂, where R is an alkyl group, are the source of off-gassing after vapor phase deposition or spin-on coating processes due to the oxostannate cluster films being less dense when the film contains dialkyl groups. To produce microelectronic products using EUV lithography, proper control of dialkyl tin contaminants is required. The high purity required from the mono-alkyl tin precursor manufacturing process becomes a challenge. In general, the syntheses of monoalkyl tin triamides have previously employed lithium dimethylamide reagents reacted with alkyl tin trichloride, or followed by a lithium/Grignard reagent (alkylating agent) to convert the tin tetraamides to the desired triamides.

However, similar synthetic methods are not applicable for the synthesis of tin compounds containing ether substituents, aromatic substituents, or small hydrocarbon rings (such as 3- to 5-membered rings) due to instability resulting from carbon ring strain, low C—Sn bond energy, or decomposition to impurities (R′₂SnX₂ or SnX₄) by fast Kocheshkov comproportionation. Especially when the carbon bonds to Sn is a tertiary carbon, the problem is more significant.

Graf (“Tin, Tin Alloys, and Tin Compounds,” Ullmann's Encyclopedia of Industrial Chemistry; Weinheim: Wiley-VCH (2005)) reports the preparation of monoorgano tin trichlorides using Kocheshkov comproportionation and the electron donating group promotes the comproportionation. As a result, the electron donating group from small hydrocarbon rings such as those containing 3, 4, or 5 ring atoms may promote the Kocheshkov-like comproportionation during the reaction especially when preparing mono-alkyl tin compounds according to scheme (I), shown below, and the disproportion during purification scheme (II), resulting in a mixture of products.

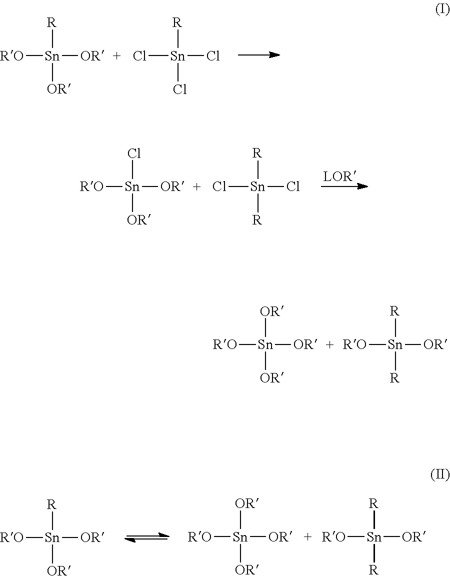

The preparation of alkyl groups can be also divided into two groups. In one case, the alkyl group contains a primary and/or a secondary moiety. For example, methyl tris(dimethylamino)tin, (MeSn(NMe₂)₃), and isopropyl tris(dimethylamino)tin, (iPrSn(NMe₂)₃), can be synthesized using dimethylamide and alkyl tin trichloride (amination) according to the method of Lorberth (Journal of Organometallic Chemistry, 16(2), 235-48 (1969)), scheme (III). In a second case, the alkyl group contains a tertiary alkyl moiety. For example, tert-butyl tris(dimethylamino)tin, (t-BuSn(NMe₂)₃), must be synthesized using an alkylating reagent to convert tin tetraamides by controlling the stoichiometry according to the method reported in Hanssgen, scheme (IV).

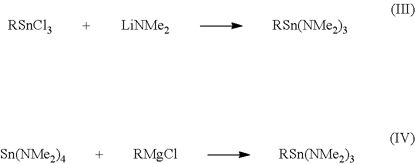

It is notable that primary and secondary monoalkyl tin triamide compounds cannot be synthesized from alkylating reagent and tetraamide because a primary alkylating reagent will convert tin tetraamides to trialkyltin amides and unreacted tetraamides, even when using the correct stoichiometry. Secondary alkylating reagents will also convert tin tetraamides to polyalkyl tin compounds.

In addition to the tertiary alkyl group, in the example of t-BuSnCl₃, Hanssgen also reports that t-BuSnCl₃ decomposes rapidly at room temperature yielding SnCl₂ and t-BuCl. Therefore, tertiary monoalkyl tin compounds cannot be prepared using lithium dimethylamides and alkyl tin trichloride.

The description above is only a general concept. Continuing work with organotin compounds has showed that primary and secondary RSnCl₃ compounds are also very unstable and the synthesis strategies described above are not applicable. To overcome the synthesis capability, a few synthetic routes to organotin triamides and organotin trialkoxides compositions have been discovered.

A method to prepare monoalkyltin triamide and monoalkyltin trialkoxides reported by Jaumier et al. (Chem. Commun., 369-370 (1998)) synthesizes monoorganotin alkoxides from trialkynylorganotins. The preparation of trialkynylorganotins by transmetallation of tetraalkynyltin compounds with Grignard reagents is also reported by Jaumier et al. (Angew. Chem. Int. Ed., 38, No. 3, 402-404 (1999)). The mothed reported by Jaumier is limited to primary or secondary alcohols because the tertiary alcohols were not acidic enough to be useful. Further, a monoalkyltin triamide can be prepared from the reaction of monoalkyltin trialkoxides with trimethylsilyl amide (see U.S. Patent Publication No 2022/0242889).

In these known methods, the monoalkyltin triamide can be prepared from the reaction of monoalkyltin trialkoxides with lithium amide, in which the reaction yield is not limited by removing by-product as a rate limited state. The overall reaction is illustrated below.

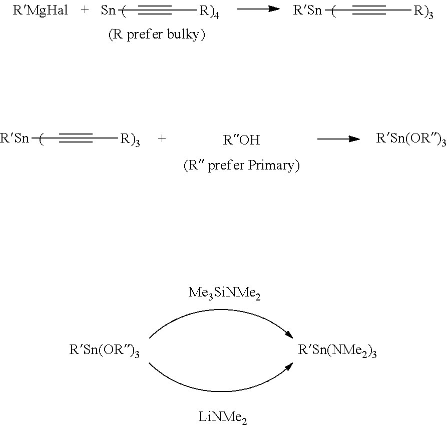

In addition, methods for preparing monoalkyltin triamides and monoalkyltin trialkoxides based on oxidative addition reaction of organic halides to tin amides are described in Lappert et al (Journal of Organometallic Chemistry, 330, 31-46 (1987)). Further conversion by subsequent reaction of the intermediate with a metal alkoxide in alcohol forms a monoalkyltin trialkoxide composition. In this case, the metal alkoxide is mostly limited to a primary alcohol due to the acidity and steric affect. The monoalkyltin triamide may be prepared from the reaction of monoalkyltin trialkoxides with trimethylsilyl amide or lithium amide as previously described, scheme (V).

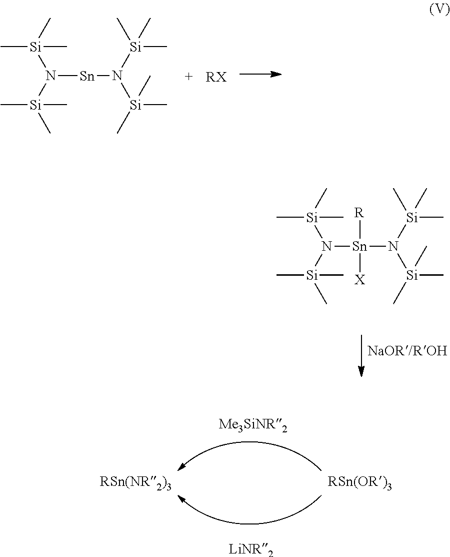

The ability to prepare and isolate monoalkyl tin compounds, including those containing alkyl groups, cyclic substituent groups, aromatic substituents, or ether substituents and having desired high purity levels has not previously been reported. Such high purity tin compounds would be very attractive for use in the microelectronic industry.

### SUMMARY OF THE INVENTION

In one embodiment, aspects of the disclosure relate to a monoorgano tin compound having formula (1) having a purity of at least about 95 mol % and containing less than about 5 mol % of a diorgano tin compound having formula (2):

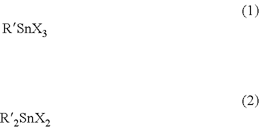

wherein R′ has formula [I] or [II], and X is selected from NR₂ and OR, wherein each R is independently a linear or branched alkyl group having about 1 to about 10 carbon atoms which is optionally substituted with one or more halogen atoms;
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)nOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.

In a second embodiment, aspects of the disclosure relate to a monoorgano tin compound having formula (1′) having a purity of at least about 95 mol % and containing less than about 5 mol % of a diorgano tin compound having formula (2′) and less than about 5 mol % of a compound having formula (5′):

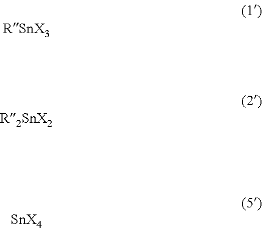

wherein R″ has formula [III], and X is selected from NR₂ and OR, wherein each R is independently a linear or branched alkyl group having about 1 to about 10 carbon atoms which is optionally substituted with one or more halogen atoms;
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20.

In a further embodiment, aspects of disclosure relate to a method of synthesizing a monoorgano tin compound having formula (1) having a purity of at least about 95 mol % and containing less than about 5 mol % of a diorgano tin compound having formula (2):

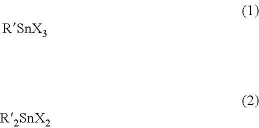

wherein R′ has formula [I] or [II], and X is selected from NR₂ and OR, wherein each R is independently a linear or branched alkyl group having about 1 to about 10 carbon atoms which is optionally substituted with one or more halogen atoms, the method comprising reacting a compound containing an R′ group with a compound having formula SnX₄;
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)nOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.

In a further embodiment, aspects of the disclosure relate to a method of synthesizing a monoorgano tin compound having formula (1′) having a purity of at least about 95 mol % and containing less than about 5 mol % of a diorgano tin compound having formula (2′) and less than about 5 mol % of a compound having formula (5′):

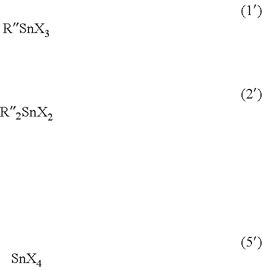

wherein R″ has formula [III], and X is selected from NR₂ and OR, wherein each R is independently a linear or branched alkyl group having about 1 to about 10 carbon atoms which is optionally substituted with one or more halogen atoms, the method comprising reacting a compound containing an R′ group with a compound having formula SnX₄;
[III]3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20.

In a further embodiment, aspects of the disclosure relate to a method of synthesizing a monoorgano tin compound having formula (1) having a purity of at least about 95 mol % and containing less than about 5 mol % of a diorgano tin compound having formula (2):

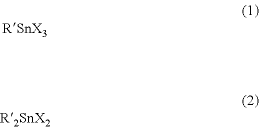

wherein R′ has formula [I] or [II], and X is selected from NR₂ and OR, wherein each R is independently a linear or branched alkyl group having about 1 to about 10 carbon atoms which is optionally substituted with one or more halogen atoms, the method comprising reacting a compound containing an OR or NR₂ group with a compound having formula R′SnY3, where Y is a reactive ligand;
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)nOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.

In a further embodiment, aspects of the disclosure relate to a method of synthesizing a monoorgano tin compound having formula (1′) having a purity of at least about 95 mol % and containing less than about 5 mol % of a diorgano tin compound having formula (2′) and less than about 5 mol % of a compound having formula (5′):

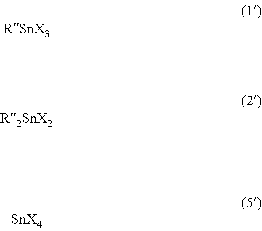

wherein R″ has formula [III], and X is selected from NR₂ and OR, wherein each R is independently a linear or branched alkyl group having about 1 to about 10 carbon atoms which is optionally substituted with one or more halogen atoms, the method comprising reacting a compound containing an OR or NR₂ group with a compound having formula R″SnY₃, where Y is a reactive ligand;
[III]3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20.

Aspects of the disclosure further relates to a method of synthesizing a monoorgano tin compound having formula (1) having a purity of at least about 95 mol % and containing less than about 5 mol % of a diorgano tin compound having formula (2):

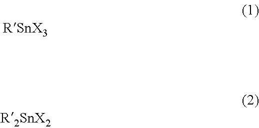

wherein R′ has formula [I] or [II], and X is selected from NR₂ and OR, wherein each R is independently a linear or branched alkyl group having about 1 to about 10 carbon atoms which is optionally substituted with one or more halogen atoms, the method comprising reacting a compound containing an OR or NR₂ group with a compound having formula R′SnY₃, where Y is a reactive ligand, the method comprising: (a) reacting a metal compound comprising an alkali metal M and a ligand X with a compound having formula SnY₂ to form a compound having formula MSnX₃; and (b) reacting the compound having formula MSnX₃ with a compound R′Z, wherein Z is a halogen atom and Y is a reactive ligand;
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)nOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.

Aspects of the disclosure further relate to a method of synthesizing a monoorgano tin compound having formula (1′) having a purity of at least about 95 mol % and containing less than about 5 mol % of a diorgano tin compound having formula (2′) and less than about 5 mol % of a compound having formula (5′):

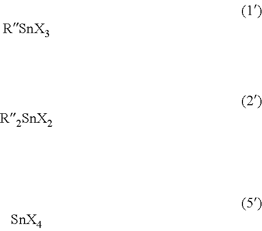

wherein R″ has formula [III], and X is selected from NR₂ and OR, wherein each R is independently a linear or branched alkyl group having about 1 to about 10 carbon atoms which is optionally substituted with one or more halogen atoms, the method comprising: (a) reacting a metal compound comprising an alkali metal M and a ligand X with a compound having formula SnY₂ to form a compound having formula MSnX₃; and (b) reacting the compound having formula MSnX₃ with a compound R″Z, wherein Z is a halogen atom and Y is a reactive ligand;
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20.

Further aspects of the disclosure relate to an organotin compound having formula (6):

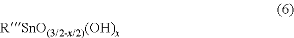

wherein 0<x≤3 and R″′ has formula [I], [II], or [III];
[I] CRaRbRc, wherein Ra is an aromatic ring having about 3 to about 10 carbon atoms which optionally contains and/or is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms, and X is selected from NR₂ and OR, wherein each R is independently a linear or branched alkyl group having about 1 to about 10 carbon atoms which is optionally substituted with one or more halogen atoms;
[II] CR^{A}R^{B}R^{C}, wherein R^{A} is (CH₂)nOR^{E}, n is 0, 1, or 2, R^{E} is a saturate hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage;
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″′ is about 2 to about 20.

Additional aspects of the disclosure relate to a composition comprising an organotin compound having formula (6) and an organotin compound having formula (7):

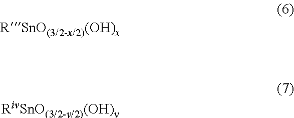

wherein 0<x≤3, 0<y≤3, R″′ has formula [I], [II], or [III], and R^{iv} is an optionally substituted hydrocarbon group having about 2 to about 20 carbon atoms which is different from R″′;
[I] CRaRbRc, wherein Ra is an aromatic ring having about 3 to about 10 carbon atoms which optionally contains and/or is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms, and X is selected from NR₂ and OR, wherein each R is independently a linear or branched alkyl group having about 1 to about 10 carbon atoms which is optionally substituted with one or more halogen atoms;
[II] CR^{A}R^{B}R^{C}, wherein R^{A} is (CH₂)nOR^{E}, n is 0, 1, or 2, R^{E} is a saturate hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage;
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″′ is about 2 to about 20.

Additional aspects of the disclosure relate to a method for producing a monoalkyltin triamide having formula (11) by reacting an alkylmagnesium reagent having formula (8) or (9) with a tin tetraamide represented by formula (10) in the presence of a first solvent containing an ether solvent having a boiling point of at least 40° C., and distilling off the ether solvent in the presence of a second solvent having an octanol/water partition coefficient greater than the ether solvent and greater than 1.0:

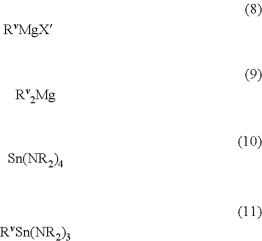

wherein R^{v} is a hydrocarbon group having 1 to 30 carbon atoms which in optionally substituted with one or more oxygen atoms, nitrogen atoms, silicon atoms, or sulfur atoms, each R is a linear or branched alkyl group having about 1 to 10 carbon atoms which is optionally substituted with one or more halogen atoms, and multiple Rs may be bonded to each other to form a cyclic structure, and X′ is chlorine, bromine, or iodine.

Further aspects of the disclosure relate to a method for a producing monoorgano tin trialkoxide compound having formula (1″′), comprising:
i) reacting a tetraalkynyl tin compound having formula (14) with a magnesium reagent having formula (8′); and
ii) reacting the product of step i) with an alcohol having formula (15):

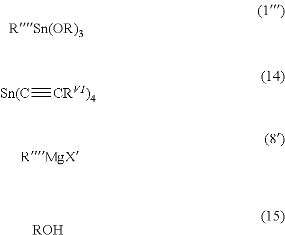

wherein each R is each independently a linear or branched alkyl group having about 1 to about 10 carbon atoms and each R^{VI} is independently a linear or branched alkyl group having about 1 to about 10 carbon atoms, or an aryl group having about 6 to 10 carbon atoms, X′ is chlorine, bromine, or iodine, and R″″ is a hydrocarbon group having about 1 to 30 carbon atoms which may contain one or more oxygen atoms, nitrogen atoms, silicon atoms, or sulfur atoms.

Additional aspects of the disclosure relate to a method for producing a monoorgano tin trialkoxide compound having formula (1″′), comprising:
i) reacting a bis[bis(trialkylsilylamino)]tin(II) compound having formula (17) with a hydrocarbyl halide compound having formula (18); and
ii) reacting the product of step i) with an alkali metal alkoxide having formula (15′) and an alcohol having formula (15):

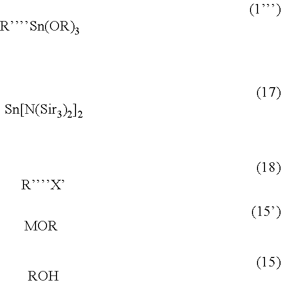

wherein each R is independently a linear or branched alkyl group having about 1 to about 10 carbon atoms, X′ is chlorine, bromine, or iodine, M is an alkali metal, and R″″ is a hydrocarbon group having about 1 to 30 carbon atoms which may contain one or more oxygen atoms, nitrogen atoms, silicon atoms, or sulfur atoms.

Advantageous refinements of the invention, which can be implemented alone or in combination, are specified in the dependent claims.

In summary, the following embodiments are proposed as particularly preferred in the scope of the present invention:

Embodiment A1: A monoorgano tin compound having formula (1) having a purity of at least about 95 mol % and containing less than about 5 mol % of a diorgano tin compound having formula (2):

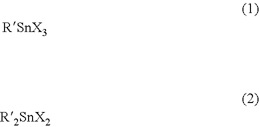

wherein R′ has formula [I]: CRaRbRc, wherein Ra is an aromatic ring having about 3 to about 10 carbon atoms which optionally contains and/or is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms, and X is selected from NR₂ and OR, wherein each R is independently a linear or branched alkyl group having about 1 to about 10 carbon atoms which is optionally substituted with one or more halogen atoms.

Embodiment A2: The monoorgano tin compound according to Embodiment A1, wherein a content of a compound having formula (3) is less than about 5 mol %:

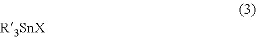

Embodiment A3: The monoorgano tin compound according to Embodiment A1 or A2, wherein a content of a compound having formula (4) is less than about 5 mol %:

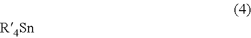

Embodiment A4: The monoorgano tin compound according to any of Embodiments A1-A3, wherein a content of a compound having formula (5) is less than about 5 mol %:

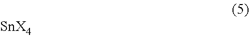

Embodiment A5: The monoorgano tin compound according to any of Embodiments A1-A4, wherein R′ is selected from the group consisting of:

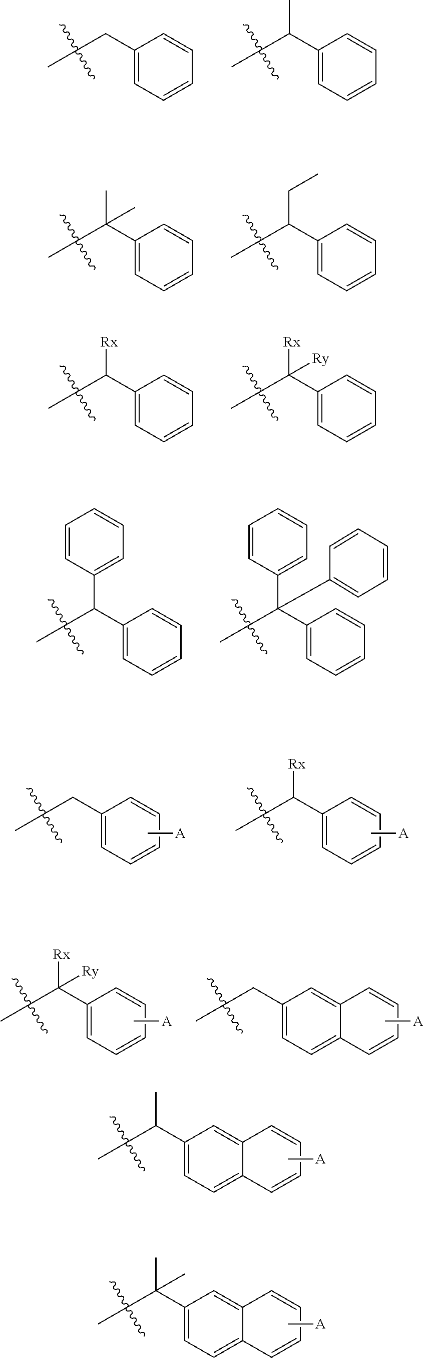

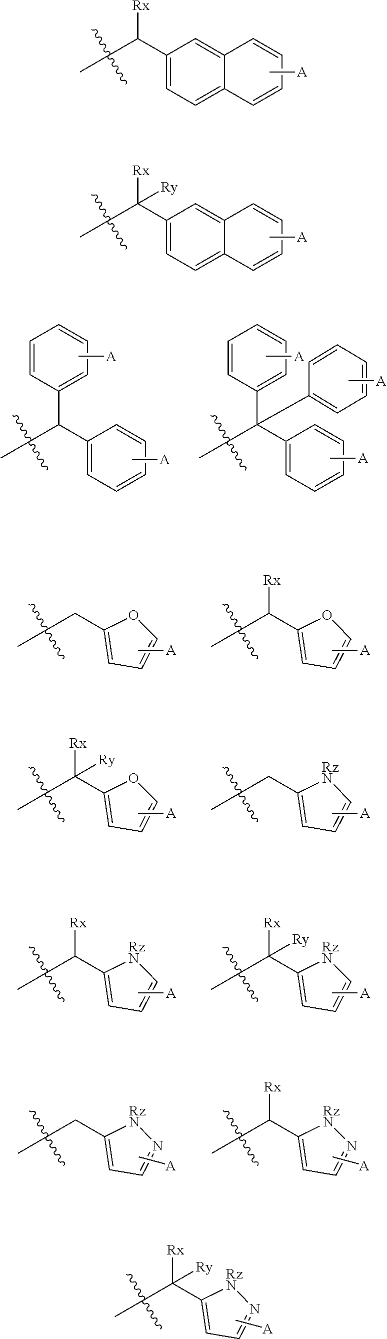

wherein each A substituent is independently hydrogen, a halogen, or a hydrocarbyl substituent having about 1 to about 5 carbon atoms which is optionally substituted with one or more oxygen, halogen, or nitrogen atoms; and wherein Rx, Ry, and Rz are each independently hydrogen or a hydrocarbyl substituent having about 1 to about 5 carbon atoms which is optionally substituted with one or more oxygen or nitrogen atoms.

Embodiment A6: The monoorgano tin compound according to any of Embodiments A1-A5, wherein the carbon atom in R′ bonded to tin is a secondary or tertiary carbon.

Embodiment A7: The monoorgano tin compound according to any of Embodiments A1-A6, wherein R′ contains a phenyl group.

Embodiment A8: The monoorgano tin compound according to any of Embodiments A1-A7, wherein X═NMe₂.

Embodiment A9: A method of synthesizing a monoorgano tin compound having formula (1) having a purity of at least about 95 mol % and containing less than about 5 mol % of a diorgano tin compound having formula (2):

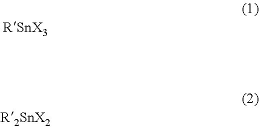

wherein R′ has formula [I]: CRaRbRc, wherein Ra is an aromatic ring having about 3 to about 10 carbon atoms which optionally contains and/or is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms, and X is selected from NR₂ and OR, wherein each R is independently a linear or branched alkyl group having about 1 to about 10 carbon atoms which is optionally substituted with one or more halogen atoms, the method comprising reacting a compound containing an R′ group with a compound having formula SnX₄.

Embodiment A10: The method according to Embodiment A9, wherein the compound containing an R′ group is a compound having formula R′MgZ, wherein Z is a halogen atom.

Embodiment A11: The method according to Embodiment A9 or A10, wherein Y is selected from a halogen atom, NR₂, and OR.

Embodiment A12: A method of synthesizing a monoorgano tin compound having formula (1) having a purity of at least about 95 mol % and containing less than about 5 mol % of a diorgano tin compound having formula (2):

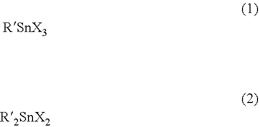

wherein R′ has formula [I]: CRaRbRc wherein Ra is an aromatic ring having about 3 to about 10 carbon atoms which optionally contains and/or is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms, and X is selected from NR₂ and OR, wherein each R is independently a linear or branched alkyl group having about 1 to about 10 carbon atoms which is optionally substituted with one or more halogen atoms, the method comprising reacting a compound containing an OR or NR₂ group with a compound having formula R′SnY₃, where Y is a reactive ligand.

Embodiment A13: The method according to Embodiment A12, wherein Y is a halogen atom, NR₂, or OR.

Embodiment A14: The method according to Embodiment A12 or A13, wherein R′SnY₃ is prepared by reacting R′₄Sn with SnY₄.

Embodiment A15: A method of synthesizing a monoorgano tin compound having formula (1) having a purity of at least about 95 mol % and containing less than about 5 mol % of a diorgano tin compound having formula (2):

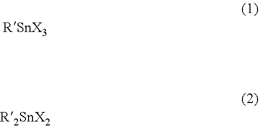

wherein R′ has formula [I]: CRaRbRc wherein Ra is an aromatic ring having about 3 to about 10 carbon atoms which optionally contains and/or is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms, and X is selected from NR₂ and OR, wherein each R is independently a linear or branched alkyl group having about 1 to about 10 carbon atoms which is optionally substituted with one or more halogen atoms, the method comprising: (a) reacting a metal compound comprising an alkali metal M and a ligand X with a compound having formula SnY₂ to form a compound having formula MSnX₃; and (b) reacting the compound having formula MSnX₃ with a compound R′Z, wherein Z is a halogen atom and Y is a reactive ligand.

Embodiment A16: The method according to Embodiment A15, wherein Y is a halogen atom, NR₂ or OR.

Embodiment A17: The method according to any of Embodiments A9-A16, wherein the reaction is performed in a solvent containing greater than about 50% by volume of a hydrocarbon solvent and/or an aromatic solvent.

Embodiment A18: The method according to Embodiment A17, wherein the solvent is dehydrated prior to performing the reaction.

Embodiment A19: The method according to any of Embodiment A9-A18, further comprising at least one purification step substantially without light exposure.

Embodiment A20: The method according to Embodiment A19, wherein the at least one purification step comprises fractional distillation.

Embodiment A21: The method according to any of Embodiments A9-A20, wherein the reaction is performed substantially without light exposure.

Embodiment A22: A method of storing a sample of the monoorgano tin compound having formula (1) according to any of Embodiments A1 to A8, the method comprising storing the sample of the monoorgano tin compound having formula (1) substantively without light exposure and at a temperature of less than about 30° C.

Embodiment A23: The method according to Embodiment A22, wherein the sample of the monoorgano tin compound having formula (1) is stored for about three days to about one year.

Embodiment A24: The method according to Embodiment A22 or A23, wherein the sample of the monoorgano tin compound undergoes substantively no decomposition after a storage time of about three days to about one year.

Embodiment A25: The method according to any of Embodiments A22-A24, comprising storing the compound having formula (1) in a container in an inert atmosphere.

Embodiment A26: The method according to any of Embodiments A22-A25, comprising storing the compound having formula (1) in a container substantially without light exposure.

Embodiment A27: An organotin compound having formula (6′):

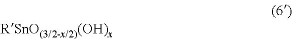

wherein 0<x≤3, wherein R′ has formula [I]: CRaRbRc and wherein Ra is an aromatic ring having about 3 to about 10 carbon atoms which optionally contains and/or is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms, and X is selected from NR₂ and OR, wherein each R is independently a linear or branched alkyl group having about 1 to about 10 carbon atoms which is optionally substituted with one or more halogen atoms.

Embodiment A28: The organotin compound having formula (6′) according to Embodiment A27, wherein the compound having formula (6′) is obtained by hydrolysis of a compound having formula (1):

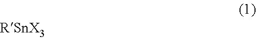

wherein X is selected from NR₂ and OR, and wherein each R is independently a linear or branched alkyl group having about 1 to about 10 carbon atoms.

Embodiment A29: A solution comprising the organotin compound having formula (6′) according to Embodiment A27 and an organic solvent.

Embodiment A30: The solution according to Embodiment A29, wherein the compound having formula (6′) is obtained by hydrolysis of a compound having formula (1):

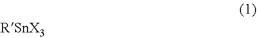

wherein X is selected from NR₂ and OR, and wherein each R is independently a linear or branched alkyl group having about 1 to about 10 carbon atoms.

Embodiment A31: A film comprising the organotin compound having formula (6′) according to Embodiment A27.

Embodiment A32: The film according to Embodiment A31, wherein the compound having formula (6′) is obtained by hydrolysis of a compound having formula (1):

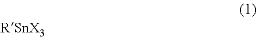

wherein X is selected from NR₂ and OR, and wherein each R is independently a linear or branched alkyl group having about 1 to about 10 carbon atoms.

Embodiment A33: A composition comprising the monoorgano tin compound having formula (1) according to any of Embodiments A1-A8 and a R^{iv}SnY₃ compound, wherein Y is a reactive ligand selected from a halogen atom, NR₂, and OR and R^{iv} is an optionally substituted hydrocarbon group having about 2 to 20 carbon atoms which is different from R′.

Embodiment A34: A composition comprising an organotin compound having formula (6′) and an organotin compound having formula (7′):

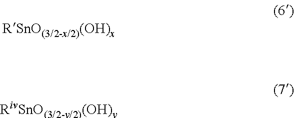

wherein 0<x≤3, 0<y≤3, wherein R′ has formula [I]: CRaRbRc, wherein Ra is an aromatic ring having about 3 to about 10 carbon atoms which optionally contains and/or is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms, and X is selected from NR₂ and OR, wherein each R is independently a linear or branched alkyl group having about 1 to about 10 carbon atoms which is optionally substituted with one or more halogen atoms, and R^{iv} is an optionally substituted hydrocarbon group having about 2 to about 20 carbon atoms which is different from R′.

Embodiment A35: The composition according to Embodiment A34, wherein the compound having formula (6′) is obtained by hydrolysis of a monoorgano tin compound having formula (1):

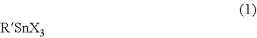

wherein X is selected from NR₂ and OR, and wherein each R is independently a linear or branched alkyl group having about 1 to about 10 carbon atoms.

Embodiment A36: A solution comprising the composition according to Embodiment A34 or A35 and an organic solvent.

Embodiment A37: The solution according to Embodiment A36, wherein the compound having formula (6′) is obtained by hydrolysis of a monoorgano tin compound having formula (1):

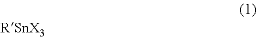

wherein X is selected from NR₂ and OR, and wherein each R is independently a linear or branched alkyl group having about 1 to about 10 carbon atoms.

Embodiment A38: A film comprising the composition according to Embodiment A34 or A35.

Embodiment A39: The film according to Embodiment A36, wherein the compound having formula (6′) is obtained by hydrolysis of a monoorgano tin compound having formula (1):

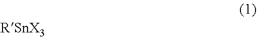

wherein X is selected from NR₂ and OR, and wherein each R is independently a linear or branched alkyl group having about 1 to about 10 carbon atoms.

Embodiment B1: A monoorgano tin compound having formula (1) having a purity of at least about 95 mol % and containing less than about 5 mol % of a diorgano tin compound having formula (2):

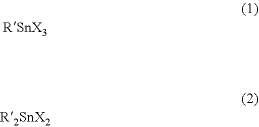

wherein R′ has formula [II]: CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage, and wherein X is selected from NR₂ and OR, wherein each R is independently a linear or branched alkyl group having about 1 to about 10 carbon atoms which is optionally substituted with one or more halogen atoms.

Embodiment B2: The monoorgano tin compound according to Embodiment B1, wherein a content of a compound having formula (3) is less than about 5 mol %:

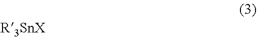

Embodiment B3: The monoorgano tin compound according to Embodiment B1 or B2, wherein a content of a compound having formula (4) is less than about 5 mol %:

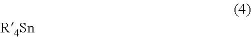

Embodiment B4: The monoorgano tin compound according to any of Embodiments B1-B3, wherein a content of a compound having formula (4) is less than about 5 mol %:

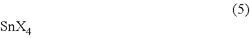

Embodiment B5: The monoorgano tin compound according to any of Embodiments B1-B4, wherein R′ is selected from the group consisting of:

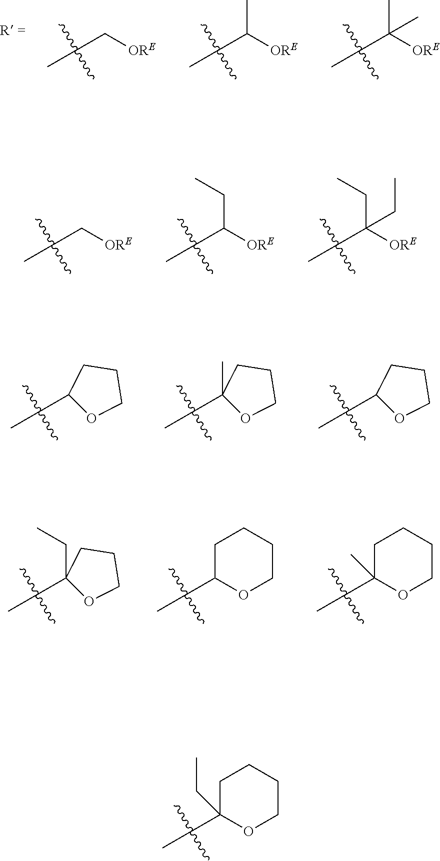

Embodiment B6: The monoorgano tin compound according to any of Embodiments B1-B5, wherein R^{A} is OR^{E} and R^{E} and at least one of R^{B} and R^{C} optionally forms a 3 to 8-membered ring containing an ether linkage.

Embodiment B7: The monoorgano tin compound according to any of Embodiments B1-B6, wherein R^{E} is a methyl group.

Embodiment B8: The monoorgano tin compound according to any of Embodiments B1-B7, wherein X═NMe₂.

Embodiment B9: A method of synthesizing a monoorgano tin compound having formula (1) having a purity of at least about 95 mol % and containing less than about 5 mol % of a diorgano tin compound having formula (2):

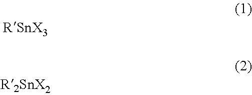

wherein R′ has formula [II]: CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage, and wherein X is selected from NR₂ and OR, wherein each R is independently a linear or branched alkyl group having about 1 to about 10 carbon atoms which is optionally substituted with one or more halogen atoms, the method comprising reacting a compound containing an R′ group with a compound having formula SnX₄.

Embodiment B10: The method according to Embodiment B9, wherein the compound containing an R′ group is a compound having formula R′MgZ, wherein Z is a halogen atom.

Embodiment B11: The method according to Embodiment B9 or B10, wherein Y is selected from a halogen atom, NR₂, and OR.

Embodiment B12: A method of synthesizing a monoorgano tin compound having formula (1) having a purity of at least about 95 mol % and containing less than about 5 mol % of a diorgano tin compound having formula (2):

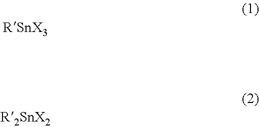

wherein R′ has formula [II]: CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage, and wherein X is selected from NR₂ and OR, wherein each R is independently a linear or branched alkyl group having about 1 to about 10 carbon atoms which is optionally substituted with one or more halogen atoms, the method comprising reacting a compound containing an OR or NR₂ group with a compound having formula R′SnY₃, where Y is a reactive ligand.

Embodiment B13: The method according to Embodiment B12, wherein Y is a halogen atom, NR₂, or OR.

Embodiment B14: The method according to Embodiment B12 or B13, wherein R′SnY₃ is prepared by reacting R′₄Sn with SnY₄.

Embodiment B15: A method of synthesizing a monoorgano tin compound having formula (1) having a purity of at least about 95 mol % and containing less than about 5 mol % of a diorgano tin compound having formula (2):

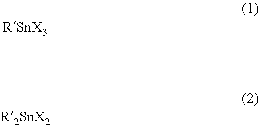

wherein R′ has formula [II]: CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage, and wherein X is selected from NR₂ and OR, wherein each R is independently a linear or branched alkyl group having about 1 to about 10 carbon atoms which is optionally substituted with one or more halogen atoms, the method comprising: (a) reacting a metal compound comprising an alkali metal M and a ligand X with a compound having formula SnY₂ to form a compound having formula MSnX₃; and (b) reacting the compound having formula MSnX₃ with a compound R′Z, wherein Z is a halogen atom and Y is a reactive ligand.

Embodiment B16: The method according to Embodiment B15, wherein Y is a halogen atom, NR₂ or OR.

Embodiment B17: The method according to any of Embodiments B9-B16, wherein the reaction is performed in a solvent containing greater than about 50% by volume of a hydrocarbon solvent and/or an aromatic solvent.

Embodiment B18: The method according to Embodiment B17, wherein the solvent is dehydrated prior to performing the reaction.

Embodiment B19: The method according to any of Embodiment B9-B18, further comprising at least one purification step substantially without light exposure.

Embodiment B20: The method according to Embodiment B19, wherein the at least one purification step comprises fractional distillation.

Embodiment B21: The method according to any of Embodiments B9-B20, wherein the reaction is performed substantially without light exposure.

Embodiment B22: A method of storing a sample of the monoorgano tin compound having formula (1) according to any of Embodiments B1 to B8, the method comprising storing the sample of the monoorgano tin compound having formula (1) substantively without light exposure and at a temperature of less than about 30° C.

Embodiment B23: The method according to Embodiment B22, wherein the sample of the monoorgano tin compound having formula (1) is stored for about three days to about one year.

Embodiment B24: The method according to Embodiment B22 or B23, wherein the sample of the monoorgano tin compound undergoes substantively no decomposition after a storage time of about three days to about one year.

Embodiment B25: The method according to any of Embodiments B22-B24, comprising storing the compound having formula (1) in a container in an inert atmosphere.

Embodiment B26: The method according to any of Embodiments B22-B25, comprising storing the compound having formula (1) in a container substantially without light exposure.

Embodiment B27: An organotin compound having formula (6′):

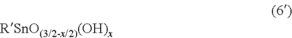

wherein 0<x≤3 and R′ has formula [II]: CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.

Embodiment B28: The organotin compound having formula (6′) according to Embodiment B27, wherein the compound having formula (6′) is obtained by hydrolysis of a compound having formula (1):

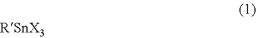

wherein X is selected from NR₂ and OR, wherein each R is independently a linear or branched alkyl group having about 1 to about 10 carbon atoms which is optionally substituted with one or more halogen atoms.

Embodiment B29: A solution comprising the organotin compound having formula (6′) according to Embodiment B27 and an organic solvent.

Embodiment B30: The solution according to Embodiment B29, wherein the compound having formula (6′) is obtained by hydrolysis of a compound having formula (1):

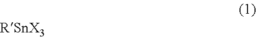

wherein X is selected from NR₂ and OR, wherein each R is independently a linear or branched alkyl group having about 1 to about 10 carbon atoms which is optionally substituted with one or more halogen atoms.

Embodiment B31: A film comprising the organotin compound having formula (6′) according to Embodiment B27.

Embodiment B32: The film according to Embodiment B31, wherein the compound having formula (6′) is obtained by hydrolysis of a compound having formula (1):

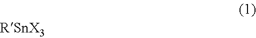

wherein X is selected from NR₂ and OR, wherein each R is independently a linear or branched alkyl group having about 1 to about 10 carbon atoms which is optionally substituted with one or more halogen atoms.

Embodiment B33: A composition comprising the monoorgano tin compound having formula (1) according to any of Embodiments B1-B8 and a R^{iv}SnY₃ compound, wherein Y is a reactive ligand selected from a halogen atom, NR₂, and OR and R^{iv} is an optionally substituted hydrocarbon group having about 2 to 20 carbon atoms.

Embodiment B34: A composition comprising an organotin compound having formula (6′) and an organotin compound having formula (7′):

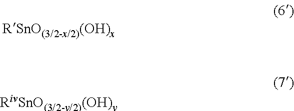

wherein 0<x≤3, 0<y≤3, wherein R′ has formula [II]: CR^{A}R^{B}R^{C}, wherein R^{A} is (CH₂)ₙOR^{E},
n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage and R^{iv} is an optionally substituted hydrocarbon group having about 2 to 20 carbon atoms which is different from R′.

Embodiment B35: The composition according to Embodiment B34, wherein the compound having formula (6′) is obtained by hydrolysis of a monoorgano tin compound having formula (1):

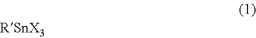

wherein X is selected from NR₂ and OR, wherein each R is independently a linear or branched alkyl group having about 1 to about 10 carbon atoms which is optionally substituted with one or more halogen atoms.

Embodiment B36: A solution comprising the composition according to Embodiment B34 or B35 and an organic solvent.

Embodiment B37: The solution according to Embodiment B36, wherein the compound having formula (6′) is obtained by hydrolysis of a monoorgano tin compound having formula (1):

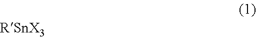

wherein X is selected from NR₂ and OR, wherein each R is independently a linear or branched alkyl group having about 1 to about 10 carbon atoms which is optionally substituted with one or more halogen atoms.

Embodiment B38: A film comprising the composition according to Embodiment B34 or B35.

Embodiment B39: The film according to Embodiment B36, wherein the compound having formula (6′) is obtained by hydrolysis of a monoorgano tin compound having formula (1):

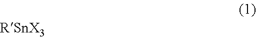

wherein X is selected from NR₂ and OR, wherein each R is independently a linear or branched alkyl group having about 1 to about 10 carbon atoms which is optionally substituted with one or more halogen atoms.

Embodiment C1: A monoorgano tin compound having formula (1′) having a purity of at least about 95 mol % and containing less than about 5 mol % of a diorgano tin compound having formula (2′) and less than about 5 mol % of a compound having formula (5′):

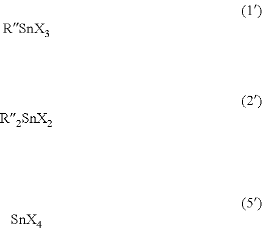

wherein R″ is a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20, X is selected from NR₂ and OR, and wherein each R is independently a linear or branched alkyl group having about 1 to about 10 carbon atoms.

Embodiment C2: The monoorgano tin compound according to Embodiment C1, wherein a content of a compound having formula (3′) is less than about 5 mol %:

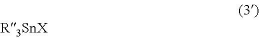

Embodiment C3: The monoorgano tin compound according to Embodiment C1 or C2, wherein a content of a compound having formula (4′) is less than about 5 mol %:

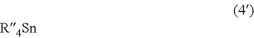

Embodiment C4: The monoorgano tin compound according to any of Embodiments C1-C3, wherein R″ is selected from the group consisting of:

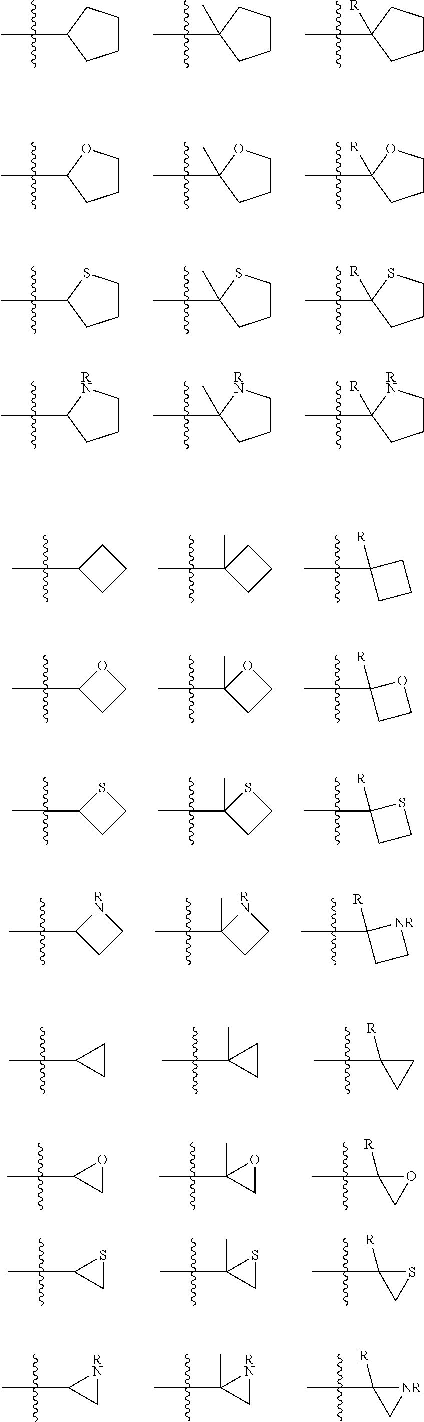

Embodiment C5: The monoorgano tin compound according to any of Embodiments C1-C4, wherein X═NMe₂.

Embodiment C6: A method of synthesizing a monoorgano tin compound having formula (1′) having a purity of at least about 95 mol % and containing less than about 5 mol % of a diorgano tin compound having formula (2′) and less than about 5 mol % of a compound having formula (5′):

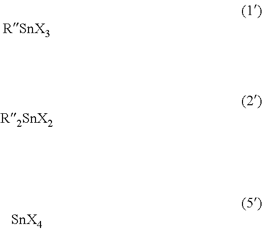

wherein R″ is a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20, X is selected from NR2 and OR, and wherein each R is independently a linear or branched alkyl group having about 1 to about 10 carbon atoms, the method comprising reacting a compound containing an R″ group with a compound having formula SnX₄.

Embodiment C7: The method according to Embodiment C6, wherein the compound containing an R″ group is a compound having formula R″MgZ, wherein Z is a halogen atom.

Embodiment C8: A method of synthesizing a monoorgano tin compound having formula (1′) having a purity of at least about 95 mol % and containing less than about 5 mol % of a diorgano tin compound having formula (2′) and less than about 5 mol % of a compound having formula (5′):

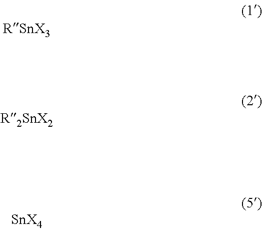

wherein R″ is a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20, X is selected from NR₂ and OR, and wherein each R is independently a linear or branched alkyl group having about 1 to about 10 carbon atoms, the method comprising reacting a compound containing an OR or NR₂ group with a compound having formula R′SnY₃, where Y is a reactive ligand.

Embodiment C9: The method according to Embodiment C8, wherein Y is a halogen atom, NR₂, or OR.

Embodiment C10: The method according to Embodiment C8 or C9, wherein R″SnY₃ is prepared by reacting R′₄Sn with SnY₄.

Embodiment C11: A method of synthesizing a monoorgano tin compound having formula (1′) having a purity of at least about 95 mol % and containing less than about 5 mol % of a diorgano tin compound having formula (2′) and less than about 5 mol % of a compound having formula (5′):

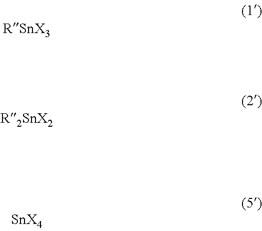

wherein R″ is a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20, X is selected from NR₂ and OR, and wherein each R is independently a linear or branched alkyl group having about 1 to about 10 carbon atoms, the method comprising: (a) reacting a metal compound comprising an alkali metal M and a ligand X with a compound having formula SnY₂ to form a compound having formula MSnX₃; and (b) reacting the compound having formula MSnX₃ with a compound R″Z, wherein Z is a halogen atom and Y is a reactive ligand.

Embodiment C12: The method according to Embodiment C11, wherein Y is a halogen atom, NR₂ or OR.

Embodiment C13: The method according to any of Embodiments C6-C12, wherein the reaction is performed in a solvent containing greater than about 50% by volume of a hydrocarbon solvent and/or an aromatic solvent.

Embodiment C14: The method according to Embodiment C13, wherein the solvent is dehydrated prior to performing the reaction.

Embodiment C15: The method according to any of Embodiments C6-C14, further comprising at least one purification step substantially without light exposure.

Embodiment C16: The method according to Embodiment C15, wherein the at least one purification step comprises fractional distillation.

Embodiment C17: The method according to any of Embodiments C6-C16, wherein the reaction is performed substantially without light exposure.

Embodiment C18: A method of storing a sample of the monoorgano tin compound having formula (1′) according to any of Embodiments C1 to C5, the method comprising storing the sample of the monoorgano tin compound having formula (1′) substantively without light exposure and at a temperature of less than about 30° C.

Embodiment C19: The method according to Embodiment C18, wherein the sample of the monoorgano tin compound having formula (1′) is stored for about three days to about one year.

Embodiment C20: The method according to Embodiment C18 or C19, wherein the sample of the monoorgano tin compound undergoes substantively no decomposition after a storage time of about three days to about one year.

Embodiment C21: The method according to any of Embodiments C18 to C20, comprising storing the compound having formula (1′) in a container in an inert atmosphere.

Embodiment C22: The method according to any of Embodiments C18 to C21, comprising storing the compound having formula (1′) in a container substantially without light exposure.

Embodiment C23: An organotin compound having formula (6″):

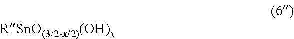

wherein 0<x≤3 and R″ is a 3 to 5-membered 5 optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20.

Embodiment C24: The organotin compound having formula (6″) according to Embodiment C23, wherein the compound having formula (6″) is obtained by hydrolysis of a compound having formula (1′):

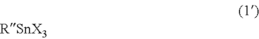

wherein X is selected from NR₂ and OR, and wherein each R is independently a linear or branched alkyl group having about 1 to about 10 carbon atoms.

Embodiment C25: A solution comprising the organotin compound having formula (6″) according to Embodiment C23 and an organic solvent.

Embodiment C26: The solution according to Embodiment C25, wherein the compound having formula (6″) is obtained by hydrolysis of a compound having formula (1′):

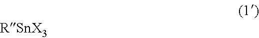

wherein X is selected from NR₂ and OR, and wherein each R is independently a linear or branched alkyl group having about 1 to about 10 carbon atoms.

Embodiment C27: A film comprising the organotin compound having formula (6″) according to Embodiment C23.

Embodiment C28: The film according to Embodiment C27, wherein the compound having formula (6″) is obtained by hydrolysis of a compound having formula (1′):

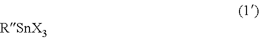

wherein X is selected from NR₂ and OR, and wherein each R is independently a linear or branched alkyl group having about 1 to about 10 carbon atoms.

Embodiment C29: A composition comprising the monoorgano tin compound having formula (1′) according to any of Embodiments C1 to C5 and a R^{iv}SnY₃ compound, wherein Y is a reactive ligand selected from a halogen atom, NR₂, and OR and R^{iv} is an optionally substituted hydrocarbon group having about 2 to 20 carbon atoms which is different from R″.

Embodiment C30: A composition comprising an organotin compound having formula (6″) and an organotin compound having formula (7″):

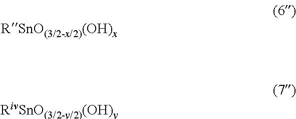

wherein 0<x≤3, 0<y≤3, R″ is a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20, and R^{iv} is an optionally substituted hydrocarbon group having about 2 to about 20 carbon atoms which is different from R″.

Embodiment C31: The composition according to Embodiment C30, wherein the compound having formula (6″) is obtained by hydrolysis of a monoorgano tin compound having formula (1′):

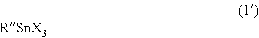

wherein X is selected from NR₂ and OR, and wherein each R is independently a linear or branched alkyl group having about 1 to about 10 carbon atoms.

Embodiment C32: A solution comprising the composition according to Embodiment C30 or C31 and an organic solvent.

Embodiment C33: The solution according to Embodiment C32, wherein the compound having formula (6″) is obtained by hydrolysis of a monoorgano tin compound having formula (1′):

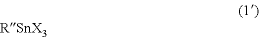

wherein X is selected from NR₂ and OR, and wherein each R is independently a linear or branched alkyl group having about 1 to about 10 carbon atoms.

Embodiment C34: A film comprising the composition according to Embodiment C30 or C31.

Embodiment C35: The film according to Embodiment C34, wherein the compound having formula (6″) is obtained by hydrolysis of a monoorgano tin compound having formula (1′):

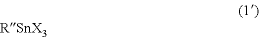

wherein X is selected from NR₂ and OR, and wherein each R is independently a linear or branched alkyl group having about 1 to about 10 carbon atoms.

Embodiment D1: A method for producing a monoalkyltin triamide having formula (11) by reacting an alkylmagnesium reagent having formula (8) or (9) with a tin tetraamide having formula (10) in the presence of a first solvent containing an ether solvent having a boiling point of at least 40° C., and distilling off the ether solvent in the presence of a second solvent having an octanol/water partition coefficient greater than the ether solvent and greater than 1.0;

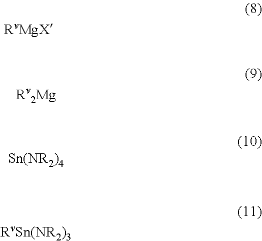

wherein R^{v} is a linear, branched, or cyclic hydrocarbyl group having 1 to 30 carbon atoms which is optionally substituted with one or more oxygen atoms, nitrogen atoms, silicon atoms, or sulfur atoms, each R is independently a linear or branched alkyl group having about 1 to 10 carbon atoms which is optionally substituted with one or more halogen atoms and multiple Rs may be bonded to each other to form a cyclic structure, and X′ is chlorine, bromine, or iodine.

Embodiment D2: A method for producing a monoalkyltin triamide having formula (11) by reacting an alkylmagnesium reagent having formula (8) or (9) with a tin tetraamide having formula (10) in the presence of a first solvent containing an ether solvent having a boiling point of at least 40° C., mixing a second solvent having an octanol/water partition coefficient greater than the ether solvent and greater than 1.0, and removing a solid containing a magnesium salt by filtration;

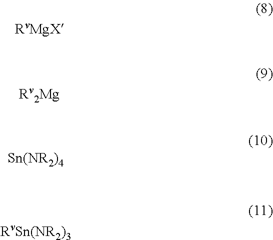

wherein R^{v} is a linear, branched, or cyclic hydrocarbyl group having 1 to 30 carbon atoms which is optionally substituted with one or more oxygen atoms, nitrogen atoms, silicon atoms, or sulfur atoms, each R is independently a linear or branched alkyl group having about 1 to 10 carbon atoms which is optionally substituted with one or more halogen atoms and multiple Rs may be bonded to each other to form a cyclic structure, and X′ is chlorine, bromine, or iodine.

Embodiment D3: The method of producing a monoalkyltin triamide (11) according to Embodiment D1 or D2, further comprising a step of distilling off a reaction mixture obtained by reacting the alkyl magnesium reagent with the tin tetraamide to obtain monoalkyltin tetraamide having a purity of 98% or greater.

Embodiment D4: The method of producing a monoalkyltin triamide (11) according to Embodiment D2, further comprising: a step of distilling off a solvent from a reaction mixture obtained by reacting the alkyl magnesium reagent with the tin tetraamide.

Embodiment D5: The method for producing a monoalkyl tin triamide (11) according to any of Embodiments D1 to D4, further comprising a step of removing a magnesium salt by filtration from a reaction mixture obtained by reacting the alkyl magnesium reagent with the tin tetraamide.

Embodiment D6: The method for producing a monoalkyl tin triamide (11) according to any of Embodiments D1 to D5, wherein the alkyl magnesium reagent and the tin tetraamide react with each other in a presence of a mixed solvent of the first solvent and the second solvent.

Embodiment D7: The method of producing a monoalkyltin triamide (11) according to any one of Embodiments D1 to D6, further comprising a step of mixing the second solvent with a crude product obtained by distilling off at least a part of the first solvent from a reaction mixture obtained by reacting the alkyl magnesium reagent with the tin tetraamide.

Embodiment D8: The method of producing a monoalkyltin triamide (11) according to any one of Embodiments D1 to D7, further comprising a step of distilling off the ether solvent while continuously adding the second solvent to a reaction mixture obtained by reacting the alkyl magnesium reagent with the tin tetraamide.

Embodiment D9: The method of producing a monoalkyltin triamide (11) according to any one of Embodiments D1 to D8, wherein the ether-based solvent has a boiling point lower than a boiling point of the monoalkyltin triamide by 30° C. or higher.

Embodiment D10: The method of producing a monoalkyltin triamide (11) according to any one of Embodiments D1 to D9, wherein the second solvent has a boiling point lower than a boiling point of the monoalkyltin triamide by 30° C. or higher.

Embodiment D11: The method of producing monoalkyltin triamide (11) according to any one of Embodiments D1 to D10, wherein the second solvent has a boiling point higher than the boiling point of the ether-based solvent by 10° C. or higher.

Embodiment D12: The method of producing a monoalkyltin triamide (11) according to any one of Embodiments D1 to D11, wherein the second solvent has an octanol-water partition coefficient of 2.5 or greater.

Embodiment D13: The method of producing a monoalkyltin triamide (11) according to any one of Embodiments D1 to D12, wherein the ether-based solvent has an octanol-water partition coefficient of 1.5 or less.

Embodiment D14: The method of producing monoalkyltin triamide according to any one of Embodiments D2 to D13, further comprising a step of setting a concentration of a tin compound to 5% to 90% by mass and removing the magnesium salt by filtration.

Embodiment D15: The method of producing a monoalkyltin triamide (11) according to any one of any one of Embodiments D2 to D14, further comprising a step of setting a concentration of the ether-based solvent to 20% by mass or less and removing the magnesium salt by filtration.

Embodiment D16: The method of producing monoalkyltin triamide according to any one of any one of Embodiments D1 to D15, wherein the ether-based solvent has a flash point of −30° C. or higher.

Embodiment D17: The method of producing a monoalkyltin triamide (11) according to any one of any one of Embodiments D1 to D16, wherein the second solvent has a flash point of −30° C. or higher.

Embodiment D18: The method of producing a monoalkyltin triamide (11) according to any one of Embodiments D1 to D17, wherein R^{v} is a tertiary hydrocarbon group having 1 to 30 carbon atoms.

Embodiment D19: The method of producing a monoalkyltin triamide (11) according to Embodiment D18, wherein R^{v} has a cyclic structure.

Embodiment D20: The method of producing a monoalkyltin triamide (11) according to Embodiment D19, wherein R^{v} is a 1-alkyl-1-cycloalkyl group.

Embodiment E1: A method for a producing monoorgano tin trialkoxide compound having formula (1″′), comprising:
i) reacting a tetraalkynyl tin compound having formula (14) with a magnesium reagent having formula (8′); and
ii) reacting the product of step i) with an alcohol having formula (15):

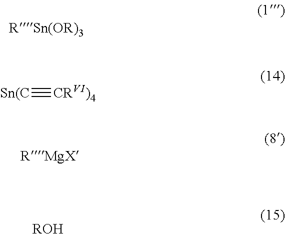

wherein each R is each independently a linear or branched alkyl group having about 1 to about 10 carbon atoms, each R^{VI} is independently a linear or branched alkyl group having about 1 to about 10 carbon atoms, or an aryl group having about 6 to 10 carbon atoms, X′ is chlorine, bromine, or iodine, and R″″ is a hydrocarbon group having about 1 to 30 carbon atoms which may contain one or more, oxygen atoms, nitrogen atoms, silicon atoms, or sulfur atoms.

Embodiment E2: The method for producing a monoorgano tin trialkoxide compound according to Embodiment E1, wherein R^{VI} is a tertiary alkyl group.

Embodiment E3: The method for producing a monoorgano tin trialkoxide compound according to Embodiment E1 or E2, wherein R is a primary alkyl group.

Embodiment E4: The method for producing a monoorgano tin trialkoxide compounds according to any of Embodiments E1 to E3, wherein R″″ has formula [I], [II], or [III]:
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″″ is about 2 to about 20.

Embodiment E5. A method for producing a monoorgano tin triamide compounds having formula (1″), comprising, producing a monoorgano tin trialkoxide compound having formula (1″′) according to any of Embodiments E1 to E4, and
(iii) reacting the monoorgano tin trialkoxide compound having formula (1″′) with a lithium amide having formula (16) or a (N,N-dialkylamino)trialkylsilane having formula (19):

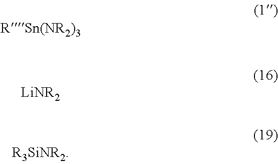

Embodiment E6: A method for producing a monoorgano tin trialkoxide compound having formula (1″′), comprising:
i) reacting a bis[bis(trialkylsilylamino)]tin(II) compound having formula (17) with a hydrocarbyl halide compound having formula (18); and
ii) reacting the product of step i) with an alkali metal alkoxide having formula (15′) and an associated alcohol having formula (15)

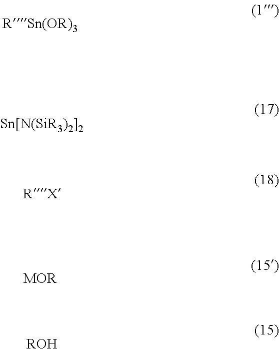

wherein each R is independently a linear or branched alkyl group having about 1 to about 10 carbon atoms, X′ is chlorine, bromine, or iodine, M is an alkali metal, and R″″ is a hydrocarbon group having about 1 to 30 carbon atoms which may contain one or more oxygen atoms, nitrogen atoms, silicon atoms, or sulfur atoms.

Embodiment E7: The method for producing monoorgano tin trialkoxide compounds according to Embodiment E6, wherein R is a primary alkyl group.

Embodiment E8. The method for producing monoorgano tin trialkoxide compounds according to Embodiment E6 or E7, wherein R″″ has formula [I], [II], or [III].
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″″ is about 2 to about 20.

Embodiment E9: A method for producing a monoorgano tin triamide compounds having formula (1″), comprising, producing a monoorgano tin trialkoxide compound having formula (1″′) according to any of Embodiments E6-E8, and
(iii) reacting the monoorgano tin trialkoxide compound having formula (1″′) with a lithium amide having formula (16) or (N,N-dialkylamino)trialkylsilane having formula (19):

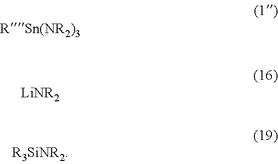

### BRIEF DESCRIPTION OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a ¹¹⁹Sn NMR spectrum of 1-methyl-cyclopentyl tris(dimethylamino)tin according to an embodiment of the disclosure;

FIG. 2 is a ¹H NMR spectrum of 1-methyl-cyclopentyl tris(dimethylamino)tin according to an embodiment of the disclosure;

FIG. 3 is a ¹¹⁹Sn NMR spectrum of R″SnO_{(3/2-x/2)}(OH)ₓ according to an embodiment of the disclosure;

FIG. 4 is a ¹H NMR spectrum of R″SnO_{(3/2-x/2)}(OH)ₓ according to an embodiment of the disclosure;

FIG. 5 is an ESI-Mass spectrum of R″SnO_{(3/2-x/2)}(OH)ₓ according to an embodiment of the disclosure;

FIG. 6 is an ESI-Mass spectrum of R″SnO_{(3/2-x/2)}(OH)ₓ according to an embodiment of the disclosure;

FIG. 7 is an ESI-Mass spectrum of R″SnO_{(3/2-x/2)}(OH)ₓ according to an embodiment of the disclosure;

FIG. 8 is a ¹¹⁹Sn NMR spectrum of a mixture 5 of R″SnO_{(3/2-x/2)}(OH)ₓ and R″SnO_{(3/2-y/2)}(OH)_{y} according to an embodiment of the disclosure;

FIG. 9 is a ¹H NMR spectrum of a mixture of R″SnO_{(3/2-x/2)}(OH)ₓ and R^{iv}SnO_{(3/2-y/2)}(OH)_{y} according to an embodiment of the disclosure;

FIG. 10 is a ¹³C NMR spectrum of a mixture of R″SnO_{(3/2-x/2)}(OH)ₓ and R^{iv}SnO_{(3/2-y/2)}(OH)_{y} according to an embodiment of the disclosure;

FIG. 11 is an ESI-Mass spectrum of a mixture of R″SnO_{(3/2-x/2)}(OH)ₓ and R^{iv}SnO_{(3/2-y/2)}(OH)_{y} according to an embodiment of the disclosure;

FIG. 12 is an ESI-Mass spectrum of a mixture of R″SnO_{(3/2-x/2)}(OH)ₓ and R^{iv}SnO(3/2-y/2)(OH)y according to an embodiment of the disclosure;

FIG. 13 is an ESI-Mass spectrum of a mixture of R″SnO_{(3/2-x/2)}(OH)ₓ and R^{iv}SnO_{(3/2-y/2)}(OH)_{y} according to an embodiment of the disclosure;

FIG. 14 is a ¹¹⁹Sn NMR spectrum of 1-methyl-1-cyclopentyltin tris(dimethylamide) according to an embodiment of the disclosure;

FIG. 15 is a ¹H NMR spectrum of 1-methyl-1-cyclopentyltin tris(dimethylamide) according to an embodiment of the disclosure;

FIG. 16 is a ¹¹⁹Sn NMR spectrum of isopropyltin tris(dimethylamide) according to an embodiment of the disclosure;

FIG. 17 is a ¹¹⁹Sn NMR spectrum of t-butyltin tris(dimethylamide) according to an embodiment of the disclosure;

FIG. 18 is a ¹H NMR spectrum of 1-methylcyclopentyltris(dimethylamino)tin according to an embodiment of the disclosure;

FIG. 19 is a ¹¹⁹Sn NMR spectrum of 1-methylcyclopentyltris(dimethylamino)tin according to an embodiment of the disclosure;

FIG. 20 is a ¹H NMR spectrum of 1-methylcyclopentyltris(tert-butoxy)tin according to an embodiment of the disclosure;

FIG. 21 is a ¹¹⁹Sn NMR spectrum of 1-methylcyclopentyltris(tert-butoxy)tin according to an embodiment of the disclosure;

FIG. 22 is a ¹¹⁹Sn{¹H} NMR spectrum of methylbenzyltris(dimethylamino)tin according to an embodiment of the disclosure; and

FIG. 23 is a ¹H NMR spectrum of methylbenzyltris(dimethylamino)tin according to an embodiment of the disclosure.

### DETAILED DESCRIPTION OF THE INVENTION

According to one aspect of the disclosure, provided are monoorgano tin compounds having formula (1) or (1′). For the purposes of this disclosure, the term “monoorgano” refers to a substituent containing (i) at least one aromatic ring, (ii) a saturated hydrocarbon group with an ether substitution, or (iii) a single 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20.

The compounds having formula (1) and (1′) preferably have a purity of at least about 95 mol % and preferably contain no more than about 5 mol % diorgano tin compounds having formula (2) or (2′) relative to the total amount of tin, preferably no more than about 4 mol %, no more than about 3 mol %, no more than about 2 mol %, more preferably no more than about 1 mol %, even more preferably no more than about 0.5 mol %, even more preferably no more than about 0.1 mol %.

In some embodiments, the content of a compound having formula (5) or (5′) in the compound having formula (1) or (1′) is less than about 5 mol %, less than about 3 mol %, less than about 2 mol %, less than about 1 mol %, less than about 0.7 mol %, less than about 0.5 mol %, or less than about 0.1 mol %:

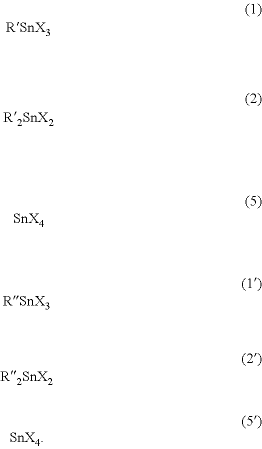

Unless otherwise stated, any numerical value is to be understood as being modified in all instances by the term “about.” Thus, a numerical value typically includes 10% of the recited value. For example, the recitation of a temperature such as “10° C.” or “about 10° C.” includes 9° C. and 11° C. and all temperatures therebetween.

In the present invention, the expression “α to β” (α and β are any numbers) includes the meaning of “α or greater and β or less” as well as the meaning of “preferably greater than α” or “preferably less than β” unless otherwise specified.

In addition, the expression “α or greater” (α represents any number) or “β or less” (β represents any number) also includes the meaning of “preferably greater than α” or “preferably less than β”.

Further, in the present invention, the expression “γ and/or δ (γ and δ represent any configuration or component)” means three combinations of only γ, only δ, and γ and δ.

All numerical ranges expressed in this disclosure expressly encompass all possible subranges, all individual numerical values within that range, including integers within such ranges and fractions and decimal amounts of the values unless the context clearly indicates otherwise. Accordingly, the content of the compounds having formula (2′) and formula (5′) are in some embodiments each independently preferably less than about 5 mol %, less than about 4 mol %, less than about 3 mol %, less than about 2 mol %, less than about 1 mol %, less than about 0.9 mol %, less than about 0.8 mol %, less than about 0.7 mol %, less than about 0.6 mol %, less than about 0.5 mol %, less than about 0.4 mol %, less than about 0.3 mol %, less than about 0.2 mol %, less than about 0.1 mol %, less than about 0.05 mol %, less than about 0.04 mol %, less than about 0.03 mol %, less than about 0.02 mol %, less than about 0.01 mol %, or nondetectable by ¹¹⁹Sn NMR, that is, the compounds having formula (2′) and formula (5′) are in some embodiments undetectable in a sample of the compound having formula (1′).

For the purposes of this disclosure, the terms hydrocarbyl group, hydrocarbon group, hydrocarbyl substituent, and hydrocarbon substituent may be understood to be synonymous and to include linear, branched, and cyclic organic groups containing only carbon and hydrogen atoms, including alkyl, alkenyl, alkynyl, aryl, and aralkyl groups. Such groups may be substituted as described below.

### Cyclic Substituents

In formulas (1′) and (2′), R″ has formula [III]: a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20, preferably no more than about 10 carbon atoms, more preferably no more than 8 carbon atoms, even more preferably no more than about 7 carbon atoms; the number of carbon atoms in R″ is preferably more than about 3 carbon atoms, more preferably more than 4 carbon atoms, even more preferably more than about 5 carbon atoms. Preferably the total number of carbon atoms in R″ is about 3 to about 7. A lower total number of carbon atoms is preferred from the viewpoint of lowering the boiling point of the tin compound and the boiling point of the outgas generated. A higher total number of carbon atoms is preferred from the viewpoint of high thermal stability and hydrophobic property as a resist material. A total number of carbon atoms in R″ is even more preferably about 5 to about 7 from the viewpoint of balancing resist properties.

The carbon bonded to Sn in R″ is preferably a secondary or tertiary carbon and a tertiary carbon is further preferred from the viewpoint of further improving photo-reactivity. Three- and four-membered rings are preferred from the viewpoint of further improving photo-reactivity due to the large ring distortion, and three-membered rings are most preferred. Three and four-membered rings are further preferred from the viewpoint of lowering the boiling point of the tin compound and the boiling point of the outgas generated, and three-membered rings are even more preferred. On the other hand, five-membered rings are preferred from the viewpoint of balance of thermal stability and photo-reactivity of tin compounds and ease of synthesis of high purity products. 3 to 5-membered heterocyclic hydrocarbon rings containing at least one Sulfur, oxygen, or nitrogen atom are preferred from the viewpoint of further improving photo-reactivity. The combination of tertiary carbon and 3 to 5-membered cyclic hydrocarbon rings is especially preferred, because the photo-reactivity is much higher because the features described above have a synergistic effect.

In formulas (1′), (2′), and (5′), X is selected from NR₂ and OR. Each R is independently a linear or branched (primary, secondary, or tertiary) alkyl group having about 1 to about 10 carbon atoms, preferably about 1 to about 5 carbon atoms, more preferably 1 to about 4 carbon atoms, such as, without limitation, primary: methyl, ethyl, n-propyl, n-butyl; secondary: isopropyl, isobutyl, isopentyl; tertiary: t-butyl, t-amyl etc. When X is NR₂, R preferably has about 1 to 3 carbon atoms and is preferably a primary alkyl group such as n-butyl, ethyl, or methyl, more preferably methyl, in terms of the reactivity of hydrolysis. When X is OR, R preferably has 3 to 5 carbon atoms and is preferably a tertiary alkyl group such as t-butyl or t-amyl, more preferably t-butyl in terms of the balance of reactivity of hydrolysis and stability.

Preferred R″ substituents include the following, where the wavy line indicates a point of attachment to the Sn atom:

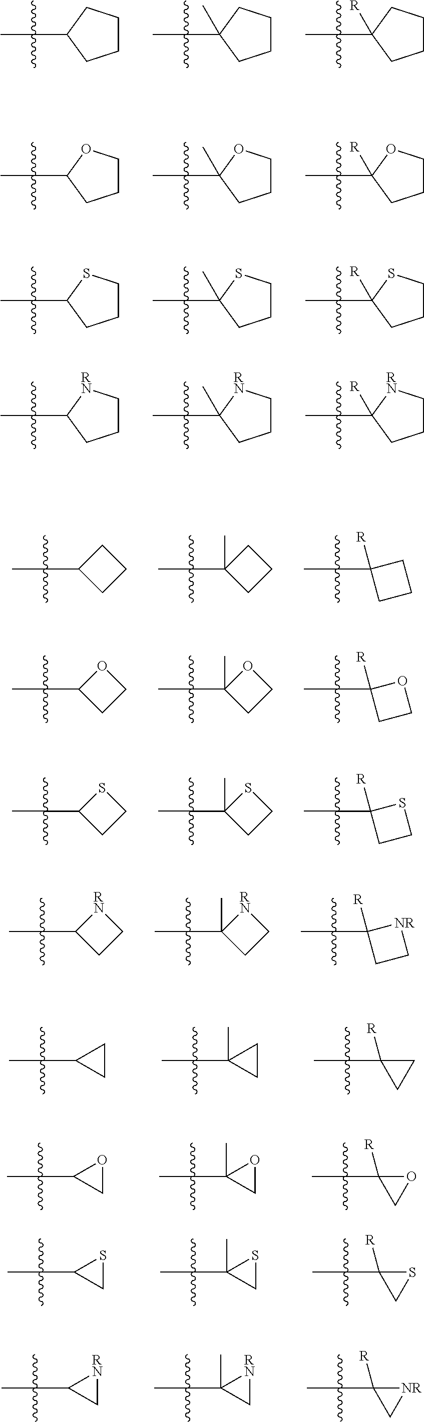

The term “optionally substituted” means that at least one hydrogen atom in the cyclic hydrocarbon or heterocyclic hydrocarbon ring in R″ may be replaced with a substituent such as, for example, a halogen, OH, OR, NH₂, N₂, or an R group as explained above.

In some embodiments, the content of a compound having formula (3′) is less than about 5 mol %, less than about 3 mol %, less than about 2 mol %, less than about 1 mol %, less than about 0.7 mol %, less than about 0.5 mol %, or less than about 0.1 mol %:

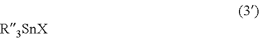

In some embodiments, the content of a compound having formula (4′) is less than about 5 mol %, less than about 3 mol %, less than about 2 mol %, less than about 1 mol %, less than about 0.7 mol %, less than about 0.5 mol %, or less than about 0.1 mol %:

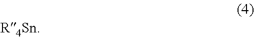

The organometallic tin compounds having formula (1′) may be used for the formation of high-resolution EUV lithography patterning precursors and are attractive due to their electron density, Sn—C bond strength, and radical formation, as well as the potential to reduce EUV dose time.

Particularly preferred compounds having formula (1′) are shown below:

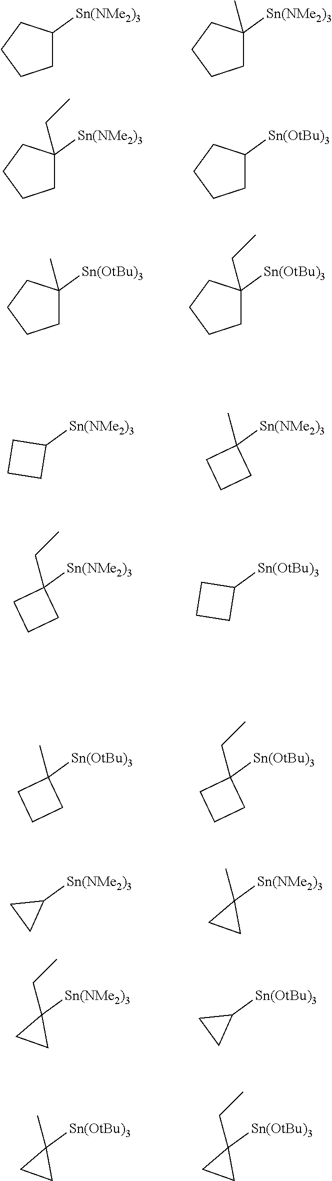

Among these compounds, those having tertiary carbon atoms bonded to tin are preferred in terms of EUV sensitivity, whereas those having secondary carbons bonded to tin are preferred in terms of stability.

### Aromatic and Ether Substituents

In formulas (1) and (2), R′ has formula [I] or [II]:
[I]: CRaRbRc, wherein Ra is an aromatic ring having about 3 to about 10 carbon atoms which optionally contains and/or is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms, and X is selected from NR₂ and OR, wherein each R is independently a linear or branched alkyl group having about 1 to about 10 carbon atoms which is optionally substituted with one or more halogen atoms;
[II]: CR^{A}R^{B}R^{C}, wherein R^{A} is (CH₂)nOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.

In formulas (1), (2), and (5), as described in more detail below, X is selected from NR₂ and OR, wherein each R is independently a linear or branched alkyl group having about 1 to about 10 carbon atoms which is optionally substituted with one or more halogen atoms (such as chlorine, fluorine, or bromine).

### Ether

When R′ has formula [II], it has the following structures, where the wavy line indicates a point of attachment to the Sn atom:

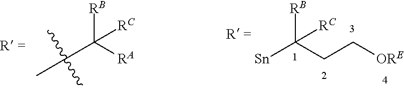

R^{A} may also be understood to be a saturated hydrocarbon group having an ether linkage, in which the oxygen atom of the ether linkage is in the beta, gamma, or delta position with respect to tin, that is, the oxygen atom is no more than four atoms removed from the Sn. The gamma or delta position is preferable because of stability but the most preferable position is the beta position (n=0, R^{A}═OR^{E}) because of high photo sensitivity. The close position of ether linkage and Sn—C bond is important to enhance photo sensitivity, because of the electronic interaction to Sn—C bond from O atom of the ether linkage. It may be understood that R^{A} and R^{C} (or R^{B}) may optionally be connected to form a 3 to 8-membered ring containing an ether linkage.

When R′ has formula [II], the total number of carbon atoms in R′ is about 2 to about 20 carbon atoms, more preferably no more than about 15 carbon atoms, more preferably no more than about 12 carbon atoms, more preferably no more than about 10 carbon atoms, more preferably no more than about 9 carbon atoms, even more preferably no more than about 8 carbon atoms; the number of carbon atoms in R′ is preferably more than about 2 carbon atoms, more preferably more than about 3 carbon atoms. A lower total number of carbon atoms is preferred from the viewpoint of lowering the boiling point of the tin compound and the boiling point of the outgas generated. A higher total number of carbon atoms is preferred from the viewpoint of high thermal stability and hydrophobic property as a resist material. Most preferably the total number of carbon atoms in R′ is about 2 to about 6 from the viewpoint of balancing the resist properties as described above.

The hydrocarbon substituents preferably each contain about 1 to about 10 carbon atoms, more preferably about 1 to about 5 carbon atoms, even more preferably 1 to about 4 carbon atoms, such as, without limitation, primary alkyl groups including methyl, ethyl, n-propyl, n-butyl; secondary alkyl groups including isopropyl, isobutyl, isopentyl; and tertiary alkyl groups including t-butyl, t-amyl, etc.

The carbon bonded to Sn in R′ is preferably a secondary or tertiary carbon and a tertiary carbon is further preferred from the viewpoint of further improving photo-reactivity. The combination of a secondary or tertiary carbon and an ether substituent in a compound having formula (1′) is especially preferred because a synergistic effect between these two features results in a much higher photo-reactivity.

In formulas (1), (2), and (5), X is selected from NR₂ and OR. Each R is independently a linear or branched (primary, secondary, or tertiary) alkyl group having about 1 to about 10 carbon atoms, preferably about 1 to about 5 carbon atoms, more preferably 1 to about 4 carbon atoms, such as, without limitation, primary: methyl, ethyl, n-propyl, n-butyl; secondary: isopropyl, isobutyl, isopentyl; tertiary: t-butyl, t-amyl etc. When X is NR₂, R preferably has about 1 to 3 carbon atoms and is preferably a primary alkyl group such as n-butyl, ethyl, or methyl, more preferably methyl, in terms of the reactivity of hydrolysis. When X is OR, R preferably has 3 to 5 carbon atoms and is preferably a tertiary alkyl group such as t-butyl or t-amyl, more preferably t-butyl in terms of the balance of reactivity of hydrolysis and stability.

When R′ has formula [II], preferred R′ substituents include the following, where the wavy line indicates a point of attachment to the Sn atom. In most preferred embodiments, R^{A} is OR^{E} and R^{E} is most preferably methyl.

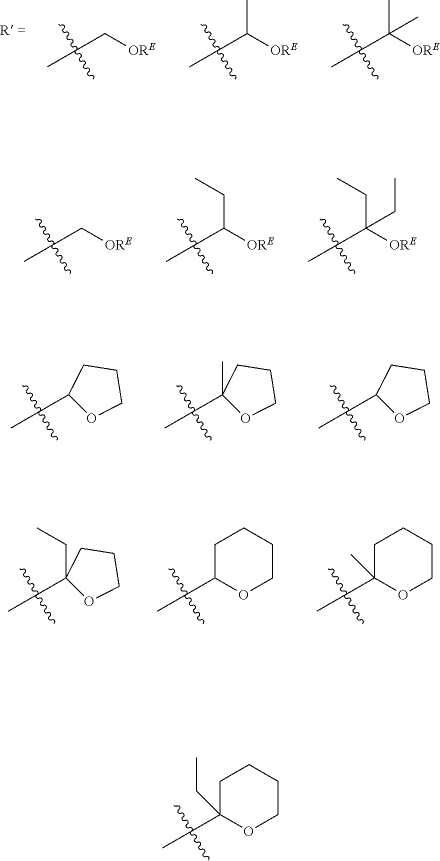

R^{B} or R^{C} is preferably a hydrogen or a methyl group when a low boiling point is desirable, and methyl and ethyl groups are desirable when a secondary or tertiary carbon bonded to Sn is preferred for steric reasons.

R^{E} is preferably a methyl group, when a low boiling point is desirable. An isopropyl or tert-butyl group is desirable because an ether linkage is stable due to steric hindrance.

In some embodiments, the content of a compound having formula (3) is less than about 5 mol %, less than about 3 mol %, less than about 2 mol %, less than about 1 mol %, less than about 0.7 mol %, less than about 0.5 mol %, or less than about 0.1 mol %:

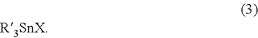

In some embodiments, the content of a compound having formula (4) is less than about 5 mol %, less than about 3 mol %, less than about 2 mol %, less than about 1 mol %, less than about 0.7 mol %, less than about 0.5 mol %, or less than about 0.1 mol %:

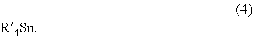

The organometallic tin compounds having formula (1) may be used for the formation of high-resolution EUV lithography patterning precursors and are attractive due to their electron density, Sn—C bond strength, and radical formation, as well as the potential to reduce EUV dose time.

Particularly preferred compounds having formula (1) when R′ has formula [II] include, without limitation, 1-methoxy-methyl tris(dimethylamino)tin, 1-methyl-(1-methoxy)-methyl tris(dimethylamino)tin, and 1,1-dimethyl-(1-methoxy)-methyl tris(dimethylamino)tin.

Among the compounds according to aspects of the disclosure, those having tertiary carbon atoms bonded to tin are preferred in terms of EUV sensitivity, whereas those having secondary carbons bonded to tin are preferred in terms of stability.

### Aromatic

In formulas (1) and (2), R′ may have formula [I]: CRaRbRc, where Ra is an aromatic ring having about 3 to about 10 carbon atoms which optionally contains and/or is optionally substituted with one or more oxygen, nitrogen, and/or halogen atoms (such as chlorine, fluorine, or bromine), Rb and Rc are each independently hydrogen or a hydrocarbyl substituent having about 1 to about 10 carbon atoms, where each hydrocarbyl substituent is optionally substituted with one or more oxygen, nitrogen, and/or halogen atoms (such as chlorine, fluorine, or bromine), and X is selected from NR₂ and OR, wherein each R is independently a linear or branched alkyl group having about 1 to about 10 carbon atoms which is optionally substituted with one or more halogen atoms. The term “optionally contains” means that one or more of the carbon atoms in the aromatic ring may be replaced with a heteroatom (nitrogen or oxygen) and the term “optionally substituted with” means that one or more of the hydrogen atoms in the aromatic ring may be replaced with a heteroatom (oxygen, nitrogen, or halogen). The term “hydrocarbyl” may be understood to include any substituents containing only carbon and hydrogen atoms, including alkyl, alkenyl, alkynyl, aryl, aralkyl groups, etc.

When R′ has formula [I], the total number of carbon atoms in R′ is preferably no more than about 20 carbon atoms, more preferably no more than about 15 carbon atoms, more preferably no more than about 12 carbon atoms, more preferably no more than about 10 carbon atoms, more preferably no more than about 9 carbon atoms, even more preferably no more than about 8 carbon atoms; the number of carbon atoms in R′ is preferably more than about 5 carbon atoms, more preferably more than about 6 carbon atoms, even more preferably more than about 7 carbon atoms. A lower total number of carbon atoms is preferred from the viewpoint of lowering the boiling point of the tin compound and the boiling point of the outgas generated. A higher total number of carbon atoms is preferred from the viewpoint of high thermal stability and hydrophobic property as a resist material. Most preferably the total number of carbon atoms in R′ is about 7 to about 9 from the viewpoint of balancing the resist properties as described above.

The hydrocarbyl substituent preferably contains about 1 to about 10 carbon atoms, more preferably about 1 to about 5 carbon atoms, even more preferably 1 to about 4 carbon atoms, such as, without limitation, primary alkyl groups including methyl, ethyl, n-propyl, n-butyl; secondary alkyl groups including isopropyl, isobutyl, isopentyl; and tertiary alkyl groups including t-butyl, t-amyl, etc., as well as aromatic rings such as phenyl and naphthyl. Each hydrocarbyl substituent is optionally substituted with one or more oxygen, nitrogen, and/or halogen atoms (such as chlorine, fluorine, or bromine).

The carbon bonded to Sn in R′ is preferably a secondary or tertiary carbon and a tertiary carbon is further preferred from the viewpoint of further improving photo-reactivity. The combination of a secondary or tertiary carbon and an aromatic ring in a compound having formula (1) and formula [I] is especially preferred because a synergistic effect between these two features results in a much higher photo-reactivity.

When R′ has formula [I], the aromatic ring in R′ has 3 to about 10 carbon atoms, more preferably about 4 to about 10 carbon atoms. For example, aromatic rings containing 3 carbon atoms include pyrazole and aromatic rings containing 4 carbon atoms include furan and, pyrrole. A preferred aromatic ring containing 6 carbon atoms is phenyl, and a preferred aromatic ring containing 10 carbon atoms is naphthyl. Most preferably, the aromatic ring in R′ is phenyl. A carbon bonded to Sn which is substituted with aromatic rings is preferred from the viewpoint of further improving photo-reactivity due to the aromatic hyperconjugation effect. Phenyl is further preferred from the viewpoint of balancing photo-reactivity and thermal stability.

Preferred R′ substituents include the following, where the wavy line indicates a point of attachment to the Sn atom. Each A substituent is independently hydrogen, a halogen, or a hydrocarbyl substituent having about 1 to about 5 carbon atoms which is optionally substituted with one or more halogen, oxygen, or nitrogen atoms; and Rx, Ry, and Rz are each independently halogen or a hydrocarbyl substituent having about 1 to about 5 carbon atoms which is optionally substituted with one or more oxygen or nitrogen atoms.

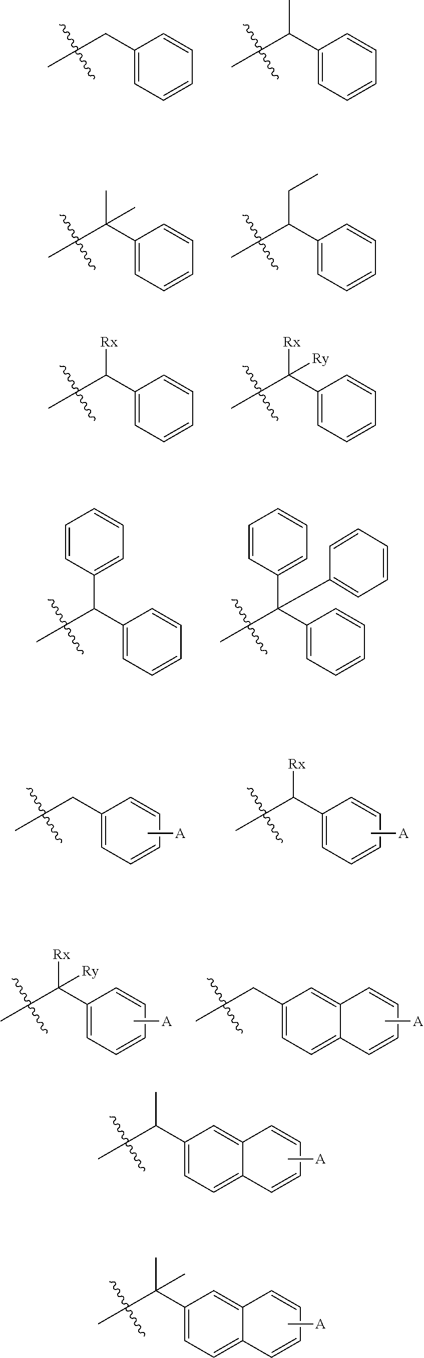

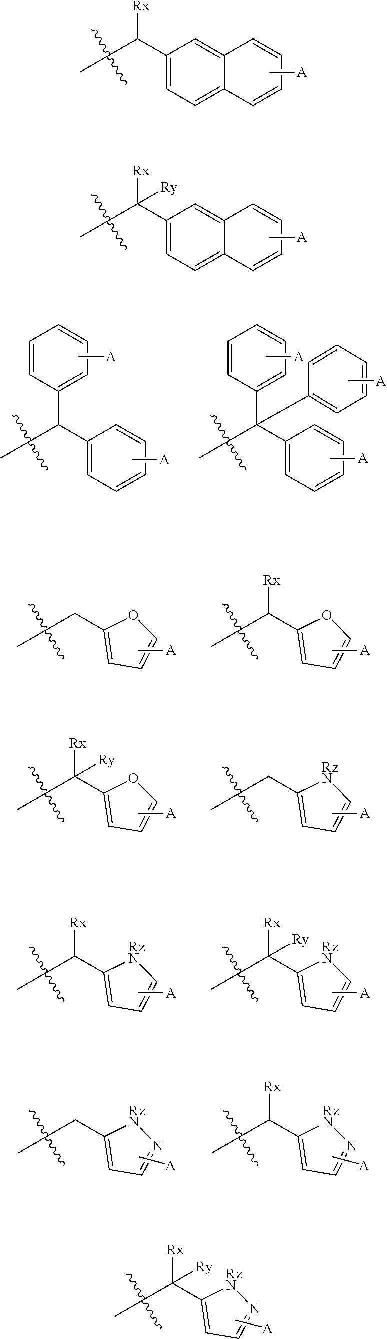

When R′ has formula [I], particularly preferred R′ substituents include, without limitation, 1-phenyl-methyl, 1-phenyl-ethyl, 1-phenyl-propyl, 1-methyl-1-phenyl-ethyl, 1-methyl-1-phenyl-propyl, 1-(2-naphthyl)-methyl, 1-(2-naphthyl)-ethyl, 1-(2-naphthyl)-propyl, 1-methyl-1-(2-naphthyl)-ethyl, 1-methyl-1-(2-naphthyl)-propyl, 1-diphenyl-methyl, 1-triphenyl-methyl, 1-(2-furyl)-methyl, 1-(2-furyl)-ethyl, 1-(2-furyl)-propyl, 1-methyl-1-(2-furyl)-ethyl, 1-methyl-1-(2-furyl)-propyl, 1-(1-methyl-2-pyrrole)-methyl, 1-(1-methyl-2-pyrrole)-ethyl, 1-(1-methyl-2-pyrrole)-propyl, 1-methyl-1-(1-methyl-2-pyrrole)-ethyl, 1-methyl-1-(1-methyl-2-pyrrole)propyl, 1-(1-methyl-5-pyrazole)-methyl, 1-(1-methyl-5-pyrazole)-ethyl, 1-(1-methyl-5-pyrazole)-propyl, 1-methyl-1-(1-methyl-5-pyrazole) ethyl, and 1-methyl-1-(1-methyl-5-pyrazole) propyl.

The term “optionally substituted” means that at least one hydrogen atom in the aromatic ring in R′ or one of the hydrogen atoms in Rb or Rc may be replaced with a substituent such as, for example, a halogen, oxygen, or nitrogen, as explained above. Rb or Rc is preferably a methyl or ethyl group from the viewpoint of balancing when a low boiling point is desirable and when a secondary or tertiary carbon bonded to Sn is preferred for steric reasons.

In some embodiments, the content of a compound having formula (3) is less than about 5 mol %, less than about 3 mol %, less than about 2 mol %, less than about 1 mol %, less than about 0.7 mol %, less than about 0.5 mol %, or less than about 0.1 mol %:

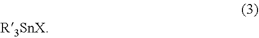

In some embodiments, the content of a compound having formula (4) is less than about 5 mol %, less than about 3 mol %, less than about 2 mol %, less than about 1 mol %, less than about 0.7 mol %, less than about 0.5 mol %, or less than about 0.1 mol %:

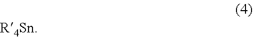

The organometallic tin compounds having formula [1] may be used for the formation of high-resolution EUV lithography patterning precursors and are attractive due to their electron density, Sn—C bond strength, and radical formation, as well as the potential to reduce EUV dose time.

Particularly preferred compounds having formula (1) and formula [I] include, without limitation: 1-phenyl-methyl tris(dimethylamino)tin, 1-phenyl-ethyl tris(dimethylamino)tin, 1-phenyl-propyl tris(dimethylamino)tin, 1-Methyl-1-phenyl-ethyl tris(dimethylamino)tin,1-methyl-1-phenyl-propyl tris(dimethylamino)tin, 1-(2-naphthyl)-methyl tris(dimethylamino)tin, 1-(2-naphthyl)-ethyl tris(dimethylamino)tin, 1-(2-naphthyl)-propyl tris(dimethylamino)tin, 1-methyl-1-(2-naphthyl)-ethyl-tris(dimethylamino)tin,1-methyl-1-(2-naphthyl)-propyl-tris(dimethylamino)tin, 1-diphenyl-methyl-tris(dimethylamino)tin, 1-triphenyl-methyl-tris(dimethylamino)tin, 1-(2-furyl)-methyl tris(dimethylamino)tin, 1-(2-furyl)-ethyl tris(dimethylamino)tin, 1-(2-furyl)-propyl tris(dimethylamino)tin, 1-methyl-1-(2-furyl)-ethyl-tris(dimethylamino)tin, 1-methyl-1-(2-furyl)-propyl-tris(dimethylamino)tin, 1-(1-methyl-2-pyrrole)-methyl tris(dimethylamino)tin, 1-(1-methyl-2-pyrrole)-ethyl tris(dimethylamino)tin, 1-(1-methyl-2-pyrrole)-propyl tris(dimethylamino)tin, 1-methyl-1-(1-methyl-2-pyrrole)-ethyl-tris(dimethylamino)tin, 1-methyl-1-(1-methyl-2-pyrrole)-propyl-tris(dimethylamino)tin, 1-(1-methyl-5-pyrazole)-methyl tris(dimethylamino)tin, 1-(1-methyl-5-pyrazole)-ethyl tris(dimethylamino)tin, 1-(1-methyl-5-pyrazole)-propyl tris(dimethylamino)tin, 1-methyl-1-(1-methyl-5-pyrazole)-ethyl-tris(dimethylamino)tin, and 1-methyl-1-(1-methyl-5-pyrazole)-propyl-tris(dimethylamino)tin.

Among these compounds, those having tertiary carbon atoms bonded to tin are preferred in terms of EUV sensitivity, whereas those having secondary carbons bonded to tin are preferred in terms of stability.

### Methods of Synthesis

Aspects of the disclosure additionally relate to methods for synthesizing the high purity tin compounds having formula (1) or formula (1′) as described above which are suitable for use in the microelectronic industry and which preferably contain low levels of diorgano tin compounds having formula (2) and (2′) and tin compounds having formula (5) and (5′). One method involves the reaction of a compound containing an R′ or R″ group with a compound having formula SnX₄, where X is OR or NR₂. A second method involves the reaction of a compound containing an OR or NR₂ group with a compound having formula R′SnY₃ or R″ SnY₃, where Y is a reactive ligand. A third method involves first reacting a metal compound containing an alkali metal M and a ligand X (NR₂ or OR) with a compound having formula SnY₂ (where Y is a reactive ligand) to form a compound having formula MSnX₃, followed by reacting the compound having formula MSnX³ with a compound R′Z or R″Z, where Z is a halogen atom. These methods will be described in further detail below. If desired, following initial purification, the level of diorgano tin compound and other minor impurities may be further reduced using fractional distillation.

¹¹⁹Sn NMR spectroscopy is ideally suited to the quantitative analysis of monoorgano tin compounds (containing both alkenyl and alkynyl substituents) due to its high sensitivity to small structural changes and large spectral range of 6500 ppm (see Davies et al., Eds.; Tin Chemistry: Fundamentals, Frontiers, and Applications; Wiley (2008)). This allows for easy identification and quantification of monoorgano tin compounds and their impurities because ¹¹⁹Sn resonances are highly resolved. ¹¹⁹Sn NMR suffers from reduced sensitivity compared to other analytical methods such as GC, HPLC, or ¹H NMR. To improve sensitivity, monoorgano tin compounds are analyzed without dilution, and a large number of spectral acquisitions (2000+) are acquired to measure the low levels of impurities described in this work. Using this approach, detection limits of as low as 0.01 mol % diorgano tin dialkoxides can be achieved.

The ¹¹⁹Sn NMR data described herein were obtained using a method similar to the relative purity method described in J. Med. Chem. (57, 22, 9220-9231 (2014)). ¹¹⁹Sn NMR spectra were acquired using inverse-gated ¹H decoupling with a 400 pulse, one second relaxation delay, and sufficient scans to achieve the required sensitivity. Samples were prepared without dilution in deuterated solvent. Quantitation was performed by integrating all peaks in the spectrum and setting the total peak area to 100. Each peak in the spectrum represents a distinct tin compound and the area of each peak represents the concentration or purity of that compound in mol %.

A first method of synthesizing a monoorgano tin compound having formula (1) or (1′) according to aspects of the disclosure comprises reacting a compound containing an R′ or R″ group with a compound having formula SnX₄, where X, R′, and R″ have been previously defined. An exemplary compound containing an R′ (or R″) group is a Grignard reagent, R′MgZ, where Z is a halogen atom such as the presently preferred bromine. Other compounds containing an R′ group include, without limitation, R′Li, R′Na, R′K, R′ZnZ, R′₂Zn, R′₃Al, and mixtures thereof (with analogous compounds replacing R′ with R″). An exemplary general reaction scheme for this method employing a Grignard reagent is:

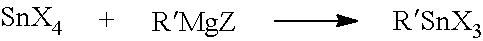

This method is preferable when R′ or R″ has a tertiary carbon bonded to Sn. Because a tertiary carbon has high steric hindrance, R′SnX₃ (or R″SnX₃) will react slowly with R′MgZ (or R″MgZ) and there will be desirable reaction selectivity of mono addition when employing this method.

Preferably, the method involves reacting the compound containing an R′ or R″ group and the SnX₄ compound in an appropriate solvent. Preferred solvents include hydrocarbons (such as, but not limited to, pentane, hexane, heptane, and cyclohexane), aromatics (such as, but not limited to, toluene and xylene), and ethers (such as, but not limited to, THF and Et₂O), and mixtures thereof. Particularly presently preferred are hydrocarbons and aromatics as the main component of the solvent for removing remaining metal salts by filtration. Toluene and hexane are presently the most preferred solvents for easy removal of the product under vacuum at low temperature following the reaction. Additionally, ethers, such as the most preferred THF, are presently preferred solvents because of the high solubility of compounds containing an R′ group (such as R′MgZ) in these types of solvents. It is also preferable to use mixtures of these solvents, such as mixtures of hydrocarbons and/or aromatics with ethers to obtain a high purity product through reaction and purification.

Lower preferred temperatures for the reaction are about −78° C., about −40° C., about −20° C., about −10° C., most preferably about 0° C., as well as all intervening temperatures, and the upper limit of the reaction temperature is preferably about 40° C., about 25° C., about 20° C., or the most preferred upper limit of about 10° C., as well as all intervening temperatures. Thus, the preferred temperature range is about 0° C. to about 10° C. In other embodiments, however, the reaction is preferably performed at room temperature. If the temperature is too low, the reaction rate will be too slow, whereas if the temperature is too high, byproducts will be produced.

A solution containing the compound containing the R′ or R″ group preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %.

It has been found that such dilute concentrations provide effective control of reaction temperature or solubility of the R′ or R″ compound. On the other hand, the productivity is lower in dilute concentrations in industrial conditions.

The concentration of the SnX₄ compound in solution is preferably up to about up to about 30 wt %, more preferably up to about 20 wt %, most preferably up to about 15 wt %. The concentration is preferably greater than about 1 wt %, greater than about 2 wt %, greater than about 3 wt %, even more preferably greater than about 5 wt %.

However, the appropriate solvent and concentrations of the reactants may be determined by routine experimentation.

The molar amount of the R′ or R″ group-containing compound relative to SnX₄ is preferably greater than about 1.0 equivalents, greater than about 1.1 equivalents, greater than about 1.2 equivalents, greater than about 1.3 equivalents, or greater than about 1.4 equivalents. The molar amount of the R′ or R″ group-containing compound relative to SnX₄ is preferably less than about 2.0 equivalents, less than about 1.8 equivalents, less than about 1.6 equivalents, more preferably less than about 1.4 equivalents. If the relative amount of the R′ or R″ group-containing compound is too high, starting materials (SnX₄) may remain. Further, the reaction speed may be too low and the amount of impurities may increase due to side reactions, such as redistribution. If the relative amount of the R′ or R″ group-containing compound is too high, over reaction may occur and poly alkylated byproducts (such as R′₂SnX₂, R′₃SnX, and R′₄Sn, and analogous R″ byproducts) may form. When the boiling point of R′SnX₃ is close to the boiling points of R′₂SnX₂ and SnX₄, it is especially important to reduce the concentrations of R′₂SnX₂ and SnX₄ because of the difficulty of purification by distillation.

Following the reaction of the two components, the reaction mixture is worked up and purified using methods well known in the art to produce the compound having formula (1) or (1′).

An exemplary reaction scheme for this method when R″ is a cyclic compound is shown here:

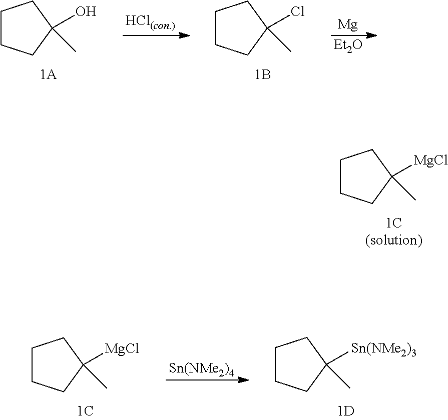

An exemplary reaction scheme for this method when R′ is an aromatic compound is shown here:

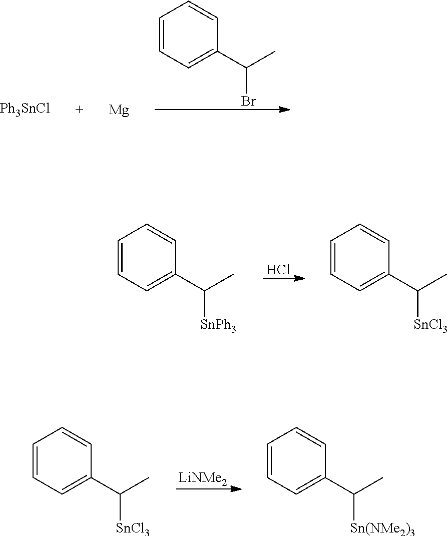

An exemplary reaction scheme for this method when R′ is an ether compound is shown here:

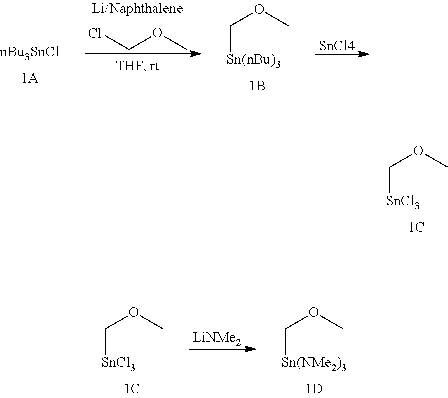

### Second Method

A second method of synthesizing a monoorgano tin compound having formula (1) or (1′) according to aspects of the disclosure comprises reacting a compound containing an OR or NR₂ group with a compound having formula R′SnY₃ or R″SnY₃, where Y is a reactive ligand (which may also be understood to be a leaving group) such as the presently preferred halogen, NR₂, or OR, where R has been previously defined. Preferred halogen atoms include chlorine, bromine, and fluorine. Most preferably, the R′SnY₃ or R″SnY₃ compound is R′SnCl₃ (R″SnCl₃). The R′SnY₃ (R″ SnY₃) compound may be purchased commercially or prepared, such as, for example, by the redistribution reaction of R′₄Sn (R″₄Sn) and SnCl₄ to produce R′SnCl₃ (R″SnCl₃). This method is preferable when R′ or R″ has a secondary carbon bonded to Sn in view of the high stability and easy preparation of R′SnY₃ or R″SnY₃.

An exemplary reaction scheme for this method is:

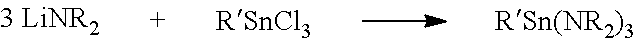

Exemplary compounds containing an OR or NR₂ group include HOR, LiOR, NaOR, KOR, Mg(OR)₂, Zn(OR)₂, Al(OR)₃, HNR₂, LiNR₂, NaNR₂, KNR₂, Mg(NR₂)₂, Zn(NR₂)₂, and Al(NR₂)₃. Among these compounds, reagents containing Li, Na, and K are preferred in terms of reactivity; HOR is preferred when Y in R′SnY₃ is NR₂.

Preferably, the method involves reacting the compound containing an OR or NR₂ group and the R′SnY₃ or R″ SnY₃ compound in an appropriate solvent. Preferred solvents include hydrocarbons (such as, but not limited to, pentane, hexane, heptane, and cyclohexane), aromatics (such as, but not limited to, toluene and xylene), and ethers (such as, but not limited to, THF and Et₂O), and mixtures thereof. Particularly presently preferred are hydrocarbons and aromatics as the main component of the solvent for removing remaining metal salts by filtration. Toluene and hexane are presently the most preferred solvents for easy removal of the product under vacuum at low temperature following the reaction. Additionally, ethers, such as the most preferred THF, are presently preferred solvents because of the high solubility of compounds containing an OR or NR₂ group in these types of solvents. Alcohols (MeOH, EtOH, especially ROH) are also preferred solvents for compounds containing an OR group. It is also preferable to use mixtures of these solvents, such as mixtures of hydrocarbons and/or aromatics with ethers and/or alcohols to obtain a high purity product through reaction and purification.

Lower preferred temperatures for the reaction are about −78° C., about −40° C., about −20° C., about −10° C., most preferably about 0° C., as well as all intervening temperatures, and the upper limit of the reaction temperature is preferably about 40° C., about 25° C., about 20° C., or the most preferred upper limit of about 10° C. as well as all intervening temperatures. Thus, the preferred temperature range is about 0° C. to about 10° C. If the temperature is too low, the reaction rate will be too slow, whereas if the temperature is too high, byproducts will be produced.

A solution containing the OR or NR₂ compound preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %.

It has been found that such dilute concentrations provide effective control of reaction temperature or solubility of the OR or NR₂ compound. On the other hand, the productivity is lower in dilute concentrations in industrial conditions.

The concentration of the R′SnY₃ or R″SnY₃ compound in solution is preferably up to about up to about 30 wt %, more preferably up to about 20 wt %, most preferably up to about 15 wt %. The concentration is preferably greater than about 1 wt %, greater than about 2 wt %, greater than about 3 wt %, even more preferably greater than about 5 wt %. However, the appropriate solvent and concentrations of the reactants may be determined by routine experimentation.

The molar amount of the OR or NR₂ compound relative to R′SnY₃ or R″ SnY₃ is preferably greater than about 3.0 equivalents, greater than about 3.05 equivalents, greater than about 3.09 equivalents, greater than about 3.10 equivalents, or greater than about 3.15 equivalents. If the relative amount of the OR or NR₂ compound is too low, the reaction speed may be too low and the amount of impurities may increase due to side reactions such as redistribution.

Following reaction of the two components, the reaction mixture is worked up and purified using methods well known in the art to produce the compound having formula (1) or (1′).

### Third Method

A third method of synthesizing a monoorgano tin compound having formula (1) according to aspects of the disclosure comprises first reacting a metal compound containing an alkali metal M and a ligand X (NR₂ or OR) with a compound having formula SnY₂ to form a compound having formula MSnX₃, where Y is a reactive ligand (which may also be understood to be a leaving group) such as the presently preferred halogen, NR₂, or OR, where R has been previously defined, followed by reacting the compound having formula MSnX₃ with a compound R′Z, where Z is a halogen atom. Preferred halogen atoms include chlorine, bromine, and fluorine. Most preferably, the SnY₂ compound is SnCl₂ in terms of reactivity and stability. Preferably the compound containing M and X is selected from LiNR₂, NaNR₂, K NR₂, LiOR, NaOR, KOR. Preferably MSnX₃ is selected from LiSn(NR₂)₃, NaSn(NR₂)₃, KSn(NR₂)₃, LiSn(OR)₃, NaSn(OR)₃, and KSn(OR)₃. Among these compounds, LiSn(NR₂)₃ and LiSn(OR)₃ are preferred for stability in preparation.

An exemplary reaction scheme for this method is:

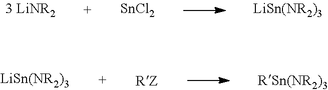

Preferably, the first step involves reacting the compound containing M and X and the SnY₂ compound in an appropriate solvent. Preferred solvents include hydrocarbons (such as, but not limited to, pentane, hexane, heptane, and cyclohexane), aromatics (such as, but not limited to, toluene and xylene), and ethers (such as, but not limited to, THF and Et₂O), and mixtures thereof. Most preferred solvents are ethers, such as THF to prepare MSnX₃ which is an Sn anion species and stable under coordination by ether solvent.

Lower preferred temperatures for the reaction are about −78° C., about −40° C., about −20° C., about −10° C., most preferably about 0° C., as well as all intervening temperatures, and the upper limit of the reaction temperature is preferably about 100° C., about 90° C., or about 80° C., as well as all intervening temperatures. Thus, the preferred temperature range is about 0° C. to about 80° C. If the temperature is too low, the reaction rate will be too slow, whereas if the temperature is too high, byproducts will be produced.

A solution containing the compound containing M and X preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %. It has been found that such dilute concentrations provide effective control of reaction temperature or solubility of the compound containing M and X. On the other hand, the productivity is lower in dilute condition in industrial conditions.

The molar amount of the compound containing M and X relative to the amount of SnY₂ is preferably greater than about 3.0 equivalents, greater than about 3.05 equivalents, greater than about 3.09 equivalents, greater than about 3.10 equivalents, or greater than about 3.15 equivalents. If the relative amount is too low, the reaction speed may be too low and the amount of impurities may increase due to side reactions.

Preferably, the second step involves reacting the MSnX₃ compound and the R′Z or R″Z compound in an appropriate solvent. Preferred solvents include hydrocarbons (such as, but not limited to, pentane, hexane, heptane, and cyclohexane), aromatics (such as, but not limited to, toluene and xylene), and ethers (such as, but not limited to, THF and Et₂O), and mixtures thereof. Particularly presently preferred are hydrocarbons and aromatics as the main component of the solvent for removing remaining metal salts by filtration. Toluene and hexane are presently the most preferred solvents for easy removal of the product under vacuum at low temperature following the reaction. Additionally, ethers, such as the most preferred THF, are presently preferred solvents because of the high solubility of the reactants in these types of solvents. It is also preferable to use mixtures of these solvents, such as mixtures of hydrocarbons and/or aromatics with ethers to obtain a high purity product through reaction and purification.

Lower preferred temperatures for the reaction are about −78° C., about −40° C., about −20° C., about −10° C., most preferably about 0° C., as well as all intervening temperatures, and the upper limit of the reaction temperature is preferably about 100° C., about 90° C., or the most preferred upper limit of about 80° C., as well as all intervening temperatures. Thus, the preferred temperature range is about 0° C. to about 80° C. If the temperature is too low, the reaction rate will be too slow, whereas if the temperature is too high, byproducts will be produced.

A solution containing the R′Z or R″Z compound preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %. It has been found that such dilute concentrations provide effective control of reaction temperature. On the other hand, the productivity is lower in dilute condition in industrial conditions.

The molar amount of the R′Z or R″Z compound relative to MSnX₃ is preferably greater than about 1.0 equivalents, greater than about 1.1 equivalents, greater than about 1.2 equivalents, or greater than about 1.25 equivalents. If the relative amount is too low, the reaction speed may be too low and the amount of impurities may increase due to side reactions.

Following reaction of the two components, the reaction mixture is worked up and purified using methods well known in the art to produce the compound having formula (1) or (1′).

### All Methods

In all of the methods described herein, the reactants are preferably added in a dropwise fashion to control the exothermic reaction and the method steps are preferably performed in an inert atmosphere, such as nitrogen or argon. The reactants may be added neat (without solvent) and it is preferable to add the reactants quickly to achieve high productivity. However, it is preferable to perform the reactions in solvent to control the exothermic reaction. Appropriate solvents include, as previously explained, without limitation, hydrocarbons (such as, but not limited to, pentane, hexane, heptane, and cyclohexane), aromatics (such as, but not limited to, toluene and xylene), and ethers (such as, but not limited to, THF and Et₂O), and mixtures thereof. In some cases, most preferred solvents are ethers, such as THF.

After completing the reaction, the reaction mixtures are allowed to slowly warm to room temperature, such as over a period of about four hours, and then stirred for an additional period of time at room temperature, such as for about two to four hours. The reaction mixture is then filtered, such as through celite, to remove the metal byproduct. Other means of filtration which are known in the art may also be employed. The resulting salt is then rinsed, such as with anhydrous hexanes, and the solvent is removed under reduced pressure by means known in the art to produce a crude product.

In all three of the methods described above, the crude product is distilled, such as at less than about 10 torr, preferably less than about 0.5 torr to yield the desired product containing the compound having formula (1) or (1′) having a purity of greater than about 95 mol % and no more than about 5 mol % of the diorgano tin compound having formula (2) or (2′). In some embodiments, the compound having formula (1) or (1′) contains no more than about 5 mol % of the tin compound having formula (5) or (5′). The appropriate distillation conditions may be determined on a case-by-case basis depending on the desired product using routine experimentation. In preferred embodiments, the content of diorgano tin compound having formula (2) or (2′) is less than about 4 mol %, less than about 3 mol %, less than about 2 mol %, less than about 1 mol %, less than about 0.5 mol %, less than about 0.1 mol %, or even lower, as described above; the desired compound may also be obtained in high yield. In preferred embodiments, the content of tin compound having formula (5) or (5′) is less than about 4 mol %, less than about 3 mol %, less than about 2 mol %, less than about 1 mol %, less than about 0.5 mol %, less than about 0.1 mol %, or even lower, as described above; the desired compound may also be obtained in high yield.

All of the method steps are preferably performed substantially without light exposure. Shielding may be accomplished by any method known in the art such as, for example, employing light-shielded containers such as amber glass, metal (SUS) containers, wrapping the container with a light-shielding cover such as cloth, foil or film, using light-shielding coatings, or performing the reactions in a dark room.

The distillation may be performed using a stainless steel column packed with a stainless steel packing material. Alternatively, the distillation may be performed in a light-shielded apparatus comprising glass such as glass equipment, glass-lined equipment, glass-coated equipment, etc. Shielding may be accomplished by any method known in the art such as, for example, employing light-shielded containers such as amber glass, metal (SUS) containers, wrapping the container with a light-shielding cover such as cloth, foil or film, using light-shielding coatings, or performing the distillation in a dark room.

In preferred embodiments, the methods described herein are performed in a solvent containing greater than about 50% by volume of a hydrocarbon solvent and/or an aromatic solvent such as, without limitation, those exemplified above. In preferred embodiments, the methods described herein are performed substantially without light exposure. In preferred embodiments, the solvents and reactants are dehydrated prior to use.

### Grignard Methods

Additional aspects of the disclosure relate to a method for producing a monoalkyltin triamide having formula (11) by reacting an alkylmagnesium reagent having formula (8) or (9) with a tin tetraamide having formula (10) in the presence of a first solvent containing an ether solvent having a boiling point of at least 40° C., and distilling off the ether solvent in the presence of a second solvent having an octanol/water partition coefficient greater than the ether solvent and greater than 1.0:

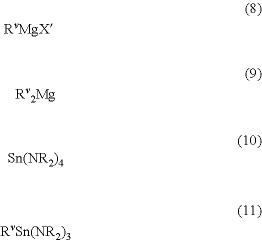

In these formulas, R^{v} is a linear, branched, or cyclic hydrocarbyl group having 1 to 30 carbon atoms which is optionally substituted with one or more oxygen atoms, nitrogen atoms, silicon atoms, or sulfur atoms, each R is independently a linear or branched alkyl group having about 1 to 10 carbon atoms which is optionally substituted with one or more halogen atoms and multiple Rs may be bonded to each other to form a cyclic structure, and X′ is chlorine, bromine, or iodine.

A further method for producing a monoalkyltin triamide having formula (11) involves reacting an alkylmagnesium reagent having formula (8) or (9) with a tin tetraamide having formula (10) in the presence of a first solvent containing an ether solvent having a boiling point of at least 40° C., mixing a second solvent having an octanol/water partition coefficient greater than the ether solvent and greater than 1.0, and removing a solid containing a magnesium salt by filtration.

Essentially, these methods of producing a monoalkyltin triamide (11) involve reacting tin tetraamide (10), a raw material tin compound, with an alkyl magnesium reagent (8) or (9) under specific reaction conditions. This method has been widely used due to the simple production process. However, diethyl ether, which is usually used as a solvent in this reaction, has a low flash point and a low boiling point, which is disadvantageous for an industrial production method in which a large amount of a solvent is used.

### Compounds

The target compound is a monoalkyltin triamide compound represented by formula (11) but the synthesis may also generate by-products and decomposition products may also be generated during storage. These impurities may be separated and purified by distillation or other methods to obtain monoalkyltin triamide with high purity.

In formula (11), R^{v} represents a linear, branched, or cyclic hydrocarbon group having about 1 to 30 carbon atoms, which may have an oxygen atom, a nitrogen atom, a silicon atom, or a sulfur atom. R represents an alkyl group having 1 to 10 carbon atoms, which may have a halogen atom, Rs may be the same as or different from each other, and may be bonded to each other to form a cyclic structure.

Substituent R^{v} is a hydrocarbon group having about 1 to 30 carbon atoms, which may have an oxygen atom, a nitrogen atom, a silicon atom, or a sulfur atom. In consideration of ease of the elimination of the R^{v} group and the vaporization of the generated R^{v} group component during EUV exposure, the upper limit of the number of carbon atoms in R^{v} is 30 or less, preferably 20 or less, and more preferably 10 or less. In addition, from the viewpoint of the stability of the eliminated components, the lower limit thereof is 1 or greater, preferably 2 or greater, and more preferably 3 or greater.

In addition, substituent R^{v} may have a heteroatom such as oxygen, nitrogen, silicon, or sulfur, and, in such cases, decomposability with respect to EUV light is high, and resist performance, such as sensitivity, may be improved. Meanwhile, a side reaction may be induced during the production depending on the substitution position of the heteroatom, and the product may be unstable. Therefore, a hydrocarbon group which may be substituted with an oxygen atom is preferable, and a hydrocarbon group which does not have a heteroatom is more preferable.

Preferred specific examples of the substituent R^{v} include an alkyl group such as a methyl group, an ethyl group, a propyl group, an isopropyl group, a butyl group, an isobutyl group, a sec-butyl group, a t-butyl group, a pentyl group, a hexyl group, a cyclopentyl group, a cyclohexyl group, or a 1-methyl-1-cyclopentyl group; an aryl group such as a phenyl group, a tolyl group, a mesityl group, or a naphthyl group; an aralkyl group such as a benzyl group, a phenethyl group, an α-methylbenzyl group, or a 2-phenyl-2-propyl group; an alkenyl group such as a vinyl group, a 1-propenyl group, an allyl group, or a 3-butenyl group; an alkynyl group such as an ethynyl group or a 2-propynyl group an alkyl group having an oxygen atom such as a 1-ethoxy-1-ethyl group, a 1-methoxy-1-ethyl group, or a 1-methyl-1-methoxy-1-ethyl group; and an alkyl group having a nitrogen atom such as a 1-dimethylamino-1-ethyl group or a 1-methyl-1-methylamino-1-ethyl group.

R^{v} may be classified into a primary substituent R^{x}, a secondary substituent R^{y}, or a tertiary substituent R^{z}, and is typically an alkyl group or an aralkyl group. Preferred examples of each of the classified substituents include a primary substituent R^{x} such as a methyl group, an ethyl group, an n-propyl group, an n-butyl group, an isobutyl group, a benzyl group, or a phenethyl group, a secondary substituent Ry such as an isopropyl group, a sec-butyl group, a cyclopentyl group, a cyclohexyl group, a cycloheptyl group, or an α-methylbenzyl group, and a tertiary substituent R^{z} such as a t-butyl group, a t-amyl group, a 1-methyl-1-cyclopropyl group, a 1-methyl-1-cyclobutyl group, a 1-methyl-1-cyclopentyl group, a 1-ethyl-1-cyclopentyl group, a 1-methyl-1-cyclohexyl group, or a 2-phenyl-2-propyl group.

Each of the substituents may exhibit different characteristics when the tin compound is used as a resist material depending on the kind of the substituent. Hereinafter, using an alkyl group as a representative example, from the viewpoint of sensitivity (photoreactivity) when each of the substituents is used for a preferable EUV resist, a secondary alkyl group R^{y} and a tertiary alkyl group R^{z} which are easily eliminated are preferable. From the viewpoint of hydrophobicity, a tertiary alkyl group R^{z} is preferable since R^{z} can increase hydrophobicity in the vicinity of a tin atom so that the solubility is controlled, and a secondary alkyl group R^{y} may be preferable when the hydrophobicity is extremely high.

In addition, several methods of producing a monoalkyltin triamide compound are known, and in particular, when the R^{v} group is tertiary, the compound is unlikely to be produced except for a synthesis method of using tin tetraamide as a raw material tin compound as described herein, and thus the production method of the present invention is preferably used when the substituent R^{v} is tertiary.

Among these, a 1-alkyl-1-cycloalkyl group such as a 1-methyl-1-cyclopentyl group is tertiary and has a cyclic structure, and thus, when a Sn—C bond is cleaved, it is presumed to have an effect of stabilizing a radical and an effect of releasing steric hindrance, and the dissociation energy of the Sn—C bond is reduced, which is preferable from the viewpoint of sensitivity.

The structure of the substituent R is not limited as long as NR₂ can be hydrolyzed, but the substituent is a hydrocarbon group having 1 to 10 carbon atoms, which may usually have a halogen, and preferably an alkyl group which may have a halogen atom. The monoalkyltin triamide (11) has six substituents R, which may be the same as or different from each other. In addition, the substituents may be bonded to each other to form a cyclic structure. Preferred specific examples of the substituent R include a methyl group, an ethyl group, a propyl group, an isopropyl group, a butyl group, an isobutyl group, a sec-butyl group, a t-butyl group, a t-amyl group, a 2-methyl-3-pentyl group, a 2,2,2-trifluoroethyl group, and a trifluoromethyl group. Examples of NR₂ include a 1-pyrrolidinyl group having a form in which two substituents are bonded to each other on nitrogen to form a 5-membered ring. Among these, NR₂ preferably represents a dimethylamino group, a diethylamino group, a methylethylamino group, or a 1-pyrrolidinyl group and particularly preferably a dimethylamino group. Due to these preferable substituents, the molecular weight of the target compound is not excessively large, the target compound is suitable for distillation and purification, and the target compound has a small steric hindrance. Therefore, the hydrolysis performance is satisfactory when the tin compound is used as a resist material.

### Physical Properties of Monoalkyltin Triamide (11)

The structure and the physical properties of the monoalkyltin triamide (11) (hereinafter, also referred to as “tin compound (11)”) are not particularly limited as long as the monoalkyltin triamide (11) is in the above-described ranges, but when the monoalkyltin triamide (11) is used as an EUV resist material, it is preferable that the monoalkyltin triamide (11) has the following physical properties.

### Boiling Point

When using the tin compound (11), the boiling point at 1 torr is preferably 300° C. or lower, more preferably 250° C. or lower, still more preferably 200° C. or lower, and particularly preferably 150° C. or lower. The lower limit of the boiling point at 1 torr is usually 0° C. or higher, preferably 10° C. or higher, and more preferably 20° C. or higher. It is preferable that the boiling point thereof is low from the viewpoint that distillation can be carried out at a low temperature and vapor deposition is easy when the tin compound is used as a resist material. However, when the boiling point is extremely low, it is difficult to perform a process accompanied by vapor deposition or a reaction at a high temperature when the compound is used as an EUV resist, and the thermal stability of a film to be molded is insufficient, which may cause problems such as volatilization or scattering of components and outgas.

### Molecular Weight

The molecular weight of the tin compound (11) is preferably 500 or less, more preferably 400 or less, and still more preferably 350 or less. The lower limit is preferably 270 or greater, more preferably 280 or greater, and still more preferably 300 or greater. When the molecular weight is extremely high, the boiling point is extremely high, and thus vapor deposition or the like may be difficult when the compound is used as an EUV resist. When the molecular weight is extremely low, the boiling point is extremely low, and thus a process accompanied by vapor deposition or a reaction at a high temperature is difficult to perform, or the thermal stability of a film to be molded is insufficient, which may cause problems such as volatilization or scattering of components or outgas.

Difference in Molecular Weight Between Substituent R^{v} and Substituent NR₂

In the production method of the present disclosure, impurities (tin compounds (10) or (12)) described below may be generated. Therefore, in consideration of distilling and purifying the crude product after production, it is preferable that a difference in molecular weight between the target compound and the impurities is a certain value or greater. The difference in molecular weight between the target compound (11) and the impurity (10) or (12) is determined by the difference in molecular weight between the substituent R^{v} and the substituent NR₂ (in the present specification, the molecular weight of the substituent means the sum of the atomic weights of the atoms constituting the substituent). Therefore, the difference in molecular weight between the substituent R and the substituent NR₂ is preferably 5 or greater, more preferably 10 or greater, and particularly preferably 20 or greater. Meanwhile, the difference in mass of various outgases generated when the compound is used as a resist tends to be reduced by reducing the difference in molecular weight between the substituent R and the substituent NR₂, and setting the conditions for the EUV process is easy to perform. Therefore, the molecular weight difference is preferably 100 or less, more preferably 70 or less, and particularly preferably 50 or less.

### Tin Compound as Impurity

When producing the monoalkyltin triamide (11), impurities containing several tin atoms may be produced. The tin compounds as such impurities are not particularly limited, and examples of representative tin compounds include tin compound represented by formulas (10) or (12). Here, the substituents R^{v} and R are the same as in the case of the above-described tin compound (11).

The method of producing monoalkyltin triamide (11) of the present invention is a method in which the tin compound (10) is used as a starting material, and the alkylation is carried out by reacting the tin compound (10) with an alkyl magnesium reagent (8) or (9). Therefore, in a case when the alkyl magnesium reagent is excessive with respect to the tin compound (10), a tin compound (12) is likely to be generated, and when the amount of the alkyl magnesium reagent is extremely small, the tin compound (10) as a raw material is likely to remain.

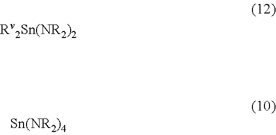

In addition, when the monoalkyltin triamide (11) is R^{v}Sn(NMe₂)₃, a tin compound having formula (13) may be generated as an impurity. Here, the substituent R^{v} is the same as in the case of the above-described monoalkyltin triamide (11).

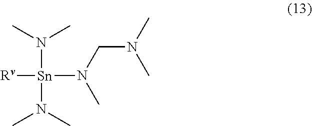

This tin compound (13) is considered to be generated by photodecomposition or thermal decomposition of the monoalkyltin triamide (11).

### Purity of Monoalkyltin Triamide

As described above, in the present reaction, there is a possibility that the above-described tin compounds (10), (12), and (13) are present, in addition to the target tin compound (11). The purity of the tin compound (11) after the reaction is preferably 50% by mole or greater, more preferably 70% by mole or greater, and particularly preferably 90% by mole or greater in terms of tin atom.

In addition, the purity of the tin compound (11) after distillation and purification is usually 95% by mole or greater, preferably 98% by mole or greater, more preferably 99% by mole or greater, and particularly preferably 99.5% by mole or greater. Meanwhile, the contained amount of each of the tin compounds (10), (12), and (13) as impurities is preferably 1% by mole or less, more preferably 0.5% by mole or less, particularly preferably 0.1% by mole, and most preferably 0.01% by mole or less.

Among these, when the content of the tin compound (12) is extremely high, the crosslinking property and the toughness are degraded when the compound is used as an EUV lithography resist. Further, the tin compound (12) may cause outgas when the photoresist is irradiated with extreme ultraviolet rays, and in an extreme situation, this may lead to degradation of a multilayer-coated optical component, which is extremely expensive. Therefore, the content of the tin compound (12) is preferably the detection limit or less.

The purity of the tin compound (11) is preferably high, but when the amount of all impurities is intended to be minimized, the productivity may be deteriorated, and thus the purity may be adjusted based on the balance with the required specifications.

Here, the unit mol % in terms of the tin atoms representing the above-described purity is a ratio of the number of tin atoms of the target compound to the number of tin atoms of all compounds (including unidentified compounds) having tin atoms. Practically, the value is calculated using the total of the integrated values of all the observed peaks as the denominator and using the integrated value of the peak of the target compound as the numerator according to ¹¹⁹Sn-NMR.

According to this calculation method, only compounds having a tin atom are a calculation target. For example, even when monoalkyltin triamide (11) is produced by the present production method and an additive or a solvent is added according to each application, the purity in terms of the tin atom can be measured by the ¹¹⁹Sn-NMR measurement.

When using ¹¹⁹Sn-NMR as an analysis method, the sensitivity can be improved by performing the analysis without diluting the tin compound and employing a large number of integration times (1000 times or more, preferably 5000 times or more, and more preferably 10000 times or more), a sufficient relaxation time (0.8 seconds or longer, preferably 0.9 seconds or longer, and more preferably 1 second or longer), and reverse gate decoupling. As a result, the detection limits for the tin compounds (10), (12), and (13) as impurities can reach 0.01% by mole by using these methods. In addition, when the sensitivity of the measurement peak is still insufficient, the sensitivity of detection may be further increased by using high-sensitivity NMR (for example, using a cryogenic probe with a 600 MHz NMR), and a detection of 0.001% by mole may be achieved.

### Raw Material Tin Compound

The raw material tin compound used in the present invention is a tin tetraamide compound represented by formula (10).

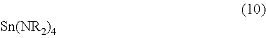

In formula (10), R represents an alkyl group having 1 to 10 carbon atoms, which may be substituted with a halogen atom. Rs may be the same as or different from each other, and may be bonded to each other to form a cyclic structure.

Preferred examples of the substituent R are the same as in the case of the above-described monoalkyltin triamide (11).

### Alkyl Magnesium Reagent

The alkyl magnesium reagent used in the present invention is a compound represented by formula (8) or (9).

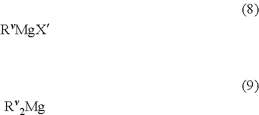

In formula (1) or (2), R^{v} represents a linear, branched, or cyclic hydrocarbyl group having 1 to 30 carbon atoms which may be substituted with an oxygen atom, a nitrogen atom, a sulfur atom, or a silicon atom. In addition, X′ represents chlorine, bromine, or iodine.

Preferred examples of the substituent R^{v} are the same as in the case of the above-described monoalkyltin triamide (11). Among the alkyl magnesium reagents, the compound (8) is preferable, which has been widely used as a Grignard reagent. In addition, X′ represents preferably chlorine or bromine and more preferably chlorine. When X′ represents chlorine, the nucleophilicity as an alkylating agent is high, and thus the substitution reaction is satisfactory even in a case of a tertiary alkyl group.

### Methods

### Reaction Conditions

### Preparation of Alkyl Magnesium Reagent

In the method of producing monoalkyltin triamide of the present invention, first, an alkyl magnesium reagent is prepared by reacting an alkyl halide with magnesium using an ether-based solvent as described below.

Here, an example in which tetrahydrofuran is used as an ether-based solvent and 1-methyl-1-chlorocyclopentane is used as an alkyl halide is described. By this reaction, 1-methyl-1-cyclopentylmagnesium chloride can be prepared as an alkyl magnesium reagent.

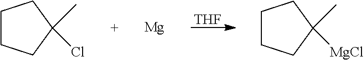

As magnesium used in the magnesium reagent, typically, metal magnesium in a scraped form is used. An ether-based solvent described below is added thereto, and alkyl halide is added thereto while the mixture is stirred. In addition, in order to activate magnesium and easily carry out the reaction with an alkyl halide, a small amount of an activator such as iodine or 1,2-dibromoethane may be added. In addition, the alkyl magnesium reagent itself can be used as the activator.

The amount of the alkyl halide to be used is usually 0.5 to 1 mol, preferably 0.8 to 1 mol, and more preferably 0.9 to 0.99 mol with respect to 1 mol of magnesium.

The reaction temperature is usually 0° C. to the boiling point of the solvent to be used and preferably 30° C. to the boiling point of the solvent to be used. Since the reaction is an exothermic reaction, it is preferable to adjust the addition rate of the alkyl halide or to adjust the reaction temperature by using a cooling device. The reaction time is usually 30 minutes to 24 hours and preferably 1 to 10 hours. Since the obtained alkyl magnesium reagent reacts with water and is decomposed, it is preferable to carry out the reaction in an inert gas atmosphere such as nitrogen or argon.

The concentration of the alkyl magnesium in the alkyl magnesium reagent solution that has been adjusted as described above is usually 3% to 35% by mass, preferably 5% to 30% by mass, more preferably 7% to 25% by mass, and particularly preferably 7% to 15% by mass. The stability of the liquid may be worsened in a case where the concentration is extremely high, and the reaction rate may slow down in the next reaction in a case where the concentration is extremely low.

### First Solvent: Solvent Used for Alkyl Magnesium Reagent

In the present production method, in the reaction between the raw material tin compound (10) and the alkyl magnesium (8) or (9), at least an ether-based solvent is used. This is because the alkyl magnesium reagent can be prepared in an ether-based solvent and is stably present. Since the ether-based solvent has a property of easily igniting, in a case of using the ether-based solvent in a large amount industrially, a solvent having a normal boiling point of 40° C. or higher is usually used from the viewpoint of safety. Examples of such an ether-based solvent include t-butyl methyl ether, diisopropyl ether, dibutyl ether, dimethoxyethane, tetrahydrofuran, 2-methyltetrahydrofuran, 4-methyltetrahydropyran, cyclopentyl methyl ether, and dioxane.

Among these ether-based solvents, a solvent having a boiling point (in particular, a boiling point at normal pressure unless otherwise noted, the same applies hereinafter) of 40° C. or higher is used, but from the viewpoint of safety, the boiling point thereof is preferably 50° C. or higher and more preferably 55° C. or higher. In addition, in a case where the boiling point is extremely high, the productivity of the operation after the reaction may decrease, and thus the boiling point thereof is preferably 150° C. or lower, more preferably 110° C. or lower, and particularly preferably 90° C. or lower. From the viewpoint of having an appropriate boiling point and stabilizing the alkyl magnesium reagent, the ether-based solvent is preferably tetrahydrofuran, dimethoxyethane, or 4-methyltetrahydropyran and particularly preferably tetrahydrofuran. In addition, the boiling point of the ether-based solvent used for the reaction is lower than the boiling point of the monoalkyltin triamide obtained by the reaction preferably by 30° C. or higher and more preferably 50° C. or higher. In a case where the difference in boiling point is extremely small, distillation purification may be difficult. From the viewpoint of safety, the flash point of the ether-based solvent is preferably −30° C. or higher and more preferably −25° C. or higher. The ether-based solvent may be used alone or in combination of a plurality of ethers.

The octanol-water partition coefficient of the ether-based solvent is usually 0.25 or greater, preferably 0.27 or greater, and more preferably 0.3 or greater. In addition, the octanol-water partition coefficient thereof is usually 3.5 or less, preferably 2.5 or less, and more preferably 2.0 or less. The viscosity is likely to increase after the reaction when the octanol-water partition coefficient of the ether solvent is extremely low, and the alkyl magnesium reagent is unstabilized when the octanol-water partition coefficient is extremely high.

As the solvent used for the alkyl magnesium reagent, the above-described ether-based solvent may be used alone, or in combination with another solvent. However, a solvent having reactivity with an alkyl magnesium reagent cannot be used. Therefore, the solvent is preferably an aliphatic hydrocarbon-based solvent or an aromatic hydrocarbon-based solvent. Specific examples of the solvent preferably used include pentane, hexane, heptane, octane, nonane, decane, undecane, dodecane, pentadecane, heptadecane, eicosane, docosane, cyclohexane, methylcyclohexane, decalin, benzene, toluene, xylene, mesitylene, 1,4-diethylbenzene, 1,3-dimethylnaphthalene, and diphenylmethane.

When an ether-based solvent and a hydrocarbon-based solvent are used in combination, the proportion of the ether-based solvent is preferably 50% by mass or greater and more preferably 80% by mass or greater.

### Synthesis of Monoalkyltin Triamide

The monoalkyltin triamide (11), which is a target compound obtained by reacting the alkyl magnesium reagent adjusted as described above with the tin tetraamide (10) as shown below can be synthesized.

Here, an example in which 1-methyl-1-chlorocyclopentyl magnesium chloride is used as the alkyl magnesium reagent and tetrakis(dimethylamino)tin (also referred to as “tin tetrakis(dimethylamide)”) is used as the tin tetraamide of the raw material tin compound is described. By this reaction, (1-methyl-1-cyclopentyl) tris(dimethylamino)tin (also referred to as “(1-methyl-1-cyclopentyl)tin tris(dimethylamide)”) can be synthesized as target monoalkyltin triamide.

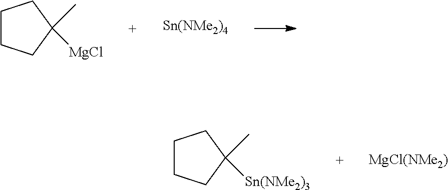

The amount of the alkyl magnesium reagent to be used depends on the difference in boiling point between the tin compound (11) and the tin impurities (the tin compound (10) as a raw material and the excessively added tin compound (12)), and the amount thereof is adjusted so that impurities having a small difference in boiling point are not generated. That is, in a case where the difference in boiling point between the tin compound (11) and the tin compound (10) is smaller, the amount thereof is usually 1 to 1.2 mol and preferably 1 to 1.1 mol with respect to 1 mol of the tin tetraamide. That is, it is preferable to use the alkyl magnesium slightly excessively. Meanwhile, in a case where the difference in boiling point between the tin compound (11) and the tin compound (12) is smaller, the amount thereof is usually 0.8 to 1 mol and preferably 0.9 to 1.0 mol with respect to 1 mol of the tin tetraamide. That is, it is preferable to use a slightly small amount of alkyl magnesium.

### Solvent Used for Tin Tetraamide

The solvent used for the tin tetraamide is not particularly limited as long as the solvent does not react with the alkyl magnesium reagent or the tin tetraamide, but is preferably a hydrocarbon-based solvent or an ether-based solvent. Specific examples of such a solvent that is preferably used include hydrocarbon-based solvents such as pentane, hexane, heptane, octane, nonane, decane, undecane, dodecane, pentadecane, heptadecane, eicosane, docosane, cyclohexane, methylcyclohexane, decalin, benzene, toluene, xylene, mesitylene, 1,4-diethylbenzene, 1,3-dimethylnaphthalene, and diphenylmethane; and ether-based solvents such as t-butyl methyl ether, diisopropyl ether, dibutyl ether, dimethoxyethane, tetrahydrofuran, 2-methyltetrahydrofuran, 4-methyltetrahydropyran, cyclopentyl methyl ether, and dioxane. Further, the solvent used for the tin tetraamide corresponds to [second solvent] described below in a case where the octanol-water partition coefficient of the solvent used for the tin tetraamide is 1.0 or greater, which is greater than that of the ether-based solvent.

The amount of the solvent used for the tin tetraamide is usually 10% to 70% by mass, preferably 20% to 60% by mass, and more preferably 30% to 50% by mass, in terms of the concentration of the tin tetraamide.

### Second Solvent

The compound used as the second solvent has an octanol-water partition coefficient of 1.0 or greater, which is greater than that of the ether-based solvent (compound used as a solvent for the alkyl magnesium reagent). This means that the second solvent has hydrophobicity higher than that of the ether-based solvent.

Under the condition that a second solvent is not used, when the solid is separated by filtration and the solvent is distilled off after the completion of the reaction, the viscosity of the reaction solution increases, and the vapor pressure is significantly reduced. When the vapor pressure decreases, the target compound is difficult to purify by distillation. Meanwhile, when a second solvent having high hydrophobicity is used, a solid containing a magnesium salt is precipitated during distillation due to a decrease in solvent polarity. The target compound can be isolated without decreasing the vapor pressure by separating the solid by filtration or distilling the compound while maintaining the precipitated state.

As a second solvent, an aliphatic hydrocarbon-based solvent or an aromatic hydrocarbon-based solvent is preferable. In addition, another kind of ether-based solvent which is different from the ether-based solvent used in the solution of the alkyl magnesium reagent and has an octanol-water partition coefficient greater than that of the ether-based solvent can be used. The octanol-water partition coefficient of the second solvent is preferably 2.0 or greater, more preferably 2.5 to 12, still more preferably 3.0 to 10, and particularly preferably 4.0 to 7.0. The viscosity of the reaction solution is likely to increase in a case where the octanol-water partition coefficient is extremely low, and the boiling point of the solvent is also high and thus it takes time for distillation in a case where the octanol-water partition coefficient is extremely high.

The boiling point of the second solvent is usually 60° C. to 300° C., preferably 60° C. to 250° C., and more preferably 90° C. to 200° C. In addition, from the viewpoint of safety, the flash point is preferably −30° C. or higher and more preferably −25° C. or higher.

In addition, the difference in boiling point between the second solvent and the monoalkyltin triamide is preferably 30° C. or higher, more preferably 50° C. or higher, and particularly preferably 100° C. or higher under reduced pressure during the distillation. When the boiling point of the monoalkyltin triamide is sufficiently high, it is possible to prevent the monoalkyltin triamide from being accompanied when the second solvent is distilled off under reduced pressure. In addition, when the boiling point of the second solvent is sufficiently high, the monoalkyltin triamide can be distilled off before the second solvent.

A hydrocarbon-based compound in which the solubility of an inorganic salt or the like is low and by-products such as an inorganic salt and the like are easily removed by filtration, centrifugation, or the like after the reaction is particularly preferable. Specific examples thereof include pentane, hexane, heptane, octane, nonane, decane, undecane, dodecane, pentadecane, heptadecane, eicosane, docosane, cyclohexane, methylcyclohexane, decalin, benzene, toluene, xylene, mesitylene, 1,4-diethylbenzene, 1,3-dimethylnaphthalene, and diphenylmethane. In addition, an ether having 8 or more carbon atoms and one oxygen atom, such as dibutyl ether, is also preferably used.

### Moisture in Solvent

In the present embodiment, the moisture contained in the reaction solution may affect the reaction, and thus is required to be controlled. The moisture represents moisture brought in from the raw materials to be used as long as the reaction is carried out in an inert atmosphere, but moisture as impurities contained in the first solvent (including the ether-based solvent) and the second solvent affects the reaction in many cases. The upper limit of the moisture content of the solvent to be used is usually 500 ppm or less, preferably 300 ppm or less, more preferably 100 ppm or less, still more preferably 80 ppm or less, and particularly preferably 40 ppm or less. When the moisture content is extremely large, there is a possibility that the alkyl magnesium reagent will be decomposed. Meanwhile, the lower limit thereof is preferably 1 ppm or greater, more preferably 5 ppm or greater, still more preferably 7 ppm or greater, and particularly preferably 10 ppm or greater. When the solvent contains a certain amount of moisture, the solubility of the alkyl magnesium reagent is adjusted for activation, and thus by-products in the reaction are likely to be suppressed.

### Method of Distilling Off Ether-Based Solvent

One of the features of the present disclosure is that the method includes a step of distilling off of the ether-based solvent in a state where at least the ether-based solvent is used and a second solvent having an octanol-water partition coefficient greater than that of the ether-based solvent is present in the reaction between the tin tetraamide (10) and the alkyl magnesium reagent (8) or (9). The magnesium salt generated by this reaction may cause an increase in viscosity in an ether-based solvent (the cause of the increase in viscosity is presumed to be gelation). Meanwhile, in a hydrophobic solvent, the magnesium salt is precipitated as a solid, and the increase in viscosity of the reaction mixture does not occur. Therefore, how to remove the ether-based solvent and replace the ether-based solvent with a hydrophobic solvent is important.

One of the other features of the present disclosure is that the method includes a step of mixing a second solvent having an octanol-water partition coefficient greater than that of the ether-based solvent and a step of removing a solid including a magnesium salt by filtration. The concentration of the tin compound in the reaction mixture in a case of filtering the magnesium salt is preferably 5% to 90% by mass, more preferably 10% to 70% by mass, and particularly preferably 20% to 50% by weight. In a case where the concentration is high, the magnesium salt is dissolved in the tin compound itself, which may be accompanied by an increase in viscosity. When the concentration of the tin compound is preferable, the viscosity of the reaction mixture is not extremely high, and the amount of the solvent is not extremely large. In addition, in a case of filtering the magnesium salt, the concentration of the ether-based solvent in the reaction mixture is usually 20% by mass or less, preferably 10% by mass or less, and more preferably 1% by mass or less. As the content of the ether-based solvent decreases, the viscosity of the reaction mixture is unlikely to increase.

Hereinafter, an aspect of distilling off the ether-based solvent and an aspect of filtering the solid containing a magnesium salt will be described.

### Use of Solvent Having High Boiling Point as Second Solvent

When a second solvent having a sufficiently high boiling point is used as the ether-based solvent used for the preparation of the magnesium reagent and the reaction between the magnesium reagent and the tin tetraamide, the ether-based solvent is preferentially removed and the second solvent having a high boiling point remains when the solvent is distilled off after the reaction. However, since the second solvent is a solvent having a high octanol-water coefficient, the salt dissolved in the reaction solution having high polarity is precipitated, and the solvent can be distilled off without causing an increase in viscosity.

In the difference in boiling point between the second solvent and the ether-based solvent, the boiling point of the second solvent is higher than that of the ether-based solvent by preferably 10° C. or higher, more preferably 40° C. or higher, and particularly preferably 70° C. or higher. When the difference in boiling point is extremely large, it takes time to distill off the second solvent, and thus the difference in boiling point is preferably 300° C. or lower.

The octanol-water partition coefficient is defined as Log₁₀ (concentration of test substance in 1-octanol layer (mol/L)/concentration of test substance in water layer (mol/L)). When the solvent is a mixture, in the present specification, a weighted average of the octanol-water partition coefficients of the solvents is used as an index instead of the octanol-water partition coefficient of the solvent.

Example: when a mixture of hexane (4.00) and decane (6.25) at a ratio of 2:1 is used as a solvent, the index treated as the octanol-water partition coefficient of the mixed solvent is (4.00×2+6.25)/3=4.75.

As a typical embodiment, for example, tetrahydrofuran (ether-based solvent: boiling point: 66° C., flash point: −21.5° C., octanol-water partition coefficient: 0.46) is used for the adjustment of the alkyl magnesium reagent. In addition, in the reaction shown above, decane (second solvent: boiling point: 174° C., flash point: 46° C., octanol-water partition coefficient: 6.25) is used as a solvent for tetrakis(dimethylamino)tin as a raw material. After the reaction, when a solid is precipitated, the solid is separated by filtration, and the solvent (here, a mixture of tetrahydrofuran and decane) is distilled off under reduced pressure. Since the boiling point of decane is sufficiently higher than the boiling point of tetrahydrofuran, tetrahydrofuran is preferentially removed. That is, the ether-based solvent is distilled off in a state where the second solvent is present. As a result, since almost only decane remains as the solvent of the reaction mixture, and decane has high hydrophobicity and does not almost dissolve the magnesium salt, the solid containing a magnesium salt is precipitated without increasing the viscosity of the reaction mixture, and can be removed by filtration. The reaction mixture from which the solid components have been removed can be purified, for example, by distillation to obtain monoalkyltris(dimethylamino)tin (11) having high purity. In this case, the ether-based solvent is the first solvent, and the solvent used for the tin tetraamide (10) as the raw material is the second solvent. Therefore, the alkylation reaction is carried out using a mixed solvent of the first solvent and the second solvent.

In addition, as another typical embodiment, for example, tetrahydrofuran is used for the adjustment of the alkyl magnesium reagent, and tetrahydrofuran is also used as a solvent for tetrakis(dimethylamino)tin as a raw material in the reaction shown above. When decane is added as the second solvent after the completion of the reaction, since only decane remains in a case of distilling off the solvent, and decane has high hydrophobicity and does not almost dissolve the magnesium salt, the solid containing a magnesium salt is precipitated without increasing the viscosity of the reaction mixture, and can be removed by filtration.

In addition, as another typical embodiment, for example, in the reaction shown above, a second compound having a boiling point higher than the boiling point of the target compound by 30° C. or higher and preferably 50° C. or higher, such as eicosane (boiling point: 343° C., octanol-water partition coefficient: 10.16) is used as the solvent for tetrakis(dimethylamino)tin as the raw material. In this case, when the reaction mixture is distilled off, first, the ether-based solvent is removed, and the solvent of the reaction mixture is almost only the second solvent. At this point, the solid containing a magnesium salt is precipitated, and thus can be removed by filtration and then distilled, but in a case where the boiling point of the second solvent is higher than that of the target compound, the target compound is distilled off by distillation, the second solvent remains as a residue, and thus the target compound can be distilled and purified even when the solid remains.

### Sequential Addition of Second Solvent

When a second solvent having a small difference in boiling point from the boiling point of the ether-based solvent is used as the second solvent, the solid containing a magnesium salt can be precipitated and removed by filtration by sequentially adding the second solvent in the middle stage of the solvent distillation.

In a typical embodiment, for example, tetrahydrofuran (ether-based solvent: boiling point: 66° C., flash point: −21.5° C., octanol-water partition coefficient: 0.46) is used for adjusting the alkyl magnesium reagent of [Formula 1]. In addition, in the reaction of [Formula 2], hexane (second solvent: boiling point: 69° C., flash point: −22° C., octanol-water partition coefficient: 4.00) is used as a solvent for tetrakis(dimethylamino)tin as the raw material. Since the boiling points of tetrahydrofuran and hexane are not significantly different from each other, both tetrahydrofuran and hexane are distilled off under the same conditions under reduced pressure. Therefore, when the distillation is continued as it is, it is not possible to remove tetrahydrofuran and leave only hexane. Therefore, hexane, which is the second solvent, is added in the middle of the distillation. For example, on the assumption that hexane and tetrahydrofuran are distilled off in the same proportion, in a case where 50 g of hexane and 50 g of tetrahydrofuran are initially present, 25 g of hexane and 25 g of tetrahydrofuran remain by distillation, and 50 g of hexane, which is the second solvent, is added, the mixed solution is formed of 75 g of hexane and 25 g of tetrahydrofuran. When hexane, which is the second solvent, is added in the middle of the sequential distillation, and the distillation is repeated, the amount of the ether-based solvent in the reaction mixture decreases, almost only hexane in the solvent remains, and the solid containing a magnesium salt is precipitated without increasing the viscosity of the reaction mixture, and can be separated by filtration. The reaction mixture from which the solid components have been removed can be purified, for example, by distillation to obtain monoalkyltris(dimethylamino)tin (11) having high purity. In this case, the method includes a step of mixing the second solvent with a crude product (reaction mixture) obtained by distilling off at least a part of the first solvent after the alkylation reaction. In addition, the method includes a step of distilling off the ether-based solvent while continuously adding the second solvent to the reaction mixture. Further, in a case where the second solvent having a high boiling point is added in the middle of the distillation, the number of times of addition can be reduced or the addition can be performed once.

### Addition of Second Solvent to High-Viscosity Reaction Mixture

When the second solvent having a small difference in boiling point from the boiling point of the ether-based solvent is used as the second solvent and the solvent is distilled off as it is without being added, the viscosity of the reaction mixture may increase. Even in this case, the solid containing the magnesium salt can be precipitated by adding the second solvent to the highly viscous liquid, and can be removed by filtration.

In a typical embodiment, for example, tetrahydrofuran (ether-based solvent: boiling point: 66° C., flash point: −21.5° C., octanol-water partition coefficient: 0.46) is used for the adjustment of the alkyl magnesium reagent of [Formula 1]. In addition, in the reaction of [Formula 2], hexane (second solvent: boiling point: 69° C., flash point: −22° C., octanol-water partition coefficient: 4.00) is used as a solvent for tetrakis(dimethylamino)tin as the raw material. Since the boiling points of tetrahydrofuran and hexane are not significantly different from each other, both tetrahydrofuran and hexane are distilled off under the same conditions under reduced pressure. When the distillation is continued as it is, the viscosity of the reaction mixture is increased in a state where tetrahydrofuran remains. Therefore, when the solid is precipitated by adding hexane, which is the second solvent, to the gel, the solid is separated by filtration and distilled off. In a case where the viscosity is increased again, hexane is further added and distilled off By repeating this operation, almost only hexane in the solvent remains, and the solid containing a magnesium salt is precipitated without increasing the viscosity of the reaction mixture, and can be separated by filtration. In the reaction mixture from which the solid components have been removed, for example, monoalkyltris(dimethylamino)tin (11) having high purity can be obtained by distillation. Further, when a second solvent having a high boiling point is added to the highly viscous liquid, the number of times of addition can be reduced or the addition can be completed in one time.

### Conditions for Producing Monoalkyltin Triamide

### Reactor

A reactor is not particularly limited, but is preferably a reactor capable of adjusting the alkyl magnesium reagent, controlling the reaction temperature of the alkyl magnesium reagent and the tin tetraamide, and controlling the temperature range thereof to be an appropriate range. Specifically, it is preferable that the reactor includes temperature control equipment (jacket equipment) capable of cooling and heating, stirring equipment, and dropping equipment. In addition, the reactor may also include a cooling condenser.

The material of the reactor (the inside of a kettle and a stirring blade) is not particularly limited, but is preferably Teflon (registered trademark), glass, SUS, or the like. Among these, glass is preferable from the viewpoint of preventing metal contamination, and SUS is preferable from the viewpoint of strength and thermal conductivity (temperature control by a jacket). In addition, since the tin compound may have corrosiveness to metals, electropolished SUS (SUS-EP) with high chemical resistance is preferable among SUS.

The shape and the capacity of the reactor can be optionally set within an appropriate range for the required amount of the reaction solution, but in order to perform an efficient dropping or stirring operation, the capacity is preferably 100 mL or greater, more preferably 300 mL or greater, still more preferably 1 L or greater, and particularly preferably 10 L or greater.

### Reaction Temperature

In the present reaction, the temperature at the time of mixing the alkyl magnesium reagent and the tin tetraamide is preferably −50° C. to 30° C., more preferably −30° C. to 15° C., and particularly preferably −20° C. to 0° C. The reaction rate may be extremely low when the temperature is extremely low, and the generation ratio of a dialkylated product may be high when the temperature is extremely high.

### Purification, Storage, and Use

The discussion below regarding the purification, storage, and usage of the compound having formula (11) is equally applicable and encompasses the purification and storage of all tin compounds set forth herein. That is, while the sections below refer only to compound (11), they are also intended to describe the purification, storage, and uses of all of the tin compounds described herein.

### Distillation Column

The monoalkyltin triamide (11) produced by the production method according to the embodiment of the present invention is purified to increase the purity and is used for lithography and the like. The most typical method of purification is distillation. Although a multi-stage distillation method is preferable as the distillation method, even in a case of single distillation, the inclusion of a demister can suppress the accompanying droplets and increase the purification efficiency.

### Theoretical Number of Stages

The theoretical number of stages is not particularly limited as long as the number of stages is set such that impurities can be separated, but when the boiling points of impurities are close and separation is difficult, the theoretical number of stages is preferably 5 or greater and more preferably 10 or greater. Meanwhile, when the theoretical number of stages is extremely large, since there is a tendency that the distillation takes a long time and thus the decomposition of the tin compound (11) is promoted, or the distillation rate is decreased and thus the productivity is decreased, the theoretical number of stages is preferably 100 or less, more preferably 70 or less, and still more preferably 50 or less.

In addition, as the theoretical number of stages increases, the equipment is larger, and thus the equipment cost tends to increase. Therefore, from the viewpoint of the equipment cost, it is preferable that the theoretical number of stages is small within a range where the required distillation capacity is satisfied.

As the theoretical number of stages increases, the separation ability increases. However, in a case where a difference in molecular weight between the tin compound (11) and the tin compound (10) and/or (12) as impurities is large to a certain extent, a large theoretical number of stages is not necessary. Therefore, the theoretical number of stages may be selected depending on the balance of the difference in boiling point.

### Filler

A filler and the structure in the distillation column are not particularly limited, but from the viewpoint of having high theoretical number of stages and low pressure loss performance, a structure filled with a regular filler is preferable. As a material of the filler, glass or SUS is preferable. The HETP (m/stage) of the filler under the distillation conditions is preferably 1.0 or less, more preferably 0.8 or less, still more preferably 0.5 or less, and particularly preferably 0.3 or less. When the HETP is low, it is possible to reduce the pressure loss, reduce the height of the distillation column to shorten the distillation time, and achieve distillation at a lower temperature, and thus a tin compound (11) having high purity may be obtained.

### Distillation Conditions

Hereinafter, the conditions related to the distillation will be described for each item. In the distillation conditions, in order to obtain a tin compound (11) having higher purity, each item and suitable conditions may be combined. In addition, in a case where specific distillation equipment and specific distillation conditions are combined, a synergistic effect may be obtained, and thus a higher purification efficiency or productivity may be obtained.

### Reflux Ratio

The main distillation may be performed without controlling the reflux ratio, but the separation efficiency may be further improved or the distillation time may be shortened by appropriately controlling the reflux ratio. A method of controlling the reflux ratio is not particularly limited, but may be carried out by controlling the opening/closing time of an outlet, controlling the flow rate of refluxing/distilling a distillate, and the like. Further, a reflux ratio of 10 represents that the extraction amount and the reflux amount are controlled at 1:10. The lower limit of the reflux ratio is preferably 0.1 or greater, more preferably 1 or greater, and still more preferably 3 or greater. When the reflux ratio is the lower limit or less, the distillation efficiency is insufficient, and a component having a close boiling point is mixed into the distillate, and thus the purification effect is unlikely to be obtained. The upper limit of the reflux ratio is preferably 200 or less, more preferably 150 or less, and still more preferably 100 or less. When the reflux ratio is the upper limit or greater, the distillation time tends to be extremely long, which may accelerate the decomposition of the tin compound, or the distillation rate tends to decrease, which may deteriorate the productivity.

### Distillation Time

The distillation time is not limited by the scale of distillation and the equipment, but is preferably shorter within a range where appropriate productivity can be ensured, and is usually 200 h or shorter, more preferably 100 h or shorter, and still more preferably 50 h or shorter. In addition, the lower limit of the distillation time is preferably 1 hour or longer and more preferably 10 hours or longer. The distillation time represents a time taken until target conditions are achieved and distillation is performed. In addition, the heating time is also preferably short within a range where appropriate productivity can be ensured, and is usually 200 h or shorter, preferably 100 h or shorter, and more preferably 50 h or shorter.

### Distillation Temperature

The distillation temperature in the present purification method represents an internal temperature during the distillation, that is, the temperature of the solution in a distiller. The distillation temperature depends on the boiling point of the target substance and other distillation conditions, but the lower limit is preferably 20° C. or higher, more preferably 30° C. or higher, and still more preferably 50° C. or higher. The upper limit is preferably 200° C. or lower, more preferably 180° C. or lower, and still more preferably 150° C. or lower. When the distillation temperature is extremely high, the decomposition of the tin compound (4) is accelerated. When the distillation temperature is extremely low, it is necessary to excessively reduce the pressure, and the equipment restriction is large.

### Difference Between Distillation Temperature and Jacket Temperature (Heat Medium Temperature)

The difference between the distillation temperature and the jacket temperature is preferably 1° C. to 20° C. and more preferably 5° C. to 10° C. When the difference in temperature is extremely large, the amount of evaporation is extremely large, and flooding occurs in the distillation column, and thus sufficient separation is unlikely to be performed. When the difference in temperature is extremely small, the amount of evaporation is extremely small, and thus it takes a long time for distillation, and thus decomposition is likely to be accelerated or the separation performance of the distillation column is likely to be degraded.

Further, the distillation temperature represents the internal temperature during distillation as described above, but the decomposition rate of the tin compound (11) may be affected by the temperature at a place different from the distillation temperature (internal temperature), such as the jacket temperature (heat medium temperature) or the column top temperature of the distillation column.

### Temperature of Cooling Condenser

The cooling temperature of the cooling condenser in an upper part of the distillation column needs to be sufficiently lower than the column top temperature, and it is preferable to use a cooling condenser having a temperature lower than the column top temperature by 10° C. to 70° C.

The difference in temperature between the cooling temperature of the condenser and the boiling point of the tin compound (11) is preferably within 50° C., more preferably within 30° C., and still more preferably within 10° C. When the cooling is excessive, the tin compound may be precipitated in the distillation column, or the cooling of the distillation kettle may proceed, and a higher jacket temperature may be required.

### Pressure During Distillation (Degree of Decompression)

Since the boiling point of the tin compound (11) is high under normal pressure, the distillation in the present purification method is basically carried out under reduced pressure conditions. The pressure in this case is preferably lower so that distillation can be carried out at a temperature as low as possible so that decomposition of the tin compound (11) does not occur. Specifically, the pressure is preferably 100 torr or less, more preferably 50 torr or less, still more preferably 20 torr or less, particularly preferably 15 torr or less, more preferably 10 torr or less, and still more preferably 5 torr or less. Meanwhile, the pressure is preferably 0.01 torr or greater, more preferably 0.1 torr or greater, and still more preferably 1 torr or greater under conditions in which particularly high separation is required or under conditions in which the scale is increased from the viewpoints of the performance of the vacuum pump, the pressure loss of the distillation column, and the like.

### Form of Distillation

The form of the distillation and the configuration of the device in the present purification method are not particularly limited. As the distillation form, for example, both batch distillation and continuous distillation can be applied, but batch distillation is preferable from the viewpoint of recovering a high-purity fraction, and continuous distillation may be preferable from the viewpoint of yield. In addition, in order to carry out more efficient purification, distillation may be carried out a plurality of times, or a plurality of distillation equipment may be combined. In addition, the feed position of the distillate or the extraction position of the distillate may be changed.

### Other Distillation Conditions

Since the tin compound (11) is unstable in water or air, it is preferable to perform a distillation operation and a filling operation of fractions under an inert atmosphere such as nitrogen or argon. Specifically, it is preferable that the fractions are recovered in a container connected in an inert gas atmosphere. Alternatively, an operation such as transferring the fractions to another container while maintaining the state of the inert gas atmosphere is preferable. In addition, it is preferable that the sampling and the analysis are also performed in the same inert gas atmosphere.

### Handling, Storage, and Transportation of Tin Compound (11)

The tin compound (11) may be unstable to light. In all parts such as a distillation kettle, a distillation column, and a fraction, light shielding properties may be achieved by using a SUS device or a light-shielded glass device (for example, brown glass or a glass device having a shielded periphery) and the like. In addition, the shielding of light may be performed by any method known in the technical field, such as wrapping the device with a light shielding cover such as cloth, foil, or a film, using a light shielding coating, or performing distillation in a dark room or a yellow room.

The monoalkyltin triamide (11) obtained by the present production method has high substitution reactivity of an amino group such as hydrolysis, is likely to undergo transmetallation with other metals or metal compounds, and has decomposition properties with respect to light and heat. Therefore, in a case of storing the tin compound (11), a storage container is required to have gas barrier properties and light shielding properties without the inner surface of the container being eroded. As a material of such a storage container, an electropolished stainless steel container (SUS-EP) is particularly preferably used. In a case of SUS-EP, since the impact resistance is also high, the container is suitable for transportation.

The tin compound (11) can be stored for a short period of time to a long period of time, such as about 3 days to about 1 year, by being stored in a container having gas barrier properties at a temperature of lower than about 30° C. without being substantially irradiated with light. For example, the tin compound (11) can be stored for a period of time of about 1 week or longer and about 10 months or shorter, about 2 to 6 weeks, and all desired times.

The temperature in a case of storage is preferably about 30° C. or lower, more preferably about 25° C. or lower, and still more preferably about 20° C. or lower. The lower limit of the storage temperature is preferably a temperature of about −10° C. or higher.

### Applications of Monoalkyltin Triamide (11): Resist Material

The monoalkyltin triamide (11) obtained by the present production method has a Sn—C bond which is EUV-sensitive and contains an amino group which can be easily hydrolyzed, and thus is useful as a material such as an EUV resist or the like. Hereinafter, the applications as a resist material will be described.

### Solution

The monoalkyltin triamide (11), which is the target compound of the present invention, can further contain a solvent as necessary. In order to facilitate coating and vapor deposition as a resist material using the tin compound (11), it is preferable to use the tin compound (11) after dilution with a solvent. The solvent is not particularly limited as long as the solvent is a compound that does not react with the tin compound (11), but practically, an ether-based solvent or a hydrocarbon-based solvent is preferably used. These solvents can be used alone or in combination of two or more kinds thereof.

The amount of the solvent to be used is preferably 0.01 to 30 parts by mass, more preferably 0.1 to 20 parts by mass, and particularly preferably 1 to 10 parts by mass with respect to 1 part by mass of the tin compound (11).

Tin Compound after Hydrolysis

The tin compound (11) may be used as a resist material after a reaction such as hydrolysis is carried out. In regard to a method of using the resist material, for example, the method disclosed in Japanese Unexamined Patent Application, First Publication No. 2021-21953 may be used. Since the tin compound (11) contains a hydrolyzable dialkylamino group, the tin compound (11) may be hydrolyzed with water or another suitable reagent under appropriate conditions to form an alkyltin oxo-hydroxo patterning composition represented by R^{v}SnO_{(3/2-x/2)}(OH)ₓ (in the formula, 0≤x≤3). The hydrolysis and condensation reactions are shown in the following reactions.

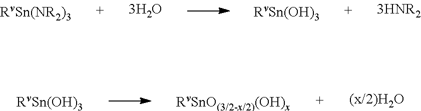

A tin compound represented by R^{v}SnO_{(3/2-X/2)}(OH)x, which is obtained by performing hydrolysis using the tin compound (11) as a raw material (hereinafter, also referred to as “tin hydrolyzate”) may be used as an EUV resist material.

Examples of the method of hydrolyzing the tin compound (11) to obtain a tin hydrolyzate include a method (dry method) of reacting steam or the like with steam generated by volatilizing the tin compound (11) under heating or reduced pressure or with a substrate on which the tin compound (11) has been vapor-deposited. In this method, a thin film (film) can be formed on a thin film (film) substrate containing the tin hydrolyzate.

In addition, the tin compound (11) is allowed to react with water or the like in a state of a solution obtained by dissolving the tin compound (11) in a solvent to obtain a partially hydrolyzed product such as a tin dodecamer cluster, and the partially hydrolyzed product is dissolved in an organic solvent or the like, whereby the partially hydrolyzed product can be used as a coating solution. This solution can be applied to a substrate by any coating, for example, spin coating or a printing technology, and further, and a thin film (coating film) containing the tin hydrolyzate may be molded on the substrate by further hydrolyzing the solution.

The thin film obtained by any of the above-described methods may be stabilized or partially condensed before light irradiation after being dried, heated, or the like. In general, the thin film has, for example, an average thickness of less than 10 microns, and an extremely thin submicron thin film, for example, a thin film with a thickness of about 100 nm or less, further 50 nm or less, or particularly 30 nm or less may be desired in order to pattern an extremely small feature. The obtained thin film may be referred to as “resist” because a part of the composition is treated by light exposure to be resistant to development/etching.

The thin film may be exposed to appropriate radiation, for example, extreme ultraviolet rays, electron beams, or ultraviolet rays using a selected pattern or a negative part of the pattern to form a latent image having a developer-resistant region and a developer-soluble region. After exposure to appropriate radiation and before development, the thin film may be heated or reacted by another method to differentiate the latent image from a non-irradiated region. The latent image is brought into contact with a developer to form a physical image, that is, a patterned thin film. The patterned thin film may be further heated to stabilize a surface-patterned residual thin film. The patterned thin film may be used as a physical mask for further processing, for example, etching of a substrate and/or adhesion of an additional material, according to the pattern. After using the patterned resist as desired, the remaining patterned thin film may be removed at an appropriate time point of processing, but the patterned thin film can also be incorporated into the final structure.

Fifth Method (R″″Sn(NR₂)₃)

A fifth method according to aspects of the disclosure is for synthesizing a monoorgano tin compound having formula (1″) according to aspects of the disclosure comprises reacting a tetrakis(dialkylamino)tin compound having formula (5″) with a Grignard compound having formula (8′) (R″″MgX′ (X′═Cl, Br, or I)). This reaction is most selective for compounds having formula (1) when the organic group is a tertiary alkyl group.

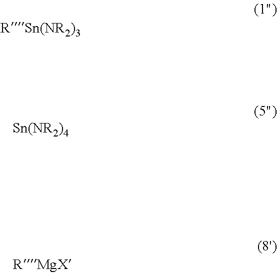

In the above formulas, each R is independently a linear or branched alkyl group having about 1 to about 10 carbon atoms, X′ is chlorine, bromine, or iodine, and R″″ is a linear, branched, or cyclic hydrocarbon group having about 1 to 30 carbon atoms which may contain one or more halogen atoms, oxygen atoms, nitrogen atoms, silicon atoms, or sulfur atoms. In some preferred embodiments, R″′ has formula [I], [II], or [III] as described above.

An exemplary reaction scheme for this method is:

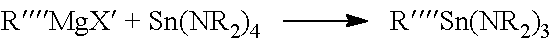

This reaction may be performed in a variety of solvents. Most preferred solvents are ethers, such as diethyl ether. Other preferred solvents include hydrocarbons (such as, but not limited to, pentane, hexane, heptane, and cyclohexane), aromatics (such as, but not limited to, toluene and xylene), and mixtures thereof.

Lower preferred temperatures for the step are about −78° C., about −40° C., about −20° C., about −10° C., most preferably about 0° C., as well as all intervening temperatures, and the upper limit of the reaction temperature is preferably about 35° C., about 30° C., or about 25° C., as well as all intervening temperatures. Thus, the preferred temperature range is about −10° C. to about 25° C. If the temperature is too low, the reaction rate will be too slow, whereas if the temperature is too high, byproducts will be produced.

A solution containing the tetrakis(dialkylamino)tin compound prior to the addition of the Grignard reagent preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %. It has been found that such dilute concentrations provide effective control of reaction temperature or solubility of the tetrakis(dialkylamino)tin compound. On the other hand, the productivity is lower in dilute condition in industrial conditions.

The molar amount of the tetrakis(dialkylamino)tin compound relative to the Grignard reagent is preferably 1.0 equivalent.

Following reaction of the two components, the reaction mixture is worked up and purified using methods well known in the art to produce the compound having formula (1), (1′), or (11).

### Sixth Method [R″″Sn(OR)₃](1″′)

A sixth method according to aspects of the disclosure is for synthesizing a monoorgano tin compound having formula (1″′) comprises reacting a tetraalkynyl tin compound having formula (14) with a Grignard compound having formula (8′) (R″″MgX′ where X′═Cl, Br, or I) to form a trialkynylorganotin compound have formula R″″Sn(CCR^{VI})₃, followed by reaction with primary or secondary alcohol having formula (15) with gentle heating to form R″″Sn(OR)₃. This reaction is most selective for compounds having formula (1″′) when the organic group R″″ is a tertiary alkyl group.

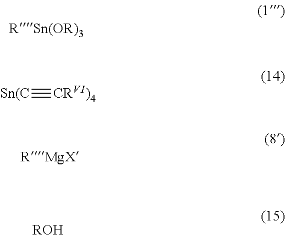

In the above formulas, each R is each independently a linear or branched alkyl group having about 1 to about 10 carbon atoms and each R^{VI} is independently a linear or branched alkyl group having about 1 to about 10 carbon atoms, or an aryl group having about 6 to 10 carbon atoms. X′ is chlorine, bromine, or iodine, and R″″ is a linear, branched, or cyclic hydrocarbon group having about 1 to 30 carbon atoms which may contain one or more halogen atoms, oxygen atoms, nitrogen atoms, silicon atoms, or sulfur atoms. In some preferred embodiments, R″″ has formula [I], [II], or [III] as described above.

The alcohol preferably is a primary alcohol such as MeOH, or EtOH. In the tetralkynyl tin compound, the alkynyl group preferably contains about 2 to 6 carbon atoms, preferably at least about four carbon atoms, and is preferably a bulky group, such as tert-butylalkynyl or phenylalkynyl.

An exemplary reaction scheme for this method is:

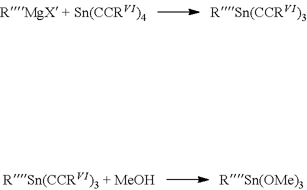

The first step of the reaction may be performed in a variety of solvents. Preferred solvents include hydrocarbons (such as, but not limited to, pentane, hexane, heptane, and cyclohexane), aromatics (such as, but not limited to, toluene and xylene), and ethers (such as, but not limited to, THF and Et₂O), and mixtures thereof. Most preferred solvents are ethers or toluene.

Lower preferred temperatures for the first reaction step are about −78° C., about −40° C., about −20° C., about −10° C., most preferably about 0° C., as well as all intervening temperatures, and the upper limit of the reaction temperature is preferably about 70° C., about 60° C., or about 50° C., as well as all intervening temperatures. Thus, the preferred temperature range is about 0° C. to about 60° C., and all intervening temperatures, including 5° C., 10° C., 15° C., 20° C., 25° C., 30° C., 35° C., 40° C., 45° C., 50° C., 55° C., and 60° C. If the temperature is too low, the reaction rate will be too slow, whereas if the temperature is too high, byproducts will be produced. Most preferably, the reaction is performed at about 60° C.

The molar amount of the tetraalkynyl tin compound relative to the Grignard reagent is preferably about 1.0 equivalent.

The molar amount of the alcohol ROH relative to the trialkynylorganotin compound is at least 3 eq, more preferably is about 6 eq.

The second step of the reaction may be performed in a variety of solvents. Preferred solvents include hydrocarbons (such as, but not limited to, pentane, hexane, heptane, and cyclohexane), aromatics (such as, but not limited to, toluene and xylene), ethers (such as, but not limited to, THF and Et₂O), and alcohol (such as, methanol, ethanol) and mixtures thereof. Most preferred solvents are aromatics like toluene.

Lower preferred temperatures for the second reaction step are about −78° C., about −40° C., about −20° C., about −10° C., most preferably about 0° C., as well as all intervening temperatures, and the upper limit of the reaction temperature is preferably about 100° C., about 90° C., or about 80° C., as well as all intervening temperatures. Thus, the preferred temperature range is about 0° C. to about 80° C., including all intervening temperatures such as 5° C., 10° C., 15° C., 20° C., 25° C., 30° C., 35° C., 40° C., 45° C., 50° C., 55° C., 60° C., 65° C., 70° C., 75° C., and 80° C. If the temperature is too low, the reaction rate will be too slow, whereas if the temperature is too high, byproducts will be produced. Most preferably, the reaction is performed under reflux and preferably at about 60° C. to about 70° C.

Following reaction of the two components, the reaction mixture is worked up and purified using methods well known in the art to produce the compound having formula R″″Sn(OR)₃.

### Seventh Method (R″″Sn(OR)₃) (1′)

A seventh method according to aspects of the disclosure is for synthesizing a monoorgano tin compound having formula (1″′) which comprises reacting a bis[bis(trialkylsilyl)amino]tin(II) compound having formula (17) with a hydrocarbyl halide compound having formula (18) (where X′ is Cl, Br, or I) to perform an oxidation insertion which forms an alkyl bis[bis(trimethylsilylamino)]tin halide compound having formula R″″Sn[SiN(SiMe₃)₂]₂X′, followed by reaction with a metal alkoxide having formula (15′) and the associated alcohol having formula (15) with gentle heating.

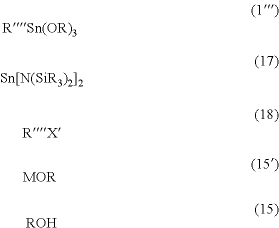

All of the substituents R″″, R, and X′ have been defined above. The alcohol preferably is a primary alcohol such as MeOH, or EtOH.

An exemplary reaction scheme for this method is:

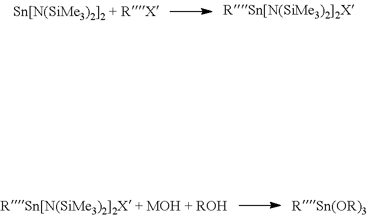

The first step of the reaction may be performed in a variety of solvents. Preferred solvents include hydrocarbons (such as, but not limited to, pentane, hexane, heptane, and cyclohexane), aromatics (such as, but not limited to, toluene and xylene), and ethers (such as, but not limited to, THF and Et₂O), and mixtures thereof. Most preferred solvents are ethers or toluene.

Lower preferred temperatures for the first reaction step are about −78° C., about −40° C., about −20° C., about −10° C., most preferably about 0° C., as well as all intervening temperatures, and the upper limit of the reaction temperature is preferably about 70° C., about 60° C., or about 50° C., as well as all intervening temperatures. Thus, the preferred temperature range is about 0° C. to about 30° C. If the temperature is too low, the reaction rate will be too slow, whereas if the temperature is too high, byproducts will be produced.

The second step of the reaction may be performed in a variety of solvents. Preferred solvents include hydrocarbons (such as, but not limited to, pentane, hexane, heptane, and cyclohexane), aromatics (such as, but not limited to, toluene and xylene), ethers (such as, but not limited to, THF and Et₂O), and alcohol (such as, methanol, ethanol) and mixtures thereof. Most preferred solvents are aromatics like toluene.

Lower preferred temperatures for the second reaction step are about −78° C., about −40° C., about −20° C., about −10° C., most preferably about 0° C., as well as all intervening temperatures, and the upper limit of the reaction temperature is preferably about 100° C., about 90° C., or about 80° C., as well as all intervening temperatures. Thus, the preferred temperature range is about 0° C. to about 80° C. If the temperature is too low, the reaction rate will be too slow, whereas if the temperature is too high, byproducts will be produced. Most preferably, the reaction is performed under gentle reflux.

Continued Reaction of R″″Sn(OR)₃ to R″″Sn(NR₂)₃ From Sixth and Seventh Methods

From the above six and seven methods, the intermediate alkyl tin trialkoxide may be further reacted with a (N,N-dialkylamino)trialkylsilane having formula R₃SiNR₂ (19) ((such as N,N-dimethylamino)trimethylsilane) or a lithium amide LiNR₂ (16) (such as lithium dimethylamide) to form the corresponding monoorgano tin triamide compound. Exemplary reaction schemes for these reactions are:

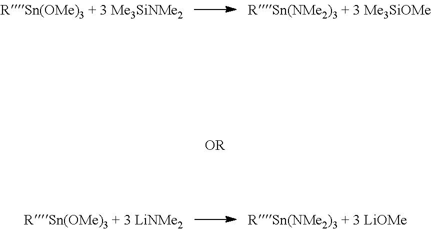

The reagents are preferably added in a dropwise fashion to control the exothermic reaction and the method steps are preferably performed in an inert atmosphere, such as nitrogen or argon. The reactants may be added neat (without solvent) and it is preferable to add the reactants quickly to achieve high productivity. However, it is preferable to perform the reactions in solvent to control the exothermic reaction. Appropriate solvents include, as previously explained, without limitation, hydrocarbons (such as, but not limited to, pentane, hexane, heptane, and cyclohexane), aromatics (such as, but not limited to, toluene and xylene), and ethers (such as, but not limited to, THF and Et₂O), and mixtures thereof. In some cases, most preferred solvents are ethers, such as THF.

After completing the reactions, the reaction mixtures are allowed to slowly warm to room temperature, such as over a period of about four hours, and then stirred for an additional period of time at room temperature, such as for about two to four hours. The reaction mixture is then filtered, such as through celite, to remove the metal byproduct. Other means of filtration which are known in the art may also be employed. The resulting salt is then rinsed, such as with anhydrous hexanes, and the solvent is removed under reduced pressure by means known in the art to produce a crude product.

In the methods described above, the crude product is distilled, such as at less than about 10 torr, preferably less than about 0.5 torr to yield the desired product containing the compound having formula (1″′) or (1″), for example, having a purity of greater than about 95 mol % and no more than about 5 mol % of the corresponding diorgano tin compound. In some embodiments, the compound having formula (1″) or (1″′) contains no more than about 5 mol % of the tin compound having formula (5″). The appropriate distillation conditions may be determined on a case-by-case basis depending on the desired product using routine experimentation. In preferred embodiments, the content of corresponding diorgano tin compound is less than about 4 mol %, less than about 3 mol %, less than about 2 mol %, less than about 1 mol %, less than about 0.5 mol %, less than about 0.1 mol %, or even lower, as described above; the desired compound may also be obtained in high yield. In preferred embodiments, the content of tin compound having formula (5″) is less than about 4 mol %, less than about 3 mol %, less than about 2 mol %, less than about 1 mol %, less than about 0.5 mol %, less than about 0.1 mol %, or even lower, as described above; the desired compound may also be obtained in high yield.

All of the method steps are preferably performed substantially without light exposure. Shielding may be accomplished by any method known in the art such as, for example, employing light-shielded containers such as amber glass, metal (SUS) containers, wrapping the container with a light-shielding cover such as cloth, foil or film, using light-shielding coatings, or performing the reactions in a dark room.

The distillation may be performed using a stainless steel column packed with a stainless steel packing material. Alternatively, the distillation may be performed in a light-shielded apparatus comprising glass such as glass equipment, glass-lined equipment, glass-coated equipment, etc. Shielding may be accomplished by any method known in the art such as, for example, employing light-shielded containers such as amber glass, metal (SUS) containers, wrapping the container with a light-shielding cover such as cloth, foil or film, using light-shielding coatings, or performing the distillation in a dark room.

In preferred embodiments, the methods described herein are performed in a solvent containing greater than about 50% by volume of a hydrocarbon solvent and/or an aromatic solvent such as, without limitation, those exemplified above. In preferred embodiments, the methods described herein are performed substantially without light exposure. In preferred embodiments, the solvents and reactants are dehydrated prior to use.

### Eighth Method [RSn(NR′2)]

An eighth method according to aspects of the disclosure is for synthesizing a monoorgano tin compound having formula (1), (1′), or (11) which comprises reacting a tin compound having formula R′Sn(OR)₃ with lithium dialkylamide.

An exemplary reaction scheme for this method is:

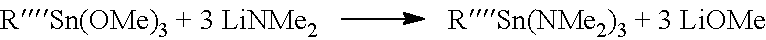

The reaction may be performed in a variety of solvents. Preferred solvents include hydrocarbons (such as, but not limited to, pentane, hexane, heptane, and cyclohexane), aromatics (such as, but not limited to, toluene and xylene), and ethers (such as, but not limited to, THF and Et₂O), and mixtures thereof. Most preferred solvents are aromatics, such as toluene.

Lower preferred temperatures for the reaction are about −78° C., about −40° C., about −20° C., about −10° C., most preferably about 0° C., as well as all intervening temperatures, and the upper limit of the reaction temperature is preferably about 100° C., about 90° C., or about 80° C., as well as all intervening temperatures. Thus, the preferred temperature range is about 0° C. to about 80° C. If the temperature is too low, the reaction rate will be too slow, whereas if the temperature is too high, byproducts will be produced. Most preferably, the reaction is performed at about −10° C. to about 10° C.

A solution containing the R′Sn(OR)₃ prior to the addition of the lithium dialkylamide preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %. It has been found that such dilute concentrations provide effective control of reaction temperature or solubility of the R′Sn(OR)₃ compound. On the other hand, the productivity is lower in dilute condition in industrial conditions.

The molar amount of the dialkylamide relative to the R′Sn(OR)₃ compound is preferably greater than about 3.0 equivalents, greater than about 3.05 equivalents, greater than about 3.09 equivalents, greater than about 3.10 equivalents, or greater than about 3.15 equivalents. If the relative amount is too low, the reaction speed may be too low and the amount of impurities may increase due to side reactions.

Following reaction of the two components, the reaction mixture is worked up and purified using methods well known in the art to produce the compound having formula (1).

### Ninth Method

A ninth method according to aspects of the disclosure is for synthesizing a monoorgano tin compound having formula (1″) which comprises reacting a tin compound having formula (1″′) (R″″Sn(OR)₃) with a (N,N-dialkylamino)trialkylsilane.

An exemplary reaction scheme for this method is:

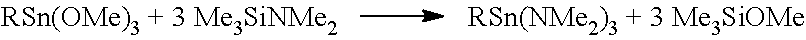

This reaction may be performed in a variety of solvents. Preferred solvents include hydrocarbons (such as, but not limited to, pentane, hexane, heptane, and cyclohexane), aromatics (such as, but not limited to, toluene and xylene), and ethers (such as, but not limited to, THF and Et₂O), and mixtures thereof. Most preferred solvents are aromatic such as toluene.

Lower preferred temperatures for the step are about −78° C., about −40° C., about −20° C., about −10° C., most preferably about 0° C., as well as all intervening temperatures, and the upper limit of the reaction temperature is preferably about 100° C., about 90° C., or about 80° C., as well as all intervening temperatures. Thus, the preferred temperature range is about 0° C. to about 80° C. If the temperature is too low, the reaction rate will be too slow, whereas if the temperature is too high, byproducts will be produced. Most preferably, the reaction is performed at about 80° C.

The molar amount of the silane reagent relative to the R″″Sn(OR)₃ compound is preferably greater than about 3.0 equivalents, greater than about 3.05 equivalents, greater than about 3.09 equivalents, greater than about 3.10 equivalents, or greater than about 3.15 equivalents. If the relative amount is too low, the reaction speed may be too low.

Following reaction of the two components, the reaction mixture is worked up and purified using methods well known in the art to produce the compound having formula (1″).

### Reduction of Additional Impurities

It is reasonable to presume that metallic impurities in organotin compounds are present as metal chlorides. If so, removal may be affected over an adsorbent, such as BASF CL-750, a chloride adsorbent known in the industry. Additional chloride impurities may be present, such as lithium chlorides which may be carried forward in the production process and become impurities of concern. Removal over a chloride-scavenging adsorbent, e.g., CL-750 or activated carbon may be effective for removal.

### Storage

Further aspects of the disclosure relate to methods of storing monoorgano tin compounds having formula (1), (1′), or (11) as described herein. A method of storing a sample (such as, but not limited to a sample of more than about 0.5 kg) of a monoorgano tin compound having formula (1), (1′), or (11) as described herein comprises storing the sample of the monoalkyl tin triamide compound having formula (1), (1′), or (11) substantially without light exposure and at any temperature, such as a temperature of less than about 30° C. The method may involve storing the compound having formula (1), (1′), or (11) in a container in an inert atmosphere and/or storing the compound having formula (1), (1′), or (11) in a container without light exposure such as, for example, in a dark room, by employing a light-shielded container such as amber glass, metal (SUS), wrapping the container with a light shielding cover such as cloth, foil or film, using light-shielding coatings, etc.

The sample of the monoorgano tin compound having formula (1), (1′), or (11) may be stored for up to about three days to about one year, such as about a week or longer, not more than about ten months, a period of about two to six weeks, and all intermediate times as desired. Preferably the sample is stored at a temperature of less than about 30° C., less than about 25° C., less than about 20° C., and preferably greater than about −10° C. “Substantively without light exposure” may be understood to mean that the sample is protected from light exposure to the greatest possible extent, such as by storage in an amber or stainless steel vessel or other means of light shielding as are known in the art and/or as described above. In embodiments, the sample of the monoorgano tin compound undergoes substantively no decomposition after a storage time of hours, up to about three days to about one year, or longer, as described above.

### Additional Aspects of the Disclosure

The organometallic tin compounds having formula (1) or (1′) form oxostannate cluster films on a silicon wafer after vapor phase deposition or spin-on coating processes. It has been found that a structure containing a small hydrocarbon ring bonded directly to a Sn atom provides more radiation sensitive Sn—C bonds that can be used to pattern structures lithographically. These are advantageous for EUV photoresist because the orbital interaction of the small cyclic hydrocarbon affects the Sn—C bond strength or the electronic state of tin and photosensitivity can be higher as a result.

The radicals and anions generated by EUV light may react with small cyclic hydrocarbon rings and ring-opening polymerize to form stronger R″′SnO_{(3/2-x/2)}(OH)ₓ (0<x≤3) films. The above reactions cause the R″′SnO_{(3/2-x/2)}(OH)ₓ (0<x≤3) cluster film in the irradiated area to change greatly, resulting in a higher contrast as a resist.

Further aspects of the disclosure relate to organotin compounds having formula (6):

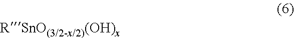

In formula (3), 0<x≤3 and R″′ has formula [I], [II], or [III] as defined above. Such compounds having formula (6) may be obtained by hydrolysis of a monoorgano tin compound having formula (1) or (1′) as described herein.

Additional aspects of the disclosure relate to solutions containing organotin compounds having formula (6) and an organic solvent such as, without limitation, a hydrocarbon solvent or an aromatic solvent as described above. Further aspects of the disclosure relate to films containing organotin compounds having formula (6) as described herein, which may be obtained by hydrolysis as previously explained.

Further aspects of the disclosure relate to compositions or mixtures containing a monoorgano tin compound having formula (1) and a R″ SnY₃ compound, wherein Y is a reactive ligand (which may also be understood to be a hydrolysable ligand) selected from a halogen atom, NR², and OR and R″ is an optionally substituted hydrocarbon group having about 2 to about 20 carbon atoms which is different from R′ or R″. Preferably Rⁿ is a primary alkyl group (such as methyl, ethyl, n-propyl, n-butyl, n-pentyl, etc.; preferred are methyl or ethyl groups), a secondary alkyl (linear or cyclic) group, such as isopropyl, isobutyl, sec-butyl, cyclohexyl, isopentyl, sec-pentyl, etc.; presently preferred is isopropyl), or a tertiary alkyl group such as tert-pentyl, 3-ethyl 3-pentyl, methyl 3-pentyl, and the preferred t-butyl. When R′ in the compound having formula (1) is a tertiary aralkyl group or a tertiary alkyl group having an ether linkage, Rⁿ is preferably a primary or secondary alkyl group, more preferably a secondary alkyl group, to balance sensitivity with stability. Also, when R′ in the compound having formula (1) is a secondary aralkyl group or a secondary alkyl group having an ether linkage, Rⁿ is preferably a primary or tertiary alkyl group, more preferably a tertiary alkyl group. When R″ in the compound having formula (1′) is a cyclic tertiary hydrocarbon group, Rⁿ is preferably a primary or secondary alkyl group, more preferably a secondary alkyl group, to balance sensitivity with stability. Also, when R″ in the compound having formula (1′) is a secondary cyclic hydrocarbon group, Rⁿ is preferably a primary or tertiary alkyl group, more preferably a tertiary alkyl group.

Additional aspects of the disclosure relate to a composition containing an organotin compound having formula (6) and an organotin compound having formula (7):

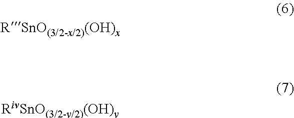

In formulas (6) and (7), 0<x≤3, 0<y≤3, R″′ has been described previously and R^{iv} is an optionally substituted hydrocarbon group having 2 to about 20 carbon atoms which is different from R″′, as previously described, such as a hydrocarbon group substituted with a halogen atom, an alkoxy group, or a dialkylamino group (such as dimethylamino, diethylamino, etc.). Such compounds having formula (6) and (7) may be obtained by hydrolysis of a monoorgano tin compound having formula (1) or (1′) as described herein. If the compounds having formula (6) and (7) are obtained from mixtures of formula (1) and R″ SnY₃ compounds, the compounds having formula (6) and (7) may exist in the same molecule. A compound which has formula (6) and (7) compounds in the same molecule is preferable in terms of high uniformity of solubility and molecular weight for use as resist materials.

Further aspects of the disclosure relate to a solution containing an organic solvent as described herein and a composition containing organotin compounds having formula (6) and formula (7), which may, in some embodiments, be obtained by hydrolysis of a monoorgano tin compound having formula (1) as described herein. Additional aspects of the disclosure relate to films prepared from or containing a composition containing organotin compounds having formula (6) and (7).

The compounds described herein may be used as resist materials after hydrolysis or other reactions such as those known in the art. The compounds described herein may contain a group which is capable of forming an alkyltin oxo-hydroxo-patterning composition which may be hydrolyzed with water or other suitable reagents under suitable conditions to form an alkyltin oxo-hydroxo-patterning composition which may be represented by the formula R″′SnO(3/2-x/2)(OH)x (0<x≤3). Hydrolysis and condensation reactions that may alter a compound with hydrolytic groups (X) are shown in the following reactions:

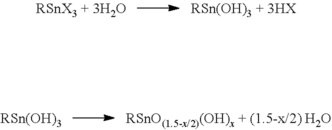

Alkyl oxohydroxy tin compounds obtained by hydrolysis using a composition containing R′SnX₃ compounds as described above as raw material and the oxohydroxy tin compounds represented by the formula R″′SnO(3/2-x/2)(OH)x (0<x≤3) may be used as an EUV resist material.

A method for obtaining oxohydroxy tin compounds (R′SnO or R″SnO) by hydrolyzing a composition containing a R′SnX₃ or R″SnX₃ compound may involve, for example, volatilizing a composition containing a R′SnX₃ or R″SnX₃ compound under heating or reduced pressure, and reacting the vapor generated by volatilizing the composition on a substrate on which the tin composition is deposited, with water vapor, etc. (a dry method). In this method, a thin film containing the tin compound R′SnO or R″SnO may be formed on the substrate.

Another method may involve reacting a composition containing a R′SnX₃ or R″SnX₃ compound in solution or in a solid state with water, etc., and hydrolyzing it to obtain the oxohydroxy tin compounds (R′SnO or R″SnO). The oxohydroxy tin compounds (R′SnO or R″SnO) may then be used as a coating solution by dissolving it in an organic solvent, for example. The organic solvent is not limited, however in particular, suitable solvents include, for example, aromatic compounds (e.g., xylenes, toluene), ethers (anisole, tetrahydrofuran), esters (propylene glycol monomethyl ether acetate, ethyl acetate, ethyl lactate), alcohols (e.g., 4-methyl-2-propanol, 1-butanol, methanol, isopropyl alcohol, 1-propanol), ketones (e.g., methyl ethyl ketone), halogen solvents (e.g., CH₂Cl₂, CHCl₃) and mixtures thereof. In general, organic solvent selection may be influenced by solubility parameters, volatility, flammability, toxicity, viscosity and potential chemical interactions with other processing materials.

The solution may be applied to a substrate by any coating or printing technique, and a thin film or coating containing oxohydroxy tin compounds (R′SnO or R″SnO) may be formed on the substrate. After the components of the solution are dissolved and combined, the character of the species may change as a result of partial hydration and condensation, especially during the coating process.

The thin film obtained by any of the above methods may be stabilized or partially condensed prior to light irradiation through drying, heating, or other processes. Generally, thin films or coatings have an average thickness of less than about 10 microns, and very thin submicron thin films, e.g., less than about 100 nanometers (nm), even less than about 50 nm or less than about 30 nm, may be desirable for patterning very small features. The resulting thin film or coating may be called a resist because the exposure processes a portion of the composition to be resistant to development/etching.

The thin film or coating may be exposed to appropriate radiation, (e.g., extreme ultraviolet, electron beam, deep ultraviolet, or ultraviolet), using a selected pattern or negative portion of the pattern to form a latent image with developer resistant and developer soluble regions. After exposure to the appropriate radiation and prior to development, the thin film or coating may be heated or otherwise reacted to further differentiate the latent image from the non-irradiated areas. The latent image is brought into contact with the developer to form a physical image, i.e., a patterned thin film or coating. The patterned thin film or coating may be further heated to stabilize the remaining patterned coating on the surface. The patterned coating may be used as a physical mask to perform further processing according to the pattern, e.g., etching of the substrate and/or attachment of additional materials. After the patterned resist is used as requested, the remaining patterned coating may be removed at an appropriate point in the processing, but the patterned coating may also be incorporated into the final structure.

The invention will now be described in connection with the following, non-limiting examples.

### Example A1-1 (Prophetic): Synthesis of 1-phenyl-ethyl tris(dimethylamino)tin

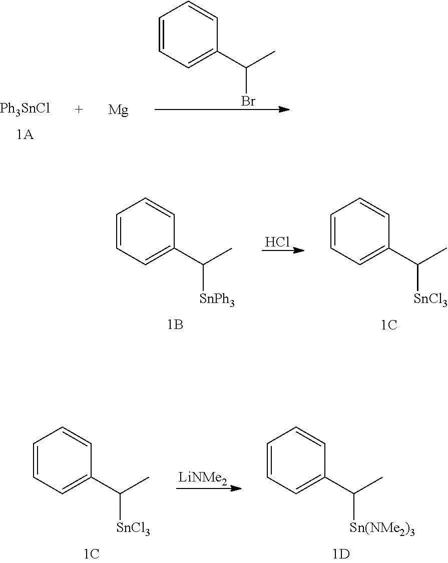

Magnesium turnings (1.0 eq) and a partial portion of THF are charged into a flask under a nitrogen atmosphere. To the mixture a catalytic amount of I₂ is slowly added for activation until the color disappears. The rest of the THF and Ph₃SnCl (1A) (1.0 eq) are charged into the reactor, following by beginning the addition of 1-bromoethyl-benzene (1.1 eq) with gentle reflux of THF. The reflux conditions are continued for 3 hours after the addition, then stirred at room temperature overnight. The resulting reaction solution is diluted with toluene, quenched with water, and the organic layer is extracted. The resulting organic layer is concentrated to give a solution containing compound 1B. The solution is diluted with toluene, and HCl gas (in excess of 3 eq) is circulated at 20° C. to 50° C. After 100 h of reaction, the disappearance of the raw material is confirmed by NMR. The resulting solution is concentrated under reduced pressure to obtain the crude product 1C. The crude product is purified by fractional distillation under reduced pressure to obtain highly pure 1C.

Dehydrated hexane and nBuLi (3 eq) are added to a flask under a nitrogen atmosphere, and the flask is cooled to 0° C. To the solution of hexane and nBuLi, HNMe₂ (6 eq) is slowly added to obtain a slurry solution of LiNMe₂. 1C (1.0 eq) diluted with dehydrated hexane is slowly added dropwise to the resulting slurry solution. The solution is then stirred at room temperature for 2 h and filtered under nitrogen by a filter loaded with Celite. The solid is then washed twice with dehydrated hexane, and the filtrates are combined. The resulting solution is then distilled under reduced pressure to remove the solvent to obtain a crude product containing 1D, which was then subjected to fractional distillation in a distillation column to obtain highly pure 1D. ¹¹⁹Sn NMR (400 mHz; neat) and ¹H NMR (400 mHz; C₆D₆) are measured and confirmed to be the title compound.

### Example A1-2 (Prophetic): Synthesis of 1-Methyl-1-phenyl-ethyl-tris(dimethylamino)tin

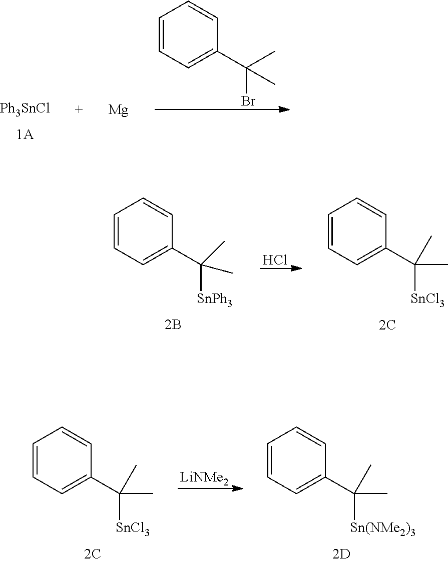

Magnesium turnings (1.0 eq) and a partial portion of THF are charged into a flask under a nitrogen atmosphere. To the mixture a catalytic amount of I₂ is slowly added for activation until the color disappears. The rest of the THF and Ph₃SnCl (1A) (1.0 eq) are charged into the reactor, following by beginning the addition of (1-bromo-1-methyl-ethyl)-benzene (1.1 eq) with gentle reflux of THF. The reflux conditions are continued for 3 hours after the addition, then stirred at room temperature overnight. The resulting reaction solution is diluted with toluene, quenched with water, and the organic layer is extracted. The resulting organic layer is concentrated to give a solution containing compound 2B. The solution is diluted with toluene, and HCl gas (in excess of 3 eq) is circulated at 20° C. to 50° C. After 100 h of reaction, the disappearance of the raw material is confirmed by NMR. The resulting solution is concentrated under reduced pressure to obtain the crude product 2C. The crude product is purified by fractional distillation under reduced pressure to obtain highly pure 2C.

Dehydrated hexane and nBuLi (3 eq) are added to a flask under a nitrogen atmosphere, and the flask is cooled to 0° C. To the solution of hexane and nBuLi, HNMe₂ (6 eq) is slowly added to obtain a slurry solution of LiNMe₂. 1C (1.0 eq) diluted with dehydrated hexane is slowly added dropwise to the resulting slurry solution. The solution is then stirred at room temperature for 2 h and filtered under nitrogen by a filter loaded with Celite. The solid is then washed twice with dehydrated hexane, and the filtrates are combined. The resulting solution is then distilled under reduced pressure to remove the solvent to obtain a crude product containing 2D, which was then subjected to fractional distillation in a distillation column to obtain highly pure 2D (>99% purity). ¹¹⁹Sn NMR (400 mHz; neat) and ¹H NMR (400 mHz; C₆D₆) are measured and confirmed to be the title compound.

### Example A1-3 (Prophetic): Synthesis of diphenyl-methyl-tris(dimethylamino)tin

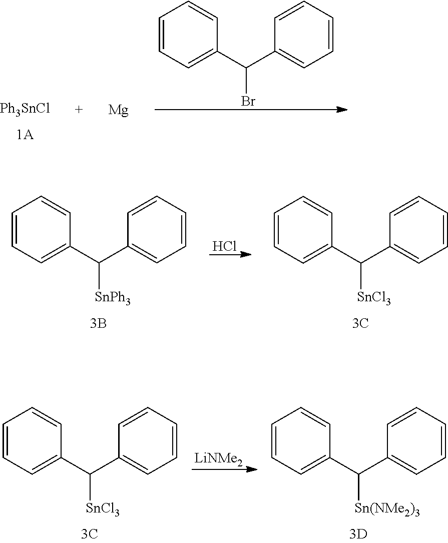

Magnesium turnings (1.0 eq) and a partial portion of THF are charged into a flask under a nitrogen atmosphere. To the mixture a catalytic amount of I₂ is slowly added for activation until the color disappears. The rest of the THF and Ph₃SnCl (1A) (1.0 eq) are charged into the reactor, following by beginning the addition of bromo-diphenyl-methane (1.1 eq) with gentle reflux of THF. The reflux conditions are continued for 3 hours after the addition, then stirred at room temperature overnight. The resulting reaction solution is diluted with toluene, quenched with water, and the organic layer is extracted. The resulting organic layer is concentrated to give a solution containing compound 3B. The solution is diluted with toluene, and HCl gas (in excess of 3 eq) is circulated at 20° C. to 50° C. After 100 h of reaction, the disappearance of the raw material is confirmed by NMR. The resulting solution is concentrated under reduced pressure to obtain the crude product 3C. The crude product is purified by fractional distillation under reduced pressure to obtain highly pure 3C.

Dehydrated hexane and nBuLi (3 eq) are added to a flask under a nitrogen atmosphere, and the flask is cooled to 0° C. To the solution of hexane and nBuLi, HNMe₂ (6 eq) is slowly added to obtain a slurry solution of LiNMe₂. 3C (1.0 eq) diluted with dehydrated hexane is slowly added dropwise to the resulting slurry solution. The solution is then stirred at room temperature for 2 h and filtered under nitrogen by a filter loaded with Celite. The solid is then washed twice with dehydrated hexane, and the filtrates are combined. The resulting solution is then distilled under reduced pressure to remove the solvent to obtain a crude product containing 3D, which was then subjected to fractional distillation in a distillation column to obtain highly pure 3D (>99% purity). ¹¹⁹Sn NMR (400 mHz; neat) and ¹H NMR (400 mHz; C₆D₆) are measured and confirmed to be the title compound.

### Example A2-1 (Prophetic): Preparation of Mixture

Isopropyl tris(dimethylamino)tin (iPrSn(NMe₂)₃) was prepared according to the method described in U.S. Patent Application Publication No. 2022/0242888. A mixture is prepared which contains 0.3 g of the compound prepared in Example 1-1 and 0.7 g isopropyl tris(dimethylamino)tin (iPrSn(NMe₂)₃). The product is filled into amber vessels without light exposure and stored under an inert gas atmosphere.

### Examples A2-2 to 2-3 (Prophetic): Preparation of Mixtures

Mixtures are prepared as described in Example 2-1, each containing 0.7 g iPrSn(NMe₂)₃ and 0.3 g of a compound prepared in Example 1-2 to 1-3. The product is filled into amber vessels without light exposure and stored under an inert gas atmosphere.

### Example A3-1 (Prophetic): Preparation and Analysis of R′SnO(3/2-x/2)(OH)x Compounds (where 0<x≤3) by Hydrolysis

To a 100-mL flask under an inert gas atmosphere are added 10 mL n-hexane (dehydrated) and 1.0 g 1-phenyl-ethyl-tris(dimethylamino)tin, which is synthesized as described in Example 1, and dissolved with stirring at 150 rpm. After cooling the resulting solution to 0-10° C., demineralized water (1.0 mL, resistance 18.2 MΩ) is added by syringe over 10 minutes while stirring at 150 rpm and maintaining a temperature of 0-10° C. to form a suspension. The resulting suspension is filtered through a funnel (Kiriyama filter paper 5B) to obtain a white solid. The resulting white solid is washed with 3 mL of demineralized water and then dried in vacuo at 40° C. for 8 h. The resulting white solid (SnO-1) product is filled into amber vessels without light exposure and stored under an inert gas atmosphere.

SnO-1 is identified by NMR using a Bruker Avance Neo 600 MHz Probe: cryo 5 mm BBO and by ESI-Mass spectroscopy to be a compound corresponding to R′SnO_{(3/2-x/2)}(OH)x (where 0<x≤3).

### Example A3-2 (Prophetic): Preparation and Analysis of Mixture of R′SnO_{(3/2-x/2)}(OH)ₓ and R″SnO_{(3/2-v/2)}(OH)ᵥ (where 0<x≤3, 0<y≤3) by Hydrolysis

A white solid (SnO-2) is obtained from 0.3 g of the compound prepared as described in Example 1-1 and 0.7 g isopropyl tris(dimethylamino)tin using the same method described in Example A3-1. The product is filled into amber vessels without light exposure and stored under an inert gas atmosphere.

SnO-2 is identified by NMR using a Bruker Avance Neo 600 MHz Probe: cryo 5 mm BBO) and ESI-Mass spectroscopy to be a compound corresponding to R′SnO_{(3/2-x/2)}(OH)ₓ and R″SnO_{(3/2-y/2)}(OH)_{y} (where 0<x≤3, 0<y≤3) which are blended in the same molecule.

### Example A4-1 (Prophetic): Preparation of Film

The SnO-1 of Example A3-1 is dissolved in chloroform (5 mL) to a concentration of 2.0 wt % while using ultrasonic waves, and the resulting solution is filtered through a 0.20 μm syringe filter to obtain a resist solution containing a transparent tin compound. Silicon wafers with oxide surfaces (Si substrate, 100 mm diameter) are ozonated and used as 25 substrates for resist thin film deposition. The surface of the Si substrate is treated with hexamethyldisilazane (HMDS) vapor prior to resist deposition. The resist solution is spin coated onto the substrate at 2000 rpm and baked on a hot plate at 90° C. for 2 minutes. The film thickness after coating and baking is measured by ellipsometer.

### Example A4-2 (Prophetic): Preparation of Film

The SnO-2 of Example A3-2 is dissolved in chloroform (5 mL) to a concentration of 2.0 wt % while using ultrasonic waves, and the resulting solution is filtered through a 0.20 um syringe filter to obtain a resist solution containing a transparent tin compound. Silicon wafers with oxide surfaces (Si substrate, 100 mm diameter) are ozonated and used as 25 substrates for resist thin film deposition. The surface of the Si substrate is treated with hexamethyldisilazane (HMDS) vapor prior to resist deposition. The resist solution is spin-coated onto the substrate at 2000 rpm and baked on a hot plate at 90° C. for 2 minutes. The film thickness after coating and baking is measured by ellipsometer.

### Example A5-1 (Prophetic): Formation of Image on Substrate

The coated substrate (film) from Example A4-1 is exposed to ultraviolet light (light source: xenon excimer lamp (172 nm, 7.2 eV) manufactured by USHIO INC., light source intensity: 0.7 mW/cm₂) using a pattern to project a pattern on the substrate. The substrate is then immersed in 2-5 heptanone for 15 seconds and rinsed with the same developer for another 15 seconds to form a negative-type image, i.e., an image in which the unexposed portion of the thin film is removed and only the pattern-exposed portion remains.

### Example A5-2 (Prophetic): Formation of Image on Substrate

The coated substrate (film) from Example A4-2 is exposed to ultraviolet light (light source: xenon excimer lamp (172 nm, 7.2 eV) manufactured by USHIO INC., light source intensity: 0.7 mW/cm₂) using a pattern to project a pattern on the substrate. The substrate is then immersed in 2-5 heptanone for 15 seconds and rinsed with the same developer for another 15 seconds to form a negative-type image, i.e., an image in which the unexposed portion of the thin film is removed and only the pattern-exposed portion remains.

### Example B1-1 (Prophetic): Synthesis of 1-methoxy-methyl-tris(dimethylamino)tin

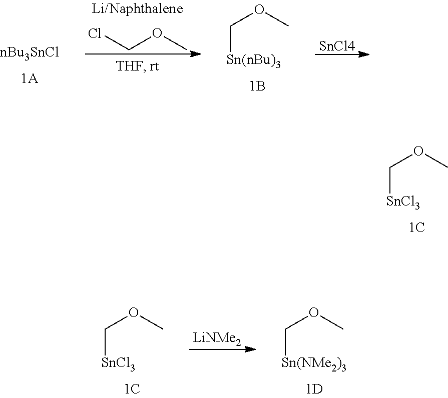

Lithium granular (1 eq), THF and naphthalene (5 mol %) are added to a flask in a glovebox. The flask is cooled to 0° C. To this flask are added nBu₃SnCl (1A) dropwise through an additional funnel at 0° C. with THF. The mixture is stirred at room temperature for 12 h. After cooling the resulting mixture to 0° C., chloromethyl methyl ether (1.2 eq) is slowly added and the temperature is then raised to room temperature and allowed to react for an additional 2 hr. The resulting reaction solution is diluted with toluene, quenched with water, and the organic layer is extracted. The resulting organic layer is concentrated to give a solution containing compound 1B.

The 1B solution is diluted with toluene, and to the diluted is added SnCl₄ (excess amount, 10 eq) and stirred for 30 h at reflux condition. The disappearance of the starting material is confirmed by NMR. The resulting solution is concentrated under reduced pressure to obtain the crude product 1C. The crude product is purified by fractional distillation under reduced pressure to obtain highly pure 1C.

Dehydrated hexane and nBuLi (3 eq) are added to a flask under a nitrogen atmosphere, and the flask is cooled to 0° C. To the solution of hexane and nBuLi, HNMe₂ (6 eq) is slowly added to obtain a slurry solution of LiNMe₂. 1C (1.0 eq) diluted with dehydrated hexane is slowly added dropwise to the resulting slurry solution. The solution is then stirred at room temperature for 2 h and filtered under nitrogen by a filter loaded with Celite. The solid is then washed twice with dehydrated hexane, and the filtrates are combined. The resulting solution is then distilled under reduced pressure to remove the solvent to obtain a crude product containing 1D, which was then subjected to fractional distillation in a distillation column to obtain highly pure 1D. ¹¹⁹Sn NMR (400 mHz; neat) and ¹H NMR (400 mHz; C₆D₆) are measured and confirmed to be the title compound.

### Example B1-2 (Prophetic): Synthesis of 1-methyl-(1-methoxy)-methyl-tris(dimethylamino)tin

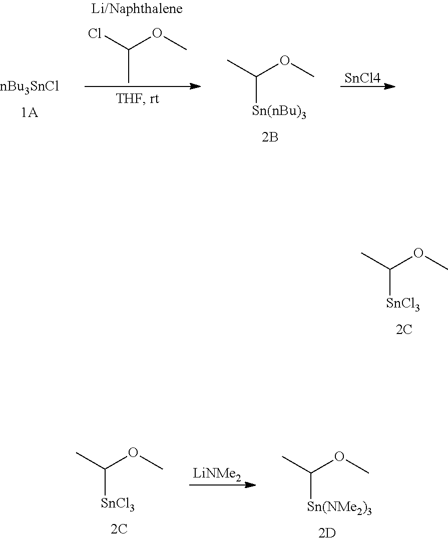

The title compound 2D is prepared as described in Example B1-1, except that chloromethyl ethyl ether is used instead of 1-chloroethylmethyl ether.

### Example B1-3 (Prophetic): Synthesis of 1,1-dimethyl-(1-methoxy)-methyl-tris(dimethylamino)tin

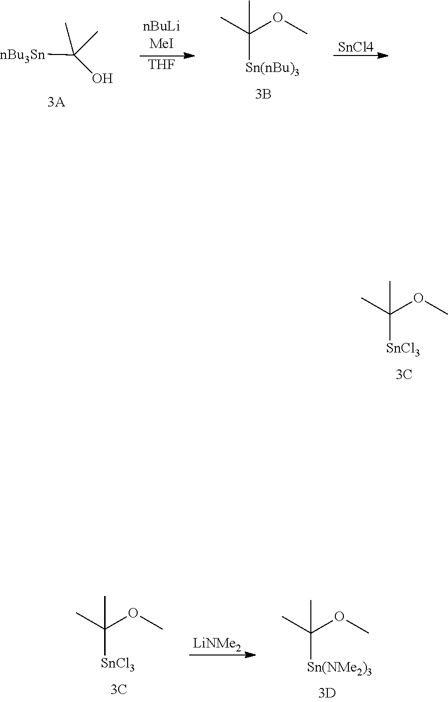

The title compound 3D is prepared as described in Example B1-1, except that 3B is prepared from 3A, nBuLi, and Mel as described in Journal of the American Chemical Society, 110(18), 6249-51) (1988) and Tetrahedron 45 (2), 495 (1989).

### Example B2-1 (Prophetic): Preparation of Mixture

Isopropyl tris(dimethylamino)tin (iPrSn(NMe₂)₃) was prepared according to the method described in U.S. Patent Application Publication No. 2022/0242888. A mixture is prepared which contains 0.3 g of the compound prepared in Example 1-1 and 0.7 g isopropyl tris(dimethylamino)tin (iPrSn(NMe₂)₃). The product is filled into amber vessels without light exposure and stored under an inert gas atmosphere.

### Examples B2-2 to B2-3 (Prophetic): Preparation of Mixtures

Mixtures are prepared as described in Example 2-1, each containing 0.7 g iPrSn(NMe₂)₃ and 0.3 g of a compound prepared in Example 1-2 to 1-3. The product is filled into amber vessels without light exposure and stored under an inert gas atmosphere.

### Example B3-1 (Prophetic): Preparation and Analysis of R′SnO(3/2-x/2)(OH)x Compounds (where 0<x≤3) by Hydrolysis

To a 100-mL flask under an inert gas atmosphere are added 10 mL n-hexane (dehydrated) and 1.0 g 1-phenyl-ethyl-tris(dimethylamino)tin, which is synthesized as described in Example 1, and dissolved with stirring at 150 rpm. After cooling the resulting solution to 0-10° C., demineralized water (1.0 mL, resistance 18.2 MΩ) is added by syringe over 10 minutes while stirring at 150 rpm and maintaining a temperature of 0-10° C. to form a suspension. The resulting suspension is filtered through a funnel (Kiriyama filter paper 5B) to obtain a white solid. The resulting white solid is washed with 3 mL of demineralized water and then dried in vacuo at 40° C. for 8 h. The resulting white solid (SnO-1) product is filled into amber vessels without light exposure and stored under an inert gas atmosphere.

SnO-1 is identified by NMR using a Bruker Avance Neo 600 MHz Probe: cryo 5 mm BBO and by ESI-Mass spectroscopy to be a compound corresponding to R′SnO (3/2-x/2)(OH)x (where 0<x≤3).

### Example B3-2 (Prophetic): Preparation and Analysis of Mixture of R′SnO_{(3/2-x/2)}(OH)ₓ and R″SnO_{(3/2-v/2)}(OH)ᵥ (Where 0<x≤3, 0<y≤3) by Hydrolysis

A white solid (SnO-2) is obtained from 0.3 g of the compound prepared as described in Example B1-1 and 0.7 g isopropyl tris(dimethylamino)tin using the same method described in Example B3-1. The product is filled into amber vessels without light exposure and stored under an inert gas atmosphere.

SnO-2 is identified by NMR using a Bruker Avance Neo 600 MHz Probe: cryo 5 mm BBO) and ESI-Mass spectroscopy to be a compound corresponding to R′SnO_{(3/2-x/2)}(OH)ₓ and R″SnO_{(3/2-y/2)}(OH)_{y} (where 0<x≤3, 0<y≤3) which are blended in the same molecule.

### Example B4-1 (Prophetic): Preparation of Film

The SnO-1 of Example B3-1 is dissolved in chloroform (5 mL) to a concentration of 2.0 wt % while using ultrasonic waves, and the resulting solution is filtered through a 0.20 μm syringe filter to obtain a resist solution containing a transparent tin compound. Silicon wafers with oxide surfaces (Si substrate, 100 mm diameter) are ozonated and used as 25 substrates for resist thin film deposition. The surface of the Si substrate is treated with hexamethyldisilazane (HMDS) vapor prior to resist deposition. The resist solution is spin coated onto the substrate at 2000 rpm and baked on a hot plate at 90° C. for 2 minutes. The film thickness after coating and baking is measured by ellipsometer.

### Example B4-2 (Prophetic): Preparation of Film

The SnO-2 of Example B3-2 is dissolved in chloroform (5 mL) to a concentration of 2.0 wt % while using ultrasonic waves, and the resulting solution is filtered through a 0.20 um syringe filter to obtain a resist solution containing a transparent tin compound. Silicon wafers with oxide surfaces (Si substrate, 100 mm diameter) are ozonated and used as 25 substrates for resist thin film deposition. The surface of the Si substrate is treated with hexamethyldisilazane (HMDS) vapor prior to resist deposition. The resist solution is spin-coated onto the substrate at 2000 rpm and baked on a hot plate at 90° C. for 2 minutes. The film thickness after coating and baking is measured by ellipsometer.

### Example B5-1 (Prophetic): Formation of Image on Substrate

The coated substrate (film) from Example B4-1 is exposed to ultraviolet light (light source: xenon excimer lamp (172 nm, 7.2 eV) manufactured by USHIO INC., light source intensity: 0.7 mW/cm2) using a pattern to project a pattern on the substrate. The substrate is then immersed in 2-5 heptanone for 15 seconds and rinsed with the same developer for another 15 seconds to form a negative-type image, i.e., an image in which the unexposed portion of the thin film is removed and only the pattern-exposed portion remains.

### Example B5-2 (Prophetic): Formation of Image on Substrate

The coated substrate (film) from Example B4-2 is exposed to ultraviolet light (light source: xenon excimer lamp (172 nm, 7.2 eV) manufactured by USHIO INC., light source intensity: 0.7 mW/cm²) using a pattern to project a pattern on the substrate. The substrate is then immersed in 2-5 heptanone for 15 seconds and rinsed with the same developer for another 15 seconds to form a negative-type image, i.e., an image in which the unexposed portion of the thin film is removed and only the pattern-exposed portion remains.

### Example C1-1: Synthesis of 1-Methyl-cyclopentyl tris(dimethylamino)tin

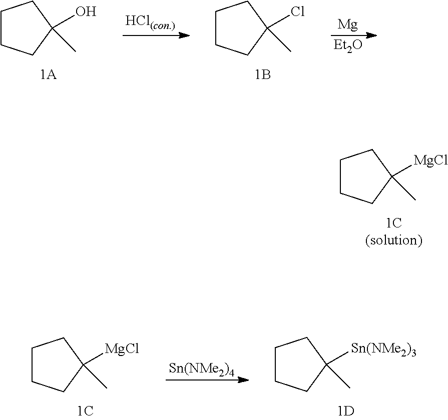

1-methylcyclopentanol (1A) (701 g, 7 mol) and Et2O (1.5 L) were dissolved in a flask under a nitrogen atmosphere. Conc. HCl (37 wt %, 2.1 L, 28 mol) was slowly dropped into the flask and stirred at room temperature for 3 h. The organic layer of the resulting solution containing 1B was extracted, and the organic layer was dried with MgSO4. The resulting solution containing 1B was concentrated to remove solvent. The product (1B) was distilled by packed column (70% yield, GC: 95%) (bp. 28° C., 20 mmHg).

Dehydrated Et2O (2.2 L), magnesium turnings (57.4 g, 2.36 mol), and a catalytic amount of iodine were added until the Mg turnings were activated. The compound (1B) (266 g, 2.25 mol) in Et2O (2.2 L) was added dropwise and the temperature was controlled by reflux of solvent. After 2 hours of reflux conditions, a 0.5 M solution of 1C was obtained.

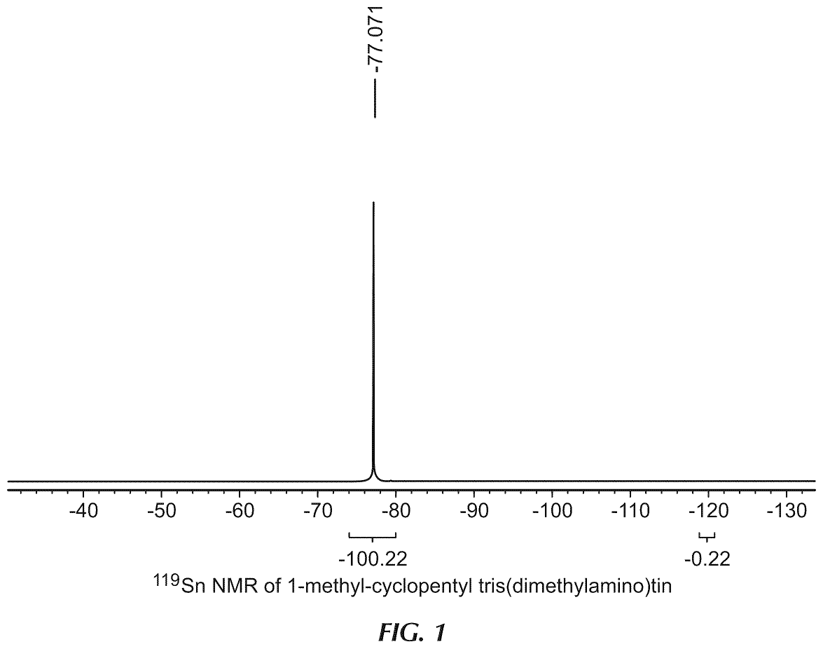

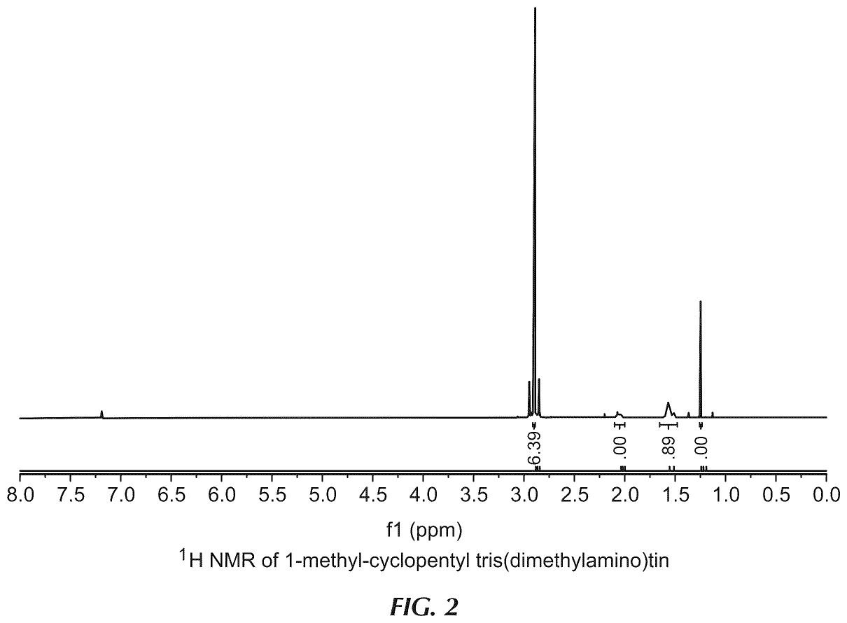

To a 5 L flask under nitrogen atmosphere, hexane (965 mL) and Sn(NMe₂)₄ (376 g, 1.28 mol) were added and allowed to cool to 0° C. The 0.5M 1C solution (2.56 L, 1.28 mol) was slowly added to the solution at −10° C.-10° C. The resulting mixture was stirred at room temperature for 15 h and filtered under nitrogen to obtain a solution. The solid was then washed twice with hexane, and the filtrates were combined. The resulting solution was then distilled under reduced pressure to remove the solvent and obtain a crude mixture containing 1D. The crude 1D was distilled by packed column and the title compound product 1D was obtained (250 g, >99.9% purity) (bp: 78.3-83.9° C. at 0.8 mmHg). The product was filled into amber vessels without light exposure and stored under an inert gas atmosphere. 119Sn NMR (400 MHz; neat) −77.1 and 1H NMR (400 MHz; C6D6): 2.9 (s, 18H), 2.0-2.2 (m, 2H), 1.5-1.7 (m, 6H), 1.5 (s, 3H), see FIG. 1 and FIG. 2.

### Example C1-2: (Prophetic): Synthesis of 1-Methyl-cyclobutyl tris(dimethylamino)tin

1-methylcyclobutanol (2A) and toluene are dissolved in a flask under a nitrogen atmosphere. Conc. HCl is slowly dropped into the flask and stirred at room temperature for 3 h. The organic layer of the resulting solution containing 2B is extracted, and the organic layer is washed twice with brine and dried with Na2SO4. The resulting solution containing 2B is concentrated, and dehydrated Et2O and magnesium turnings are added. The mixture is heated to reflux conditions while using a cooling condenser, and a catalytic amount of 12 is slowly added for activation. After 3 hours of reflux conditions, the mixture is filtered to yield a 0.5 M solution of 2C.

In a flask under nitrogen atmosphere, toluene and Sn(NMe2)4 are added and allowed to cool to 0° C. The 0.5M 2C solution is slowly added to the solution. The resulting mixture is stirred at room temperature for 2 h and filtered under nitrogen with a filter loaded with Celite to obtain a solution. The solid is then washed twice with dehydrated hexane, and the filtrates are combined. The resulting solution is then distilled under reduced pressure to remove the solvent to obtain a crude mixture containing 2D. The crude 2D is distilled by packed column and the product 2D is obtained (>99.9% purity). The product is filled into amber vessels without light exposure and stored under an inert gas atmosphere. 119Sn NMR (400 mHz; neat) and 1H NMR (400 mHz; C6D6) is measured and used to confirm the product.

### Example C1-3 (Prophetic): Synthesis of 1-Methyl-cyclopropyl tris(dimethylamino)tin

1-methylcyclopropanol (3A) and toluene are dissolved in a flask under nitrogen atmosphere. Conc. HCl is slowly dropped into the flask and stirred at room temperature for 3 h. The organic layer of the resulting solution containing 3B is extracted, and the organic layer is washed twice with brine and dried with Na2SO4. The resulting solution containing 3B is concentrated, and dehydrated Et2O and magnesium turnings are added. The mixture is heated to reflux conditions while using a cooling condenser, and a catalytic amount of 12 is slowly added for activation. After 3 hours of reflux conditions, the mixture is filtered to yield a 0.5 M solution of 3C.

In a flask under nitrogen atmosphere, toluene and Sn(NMe2)4 are added and allowed to cool to 0° C. The 0.5M 3C solution is slowly added to the solution. The resulting mixture is stirred at room temperature for 2 h and filtered under nitrogen with a filter loaded with Celite to obtain the solution. The solid is then washed twice with dehydrated hexane, and the filtrates are combined.

The resulting solution is then distilled under reduced pressure to remove the solvent to obtain a crude mixture containing 3D. The crude 3D is distilled by packed column and the product 3D is obtained (>99.9% purity). The product is filled into amber vessels without light exposure and stored under an inert gas atmosphere. 119Sn NMR (400 mHz; neat) and 1H NMR (400 mHz; C6D6) are measured and used to confirm the product.

### Example C1-4 (Prophetic): Synthesis of Cyclopentyl tris(dimethylamino)tin

Anhydrous hexanes 3 L and n-BuLi (1.24 kg, 4.64 mol, 2.4 M solution in hexanes) are charged into a 22 L reactor. Dimethylamine (417 g, 9.27 mol) is added subsurface at about −10 to 10° C. The reaction mixture is stirred for an additional four hours and continuously cooled to about −10° C. to 10° C. To the mixture is added 4A (1.50 mol in hexanes 500 mL) dropwise at about −10° C. to 10° C. The resulting mixture is allowed to warm to room temperature over four hours and stirred for an additional four hours at room temperature. The reaction mixture is filtered through sparkler to remove the LiCl byproduct. The salt is rinsed with anhydrous hexanes (2×500 mL). The solvent is removed under reduced pressure to obtain a crude mixture containing 4B. The crude 4B is distilled by packed column and the product 4B is obtained (>99.9% purity). The product is filled into amber vessels without light exposure and stored under an inert gas atmosphere. 119Sn NMR (400 mHz; neat) and 1H NMR (400 mHz; C6D6) are measured and used to confirm the product.

### Example C1-5 (Prophetic): Synthesis of Cyclopropyl tris(tert-butoxy)tin

In a 5.0 L flask are placed 252.47 g (2.25 mole) of t-BuOK and 3.5 L of hexanes and cooled to 0° C. To this mixture, 189.08 g (0.75 moles) of 5A is added dropwise while maintaining the pot temperature at 0 to 10° C. The resulting mixture is allowed to warm to room temperature over four hours and stirred for an additional four hours at room temperature. The reaction mixture is filtered through sparkler to remove the NaCl byproduct. The salt is rinsed with anhydrous hexanes (2×500 mL). The solvent is removed under reduced pressure to obtain a crude mixture containing 5B. The crude 5B is distilled by packed column and the product 5B is obtained (>99.9% purity). The product is filled into amber vessels without light exposure and stored under an inert gas atmosphere. 119Sn NMR (400 mHz; neat) and 1H NMR (400 mHz; C6D6) are measured and used to confirm the product.

### Example C1-6 (Prophetic): Synthesis of cyclopropyl tris(tert-butoxy)tin

In a 5.0 L flask are placed 2.25 mole of LiNMe₂ and 3.5 L of THF and cooled to 0° C. To this mixture 0.75 moles of 6B are added dropwise while maintaining the pot temperature at 0 to 10° C. The resulting mixture is allowed to warm to reflux temperature over four hours and stirred for an additional 20 hours at reflux temperature. The reaction mixture is filtered to obtain 6B solution. To the 6B solution 0.75 moles of 6C are added dropwise while maintaining the pot temperature at 0 to 10° C. The resulting mixture is allowed to warm to room temperature over four hours and stirred for an additional four hours at room temperature. The reaction mixture is filtered through sparkler to remove the LiI byproduct. The salt is rinsed with anhydrous hexanes (2×500 mL). The solvent is removed under reduced pressure to obtain a crude mixture containing 6D. The crude 6D is distilled by packed column and the product 6D is obtained (>99.9% purity). The product is filled into amber vessels without light exposure and stored under an inert gas atmosphere. 119Sn NMR (400 mHz; neat) and 1H NMR (400 mHz; C6D6) are measured and used to confirm the product.

### Example C2-1 Preparation of Mixture

Isopropyl tris(dimethylamino)tin (iPrSn(NMe2)3) was prepared according to the method described in U.S. Patent Application Publication No. 2022/0242888. A mixture was prepared which contained 0.3 g of the compound prepared in Example C1-1 and 0.7 g isopropyl tris(dimethylamino)tin (iPrSn(NMe₂)₃). The product is filled into amber vessels without light exposure and stored under an inert gas atmosphere.

### Examples C2-2 to C2-6 (Prophetic): Preparation of Mixtures

Mixtures are prepared as described in Example C2-1, each containing 0.7 g iPrSn(NMe₂)₃ and 0.3 g of a compound prepared in Example C1-2 to C1-6. The product is filled into amber vessels without light exposure and stored under an inert gas atmosphere.

### Example C3-1: Preparation and Analysis of R′SnO(3/2-x/2)(OH)x Compounds (where 0<x≤3) by Hydrolysis

To a 100-mL flask under an inert gas atmosphere were added 10 mL n-hexane (dehydrated) and 1.0 g 1-methyl-cyclopentyl tris(dimethylamino)tin, which was synthesized as described in Example C1, and dissolved with stirring at 150 rpm. After cooling the resulting solution to 0-10° C., demineralized water (1.0 mL, resistance 18.2 MΩ) was added by syringe over 10 minutes while stirring at 150 rpm and maintaining a temperature of 0-10° C. to form a suspension. The resulting suspension was filtered through a funnel (Kiriyama filter paper 5B) to obtain a white solid. The resulting white solid was washed with 3 mL of demineralized water and then dried in vacuo at 40° C. for 8 h. The resulting white solid (SnO-1) weighed 0.56 g. The product is filled into amber vessels without light exposure and stored under an inert gas atmosphere.

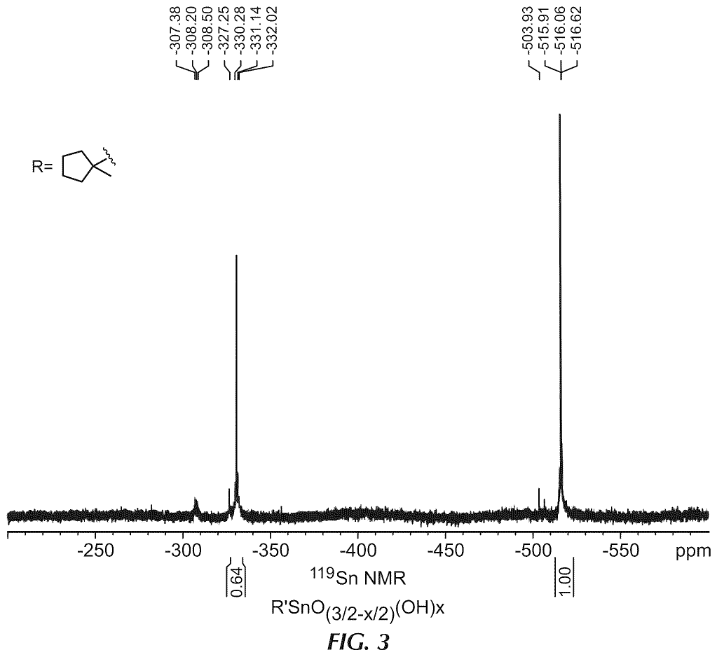

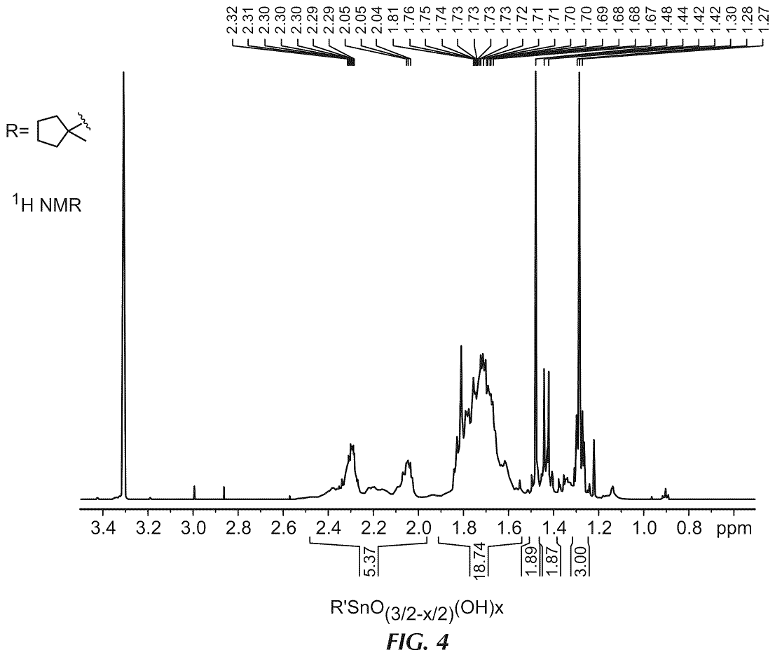

SnO-1 was identified by NMR using a Bruker Avance Neo 600 MHz Probe: cryo 5 mm BBO. Two major peaks were observed by 119Sn NMR (600 MHz, MeOD/CDCl3 1/1): 5-coordinated (R′SnO4): −331 ppm and 6-coordinated (R′SnO5): −516 ppm (see FIG. 3). 1H NMR (600 MHz MeOD/CDCl3 1/1): 2.0-2.4 (m, 2H), 1.6-1.9 (m, 6H), 1.48 (Me, 3H R′SnO4), 1.28 (Me, 3H R′SnO5) (see FIG. 4). This correlates with the NMR results of a reported tin dodecamer cluster in Organometallics 19, 1940-1949 (2000).

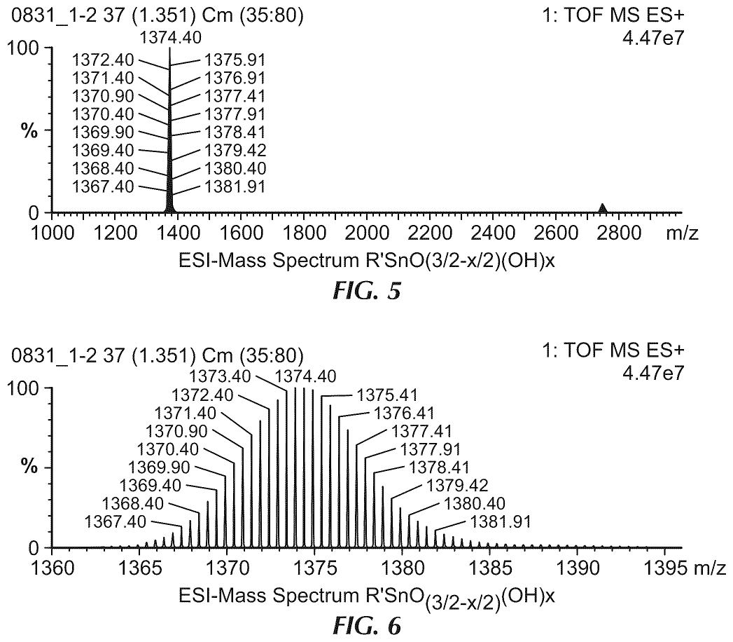

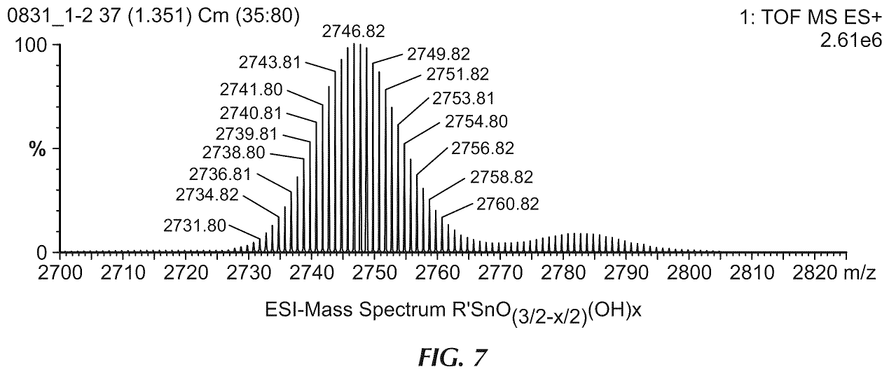

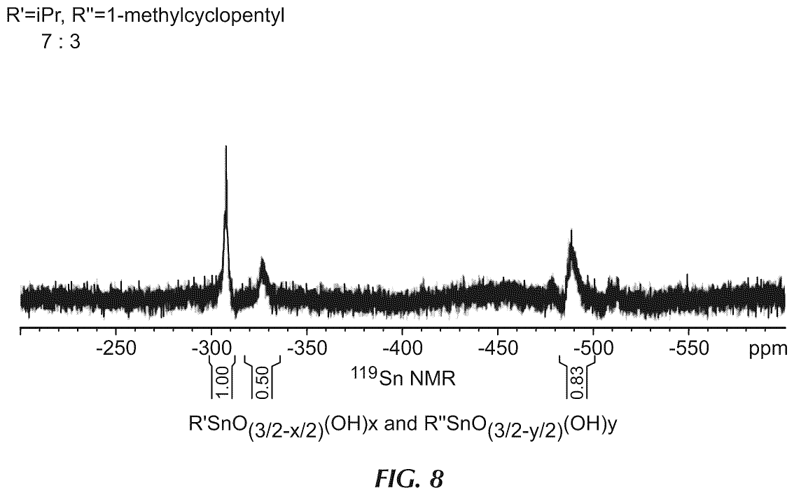

The ESI-Mass spectrum is shown in FIGS. 5, 6, and 7. FIG. 5 is the complete spectrum, and FIG. 6 and FIG. 7 depict enlarged portions. System: Waters Xevo G2-XS Qtof, solvent CH3CN, mode: ESI positive), indicating 2 main peaks [(C6H11Sn)12O14(OH)6] monovalent ion m/z=2746, divalent ion m/z=1374. Accordingly, a compound corresponding to R′SnO (3/2-x/2)(OH)x (where 0<x≤3) was obtained.

### Example C3-2: Preparation and Analysis of Mixture of R′SnO(3/2-x/2)(OH)x and R″SnO(3/2-y/2)(OH)y (where 0<x≤3, 0<y≤3) by Hydrolysis

A white solid (SnO-2) in an amount of 0.43 g was obtained from 0.3 g of the compound prepared as described in Example C1-1 and 0.7 g isopropyl tris(dimethylamino)tin using the same method described in Example C3-1. The product is filled into amber vessels without light exposure and stored under an inert gas atmosphere.

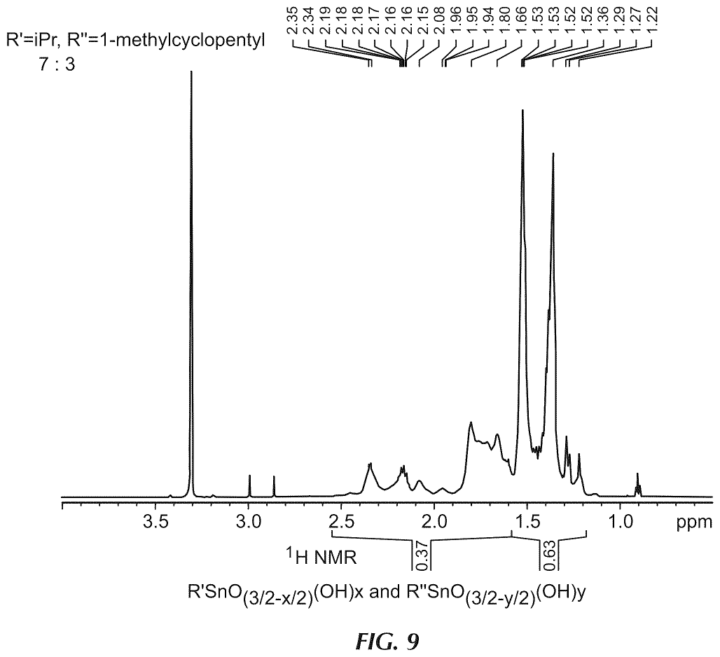

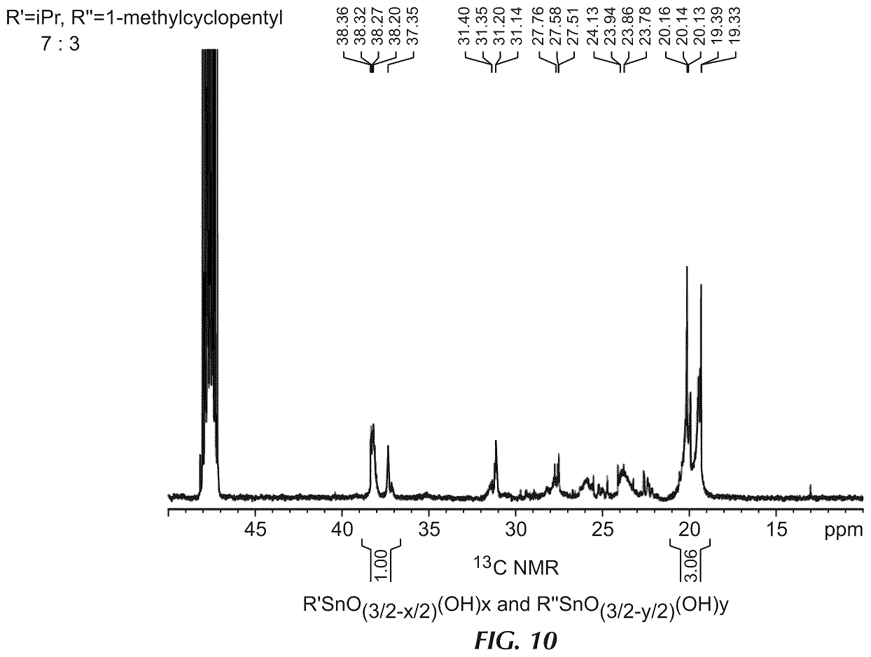

SnO-2 was identified by NMR using a Bruker Avance Neo 600 MHz Probe: cryo 5 mm BBO). Two major peak groups were observed by ¹¹⁹Sn NMR (600 MHz, MeOD/CDCl3 1/1): 5-coordinated (R′ or R″ SnO4): −307 ppm, −326 ppm and 6-coordinated (R′SnO5): −487 ppm, see FIG. 8. ¹H NMR (FIG. 9) and ¹³C NMR (FIG. 10) indicated that both R′(methyl cyclopentyl) and R″ (isopropyl) are included in the compound in a ratio of about R′:R″=1:3. This correlates with the NMR results of a tin dodecamer cluster.

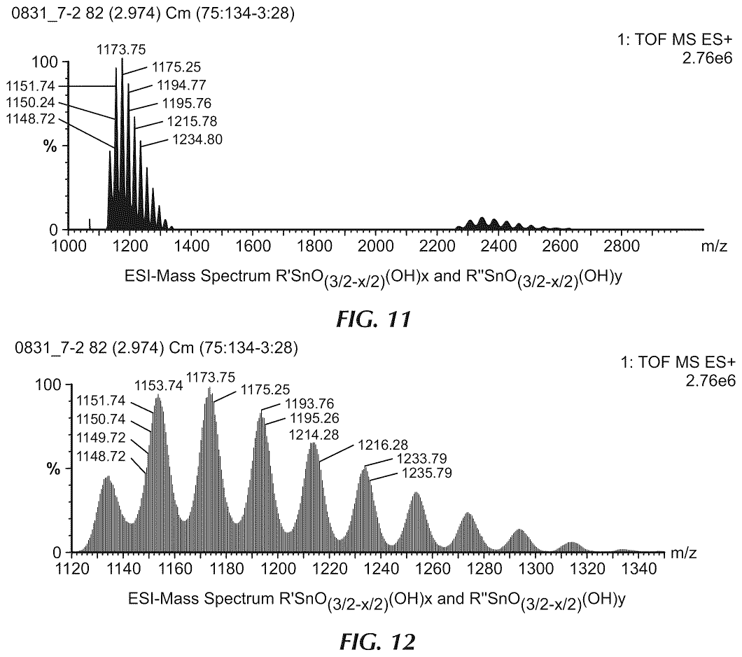

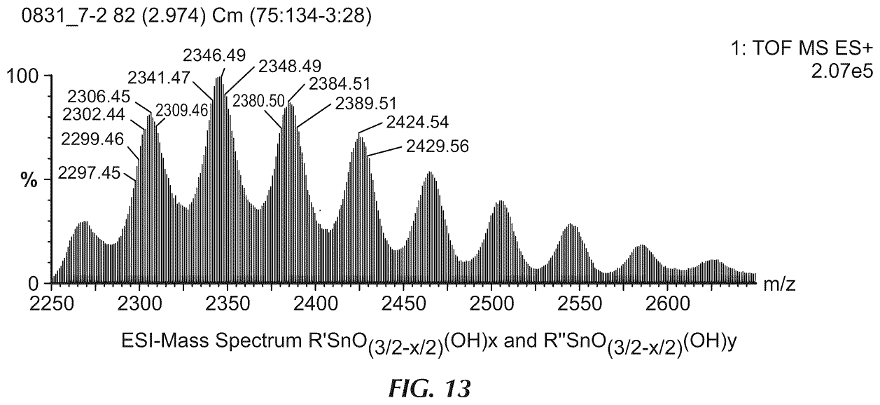

The ESI-Mass spectrum is shown in FIGS. 11-13 (complete spectrum in FIG. 11 and enlarged portions in FIGS. 12 and 13). (System: Waters Xevo G2-XS Qtof, solvent CH3CN, mode: ESI positive), indicating 2 main peaks R′(methyl cyclopentyl: C6H11) and R″ (isopropyl: C3H7) [(C6H11) 2(C3H7) 10Sn12O14(OH)₆] monovalent ion m/z=2346, divalent ion m/z=1174.

Another tin dodecamer cluster with a different R′:R″ ratio was detected. Accordingly, a compound corresponding to R′SnO(3/2-x/2)(OH)x and R″SnO(3/2-y/2)(OH)y (where 0<x≤3, 0<y≤3) which were blended in the same molecule was obtained.

### Example C4-1—Preparation of Film

The SnO-1 of Example C3-1 was dissolved in chloroform (5 mL) to a concentration of 2.0 wt % while using ultrasonic waves, and the resulting solution was filtered through a 0.20 μm syringe filter to obtain a resist solution containing a transparent tin compound. (SnO-1 did not dissolve in 4-methyl-2-pentanol under the same condition). Silicon wafers with oxide surfaces (Si substrate, 100 mm diameter) were ozonated and used as substrates for resist thin film deposition. The surface of the Si substrate was treated with hexamethyldisilazane (HMDS) vapor prior to resist deposition. The resist solution was spin coated onto the substrate at 2000 rpm and baked on a hot plate at 90° C. for 2 minutes. The film thickness after coating and baking was measured by ellipsometer to be 22 nm.

### Example C4-2—Preparation of Film

The SnO-2 of Example C3-2 was dissolved in chloroform (5 mL) to a concentration of 2.0 wt % while using ultrasonic waves, and the resulting solution was filtered through a 0.20 um syringe filter to obtain a resist solution containing a transparent tin compound. Silicon wafers with oxide surfaces (Si substrate, 100 mm diameter) were ozonated and used as substrates for resist thin film deposition. The surface of the Si substrate was treated with hexamethyldisilazane (HMDS) vapor prior to resist deposition. The resist solution was spin-coated onto the substrate at 2000 rpm and baked on a hot plate at 90° C. for 2 minutes. The film thickness after coating and baking was measured by ellipsometer to be 24 nm.

### Example C5-1 (Prophetic)—Formation of Image on Substrate

The coated substrate (film) from Example C4-1 is exposed to ultraviolet light (light source: xenon excimer lamp (172 nm, 7.2 eV) manufactured by USHIO INC., light source intensity: 0.7 mW/cm2) using a pattern to project a pattern on the substrate. The substrate is then immersed in 2-5 heptanone for 15 seconds and rinsed with the same developer for another seconds to form a negative-type image, i.e., an image in which the unexposed portion of the thin film is removed and only the pattern-exposed portion remains.

### Example C5-2 (Prophetic)—Formation of Image on Substrate

The coated substrate (film) from Example C4-2 is exposed to ultraviolet light (light source: xenon excimer lamp (172 nm, 7.2 eV) manufactured by USHIO INC., light source intensity: 0.7 mW/cm²) using a pattern to project a pattern on the substrate. The substrate is then immersed in 2-5 heptanone for 15 seconds and rinsed with the same developer for another 15 seconds to form a negative-type image, i.e., an image in which the unexposed portion of the thin film is removed and only the pattern-exposed portion remains.

### Example D: Preparation Example of Alkyl Magnesium Reagent

Magnesium (3.14 g, 129 mmol) was added to a 200 mL flask equipped with a meniscus stirring blade and a Dimroth condenser. After nitrogen purging of the flask was performed three times, tetrahydrofuran (15.4 g, 17.3 mL) and a tetrahydrofuran solution (concentration: 10% by mass, 8.78 g, 6.12 mmol) of 1-methyl-1-cyclopentylmagnesium chloride were added thereto. After the mixture was stirred at 400 rpm for 5 minutes, the reaction mixture was heated to 30° C. A 22 mass % tetrahydrofuran solution (3.27 g, 6.14 mmol) of 1-chloro-1-methylcyclopentane was added to the mixture. In this case, an increase in internal temperature of 1 to 2 degrees was confirmed. After the mixture was stirred at 400 rpm for 30 minutes, a 22 mass % tetrahydrofuran solution (63.2 g, 53.1 mmol) of 1-chloro-1-methylcyclopentane was added dropwise thereto over 100 minutes. After completion of the dropwise addition, the mixture was stirred at 400 rpm for 90 minutes while the temperature was maintained at 30° C. The supernatant after stirring was separated to obtain a THF solution of 1-methyl-1-cyclopentyl magnesium chloride (yielding amount: 89.11 g, concentration: 9.83% by mass (calculated by titration using 1,10-phenanthroline), yield: 45%).

### Example D-1

Hexane (36.6 g, 54.6 mL), tin tetrakis(dimethylamide) (Sn(NMe₂)₄, 18.0 g, 60.54 mmol), and pyridine (9.43 g, 119.3 mmol) were added to a 300 mL flask equipped with a meniscus stirring blade in a nitrogen gas atmosphere. After the mixture was stirred at 400 rpm for 5 minutes, the reaction system mixture was cooled to −10° C. A 9.2 mass % THF solution (94.7 g, 60.71 mmol) of 1-methyl-1-cyclopentyl magnesium chloride was added dropwise to the mixture using a syringe pump over 60 minutes. After completion of the dropwise addition, the temperature was raised to 22° C., and the mixture was stirred at 400 rpm for 180 minutes. After the mixture was stirred, the reaction solution was filtered through a pressurized filter in a nitrogen gas atmosphere, and the filtration residue was washed with hexane (29.5 g). The filtrate and the washing solution were mixed, and the mixed solution was concentrated under reduced pressure, thereby obtaining a yellow gel-like substance. By adding hexane (28.2 g) to the compound, the gel-like substance was changed to a suspension containing a white solid. This suspension was filtered again through a pressurized filter in a nitrogen gas atmosphere, and the filtration residue was washed with hexane (28.2 g). The filtrate and the washing solution were mixed, and the mixed solution was concentrated under reduced pressure, thereby obtaining a yellow gel-like compound again. By adding hexane (28.2 g) to the gel-like substance, the gel-like substance was changed to a suspension containing a white solid. This suspension was filtered again through a pressurized filter in a nitrogen gas atmosphere, and the filtration residue was washed with hexane (18.0 g). The filtrate and the washing solution were mixed, and the mixed solution was concentrated under reduced pressure (crude product weight: 18.31 g). Thereafter, the mixture was subjected to single distillation at an internal temperature of 87° C. and at a pressure of 95 Pa, thereby obtaining 1-methyl-1-cyclopentyltin tris(dimethylamide) (yielding amount: 11.24 g, purity: 96.5% by mole (purity was calculated by ¹¹⁹Sn NMR), yield: 54%).

### Example D-2

Decane (40.3 g, 55.1 mL), tin tetrakis(dimethylamide) (Sn(NMe₂)₄, 20.2 g, 68.54 mmol), and pyridine (10.7 g, 135.5 mmol) were added to a 300 mL flask equipped with a meniscus stirring blade in a nitrogen gas atmosphere. After the mixture was stirred at 400 rpm for 10 minutes, the reaction system mixture was cooled to −10° C. An 11 mass % THF solution (89.6 g, 66.32 mmol) of 1-methyl-1-cyclopentyl magnesium chloride was added dropwise to the mixture using a syringe pump over 60 minutes. After completion of the dropwise addition, the temperature was raised to 25° C., and the mixture was stirred at 400 rpm for 180 minutes. After the mixture was stirred, the reaction solution was filtered through a pressurized filter in a nitrogen gas atmosphere, and the filtration residue was washed with decane (39.1 g). The filtrate and the washing solution were mixed, and the mixed solution was concentrated under reduced pressure, thereby obtaining a suspension containing a white solid (crude product weight: 32.5 g). Decane (7.1 g) was added to the compound, and the mixture was filtered again through a pressurized filter in a nitrogen gas atmosphere, and the filtration residue was washed with decane (33.3 g). The filtrate and the washing solution were mixed, and the mixed solution was concentrated under reduced pressure. Thereafter, the mixture was subjected to single distillation at an internal temperature of 85° C. and at a pressure 85 Pa, thereby obtaining 1-methyl-1-cyclopentyltin tris(methylamide) (yielding amount: 11.9 g, purity: 97.5% by mole (purity was calculated by ¹¹⁹Sn NMR), yield: 52%).

### Example D-3

Hexane (32.6 g, 49.4 mL), tin tetrakis(dimethylamide) (Sn(NMe₂)₄, 16.3 g, 55.35 mmol), and pyridine (8.79 g, 111.1 mmol) were added to a 300 mL flask equipped with a meniscus stirring blade in a nitrogen gas atmosphere. After the mixture was stirred at 400 rpm for 5 minutes, the reaction system mixture was cooled to −10° C. A 5.0 mass % MTHP solution (124.56 g, 43.2 mmol) of 1-methyl-1-cyclopentyl magnesium chloride was added dropwise to the mixture using a syringe pump over 60 minutes. After completion of the dropwise addition, the temperature was raised to 22° C., and the mixture was stirred at 400 rpm for 180 minutes. After the mixture was stirred, the reaction solution was filtered through a pressurized filter in a nitrogen gas atmosphere, and the filtration residue was washed with hexane (35.0 g). The filtrate and the washing solution were mixed, and the mixed solution was concentrated under reduced pressure, thereby obtaining a golden-colored highly viscous liquid. By adding hexane (31.3 g) to the compound, the highly viscous liquid was changed to a suspension containing a white solid. This suspension was filtered again through a pressurized filter in a nitrogen gas atmosphere, and the filtration residue was washed with hexane (16.3 g). The filtrate and the washing solution were mixed, and the mixed solution was concentrated under reduced pressure, thereby obtaining a highly viscous liquid again. By adding hexane (22.9 g) to the highly viscous liquid, the highly viscous liquid was changed to a suspension containing a white solid. This suspension was filtered again through a pressurized filter in a nitrogen gas atmosphere, and the filtration residue was washed with hexane (12.3 g). The filtrate and the washing solution were mixed, and the mixed solution was concentrated under reduced pressure, thereby obtaining a highly viscous liquid again. By adding hexane to this highly viscous liquid, the highly viscous liquid was changed to a suspension containing a white solid. This suspension was filtered again through a pressurized filter in a nitrogen gas atmosphere, and the filtration residue was washed with hexane. The filtrate and the washing solution were mixed, and the mixed solution was concentrated under reduced pressure. Thereafter, the mixture was subjected to single distillation at an internal temperature of 90° C. and 80 Pa, thereby obtaining 1-methyl-1-cyclopentyltin tris(dimethylamide) (yielding amount: 4.70 g, purity: 48.8% by mole (purity was calculated by ¹¹⁹Sn NMR), yield: 12%).

### Example D-4

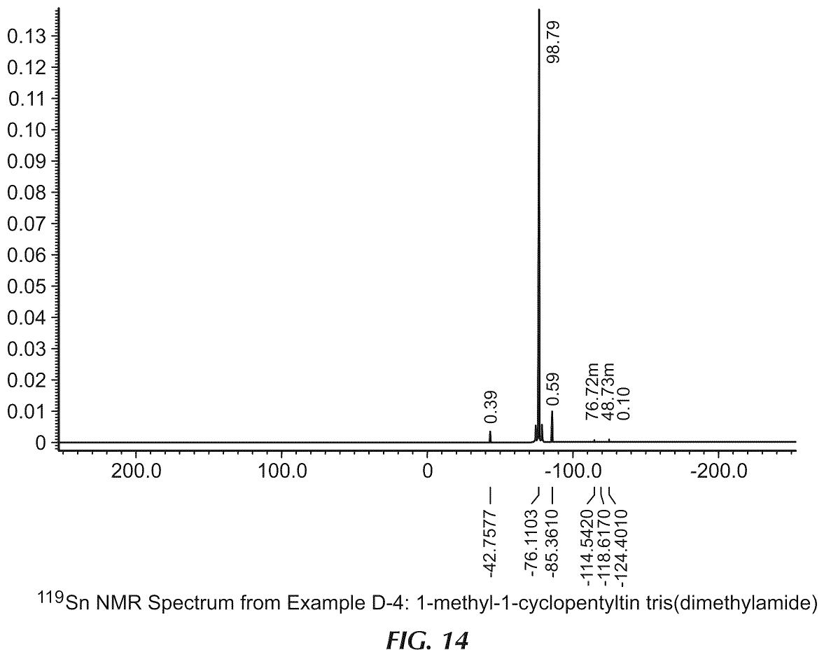

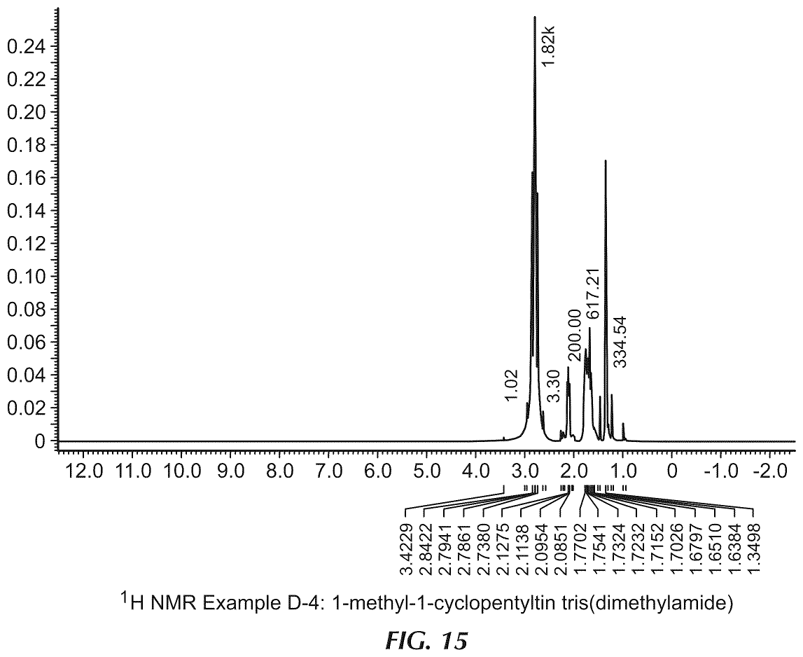

Decane (40.6 g, 55.6 mL) and tin tetrakis(dimethylamide) (Sn(NMe₂)₄, 21.0 g, 71.12 mmol) were added to a 500 mL flask equipped with a meniscus stirring blade in a nitrogen gas atmosphere. After the mixture was stirred at 400 rpm for 10 minutes, the reaction system mixture was cooled to −5° C. A 12 mass % THF solution (90.9 g, 75.34 mmol) of 1-methyl-1-cyclopentyl magnesium chloride was added dropwise to the mixture using a dropping funnel over 60 minutes. After completion of the dropwise addition, the temperature was raised to 25° C., and the mixture was stirred at 400 rpm for 180 minutes. After the mixture was stirred, the reaction solution was filtered through a pressurized filter in a nitrogen gas atmosphere, and the filtration residue was washed with decane (60.8 g). The filtrate and the washing solution were mixed, and the mixed solution was concentrated under reduced pressure, thereby obtaining a suspension containing a white solid. After the addition of decane (18 g) to the compound, the mixture was filtered again through a pressurized filter in a nitrogen gas atmosphere, and the filtration residue was washed with decane (60.8 g). The filtrate and the washing solution were mixed, and the mixed solution was concentrated under reduced pressure. Thereafter, the mixture was subjected to single distillation at an internal temperature of 89° C. and at a pressure of 70 Pa, thereby obtaining 1-methyl-1-cyclopentyltin tris(dimethylamide) (yielding amount: 15.21 g, purity: 98.8% by mole (purity was calculated by ¹¹⁹Sn NMR), yield: 63%). The ¹¹⁹Sn and ¹H NMR spectra are shown in FIGS. 14 and 15.

### Example D-5

Hexane (36 g, 54.6 mL), tin tetrakis(dimethylamide) (Sn(NMe₂)₄, 18 g, 60.4 mmol), and pyridine (9.56 g, 120.8 mmol) were added to a 300 mL flask equipped with a meniscus stirring blade in a nitrogen gas atmosphere. After the mixture was stirred at 400 rpm for 5 minutes, the reaction system mixture was cooled to −10° C. A 9.2 mass % THF solution (95.17 g, 61.01 mmol) of 1-methylcyclopentyl magnesium chloride was added dropwise to the mixture using a syringe pump over 60 minutes. After completion of the dropwise addition, the temperature was raised to 22° C., and the mixture was stirred at 400 rpm for 180 minutes. After the mixture was stirred, the reaction solution was filtered through a pressurized filter in a nitrogen gas atmosphere, and the filtration residue was washed with hexane. The reaction solution obtained by mixing the filtrate and the washing solution was concentrated under reduced pressure while hexane was added. In a case where the solvent was distilled off for a while, a white solid began to precipitate from the reaction solution. Further, the mixture was concentrated under reduced pressure while hexane was added, thereby obtaining a suspension containing a white solid. This suspension was filtered again through a pressurized filter in a nitrogen gas atmosphere, and the filtration residue was washed with hexane. The filtrate and the washing solution were mixed, and the mixed solution was concentrated under reduced pressure. Thereafter, the mixture was subjected to single distillation at an internal temperature of 87° C. and at a pressure of 95 Pa, thereby obtaining 1-methyl-1-cyclopentyltin tris(dimethylamide) without an increase in viscosity.

### Example D-6

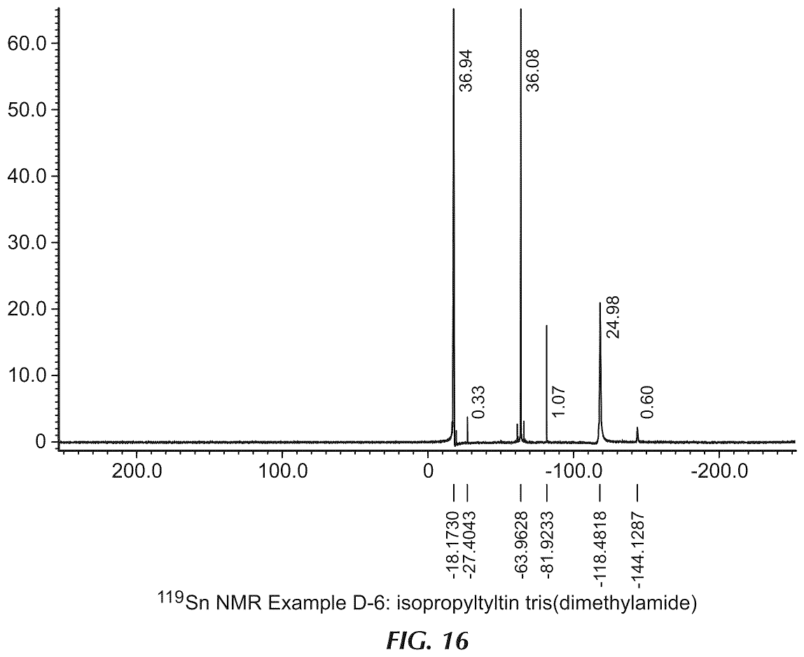

Decane (40.3 g, 55.1 mL) and tin tetrakis(dimethylamide) (Sn(NMe₂)₄, 20.3 g, 67.8 mmol) were added to a 500 mL flask equipped with a meniscus stirring blade in a nitrogen gas atmosphere. After the mixture was stirred at 400 rpm for 10 minutes, the reaction system mixture was cooled to −5° C. An 8 mass % THF solution of isopropylmagnesium chloride (88.0 g, 67.83 mmol) was added dropwise to the mixture using a syringe pump over 60 minutes. After completion of the dropwise addition, the temperature was raised to 25° C., and the mixture was stirred at 400 rpm for 180 minutes. After the mixture was stirred, the reaction solution was filtered through a pressurized filter in a nitrogen gas atmosphere, and the filtration residue was washed with decane (60.8 g). The filtrate and the washing solution were mixed, and the mixed solution was concentrated under reduced pressure, thereby obtaining a suspension containing a white solid. This suspension was filtered again through a pressurized filter in a nitrogen gas atmosphere, and the filtration residue was washed with decane (60.6 g). The filtrate and the washing solution were mixed, and the mixed solution was concentrated under reduced pressure. Meanwhile, a liquid obtained by mixing the fractions obtained by the first and second solvent distillation operations was connected to a 5-stage KIRIYAMA PAC and concentrated again under reduced pressure. The concentrated solution obtained in the present operation and the concentrated solution obtained in the previous operation were subjected to simple distillation at an internal temperature of 80° C. and at a pressure of 130 Pa, thereby obtaining isopropyltin tris(dimethylamide) (yielding amount: 13.54 g, purity: 36.1% by mole (purity was calculated by ¹¹⁹Sn NMR), yield: 24%). The ¹¹⁹Sn NMR spectrum is shown in FIG. 16.

### Example D-7

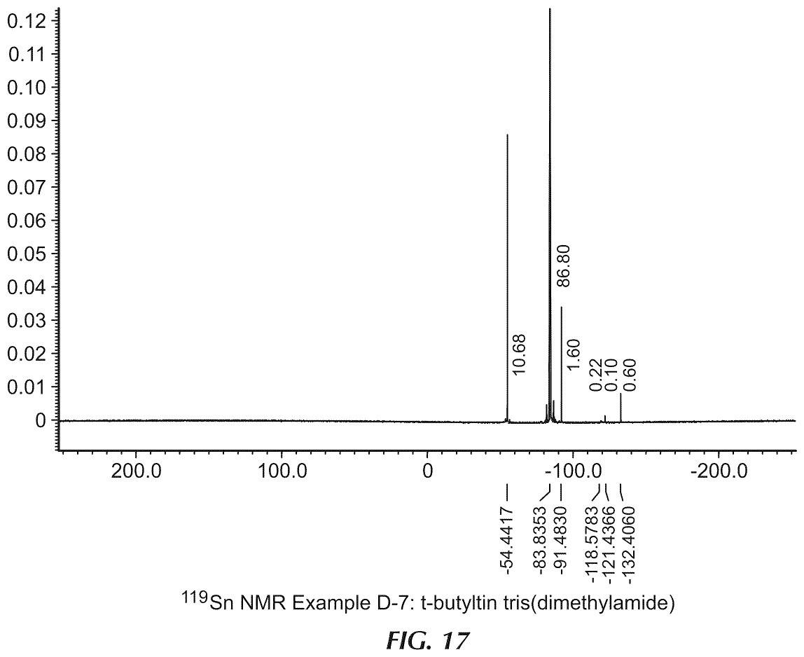

Decane (36.5 g, 49.6 mL) and tin tetrakis(dimethylamide) (Sn(NMe₂)₄, 14.5 g, 49.15 mmol) were added to a 500 mL flask equipped with a meniscus stirring blade in a nitrogen gas atmosphere. After the mixture was stirred at 400 rpm for 10 minutes, the reaction system mixture was cooled to −5° C. An 8 mass % THF solution of t-butylmagnesium chloride (61.7 g, 48.62 mmol) was added dropwise to the mixture using a syringe pump over 60 minutes. After completion of the dropwise addition, the temperature was raised to 25° C., and the mixture was stirred at 400 rpm for 180 minutes. After the mixture was stirred, the reaction solution was filtered through a pressurized filter in a nitrogen gas atmosphere, and the filtration residue was washed with decane (44.4 g). The filtrate and the washing solution were mixed, and the mixed solution was concentrated under reduced pressure, thereby obtaining a suspension containing a white solid. This suspension was filtered again through a pressurized filter in a nitrogen gas atmosphere, and the filtration residue was washed with decane (44.3 g). The filtrate and the washing solution were mixed, and the mixed solution was concentrated under reduced pressure, using a five-stage KIRIYAMA PAC. Meanwhile, the fractions obtained in the first and second solvent-removal operations were mixed and concentrated again under reduced pressure using a 5-stage KIRIYAMA PAC. After that, t-butyltin tris(dimethylamide) was obtained by single distillation at 80° C. and 135 Pa (yielding amount: 9.56 g, purity: 86.8% by mole (purity was calculated by ¹¹⁹Sn NMR), yield: 55%). The ¹¹⁹Sn NMR spectrum is shown in FIG. 17.

Tables 1 to 4 list the ratios of the components of the product (crude product) before simple distillation and the product after simple distillation in each example.

In the following tables, R of the tin compounds (10) to (12) represents a methyl group. In Examples D-1 to D-4, R^{v} of the tin compounds (11) to (13) represents a 1-methyl-1-cyclopentyl group. R^{v} of the tin compounds (11) to (13) in Example D-6 represents an isopropyl group.

In the following tables, the measurement conditions of NMR are as follows. NMR was measured for the crude product before distillation and the sample after single distillation without dilution. The number of times of integration was 5,000, and the relaxation time was 0.94 seconds.

In the following tables, “n. d.” denotes that the value did not reach the detection limit.

The term “Grignard dimer” denotes a compound in which two 1-methyl-1-cyclopentyl groups are bonded.

TABLE 1
Composition of crude product before single distillation after
reaction (measurement value by ¹¹⁹SnNMR, unit: mol %)

| | Tin | Tin | Tin | Tin |
|---|---|---|---|---|
| | compound | compound | compound | compound |
| Entry | (10) | (11) | (12) | (13) |
| Example D-1 | 0.42 | 94.79 | 1.18 | 3.43 |
| Example D-2* | 2.38 | 96.37 | n.d. | 1.25 |
| Example D-3 | 24.25 | 73.65 | 0.13 | 0.92 |
| Example D-4 | n.d. | 96.08 | 2.87 | 0.96 |
| Example D-6 | 25.35 | 35.86 | 36.15 | 1.22 |
| Example D-7 | n.d. | 84.99 | 11.94 | 2.36 |

In Table 1, the proportions of the compounds corresponding to the tin compounds (10), (11), (12), and (13) in the product are values obtained by summing the integral intensities of the peaks confirmed by ¹¹⁹Sn NMR. In Example D-2, the reaction solution after the second filtration (before distillation of the solvent) was measured.

Without limiting, it is believed that in Example D-6 (isopropyl), the reactivity of the first alkylation and the second alkylation are nearly the same (likely due to the lack of steric hindrance), so similar amounts of monoalkyl (11) and dialkyl (12) products are obtained, and a significant amount of the unreacted tetrakis starting material (10) remains. In Example D-7, the larger amount of dialkyl compound (12) is likely due to the larger relative amount of t-butylmagnesium chloride which was employed.

TABLE 2
Composition of crude product before single distillation
after reaction (measurement value by ¹HNMR, unit: mol %)

| | Second solvent | Tin compound | Grignard |
|---|---|---|---|
| Entry | (hydrophobic solvent) | (11) | dimer |
| Example D-1 | 28 | 100 | 4.9 |
| Example D-4 | 4.89 | 100 | 1.4 |

In Table 2, the molar ratios of the second solvent and the Grignard dimer were calculated from the integral intensities of the second solvent and the Grignard dimer in a case where the integral intensity of the C—H derived peak of the tin compound (11) was set as a reference (100).

TABLE 3
Composition of product after single distillation
(measurement value by ¹¹⁹SnNMR, unit: mol %)

| | Tin | Tin | Tin | Tin |
|---|---|---|---|---|
| | compound | compound | compound | compound |
| Entry | (10) | (11) | (12) | (13) |
| Example D-1 | 0.16 | 96.54 | 0.21 | 2.06 |
| Example D-2 | 1.87 | 97.49 | n.d. | 0.64 |
| Example D-3 | n.d. | 48.88 | 50.98 | 0.15 |
| Example D-4 | 0.05 | 98.79 | 0.39 | 0.59 |
| Example D-6 | 24.98 | 36.08 | 36.94 | 1.07 |
| Example D-7 | 0.23 | 86.8 | 10.68 | 1.6 |

In Table 3, the proportions of the compounds corresponding to the tin compounds (10), (11), (12), and (13) in the product are values obtained by summing the integral intensities of the peaks confirmed by ¹¹⁹Sn NMR.

Without limiting, it is noted that, with respect to Examples D-6 and D-7, the desired monoalkyl triamide compounds (11) are not easily separated from the tetrakis (10) and dialkyl (12) compounds by simple distillation due to the very small difference in molecular weights between these compounds.

TABLE 4
Composition of product after single distillation
(measurement value by ¹HNMR, unit: mol %)

| | Second solvent | | |
|---|---|---|---|
| | (hydrophobic | Tin compound | Grignard |
| Entry | solvent) | (11) | dimer |
| Example D-1 | n.d. | 100 | n.d. |
| Example D-2 | 1.56 | 100 | 1.5 |
| Example D-4 | 0.47 | 100 | 1.14 |

In Table 4, the molar ratios of the second solvent and the Grignard dimer were calculated from the integral intensities of the second solvent and the Grignard dimer in a case where the integral intensity of the C—H derived peak of the tin compound (11) was set as a reference (100).

### Example E1: Preparation of 1-chloro-1-methylcyclopentane

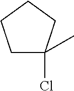

A 3 L flask was equipped with a pot thermometer, an addition funnel, a magnetic stir bar and a water condenser that connected to a N₂ system. At room temperature, 1-methylcyclopentanol (300 g, 2.995 mol) was dissolved in 200 mL hexane and charged to the flask. The flask was cooled down to 5° C. using a dry-ice and acetone bath. Then 12M HCl (739 g, 7.5 mol) was added dropwise to the mixture through an addition funnel. The temperature of the reaction was kept below 30° C. After addition, the mixture was warmed up and stirred at room temperature for 2 h; two layers was observed. After reaction completion was confirmed by GC, the organic layer was extracted and dried with MgSO₄ overnight. The organic layer was then filtered and the solvent was stripped using a Vigreux column at a maximum pot temperature of 40° C. at 50 mmHg. The crude material was then distilled with a pro-pak column (b.p.=28° C. at 20 mmHg) to afford 573.3 g product (70% yield). ¹H NMR (400 MHz, 25° C., C₆D₆): 1.32 (m, 2H, CH₂), 1.38 (m, 2H, CH₂), 1.44 ppm (s, 3H, CH₃), 1.80 ppm (m, 2H, CH₂), 1.95 ppm (m, 2H, CH₂).

### Example E2: Preparation of Chloro(1-methylcyclopentyl)magnesium

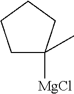

A 12 L flask was equipped with a pot thermometer, 2 addition funnels, mechanical stirring and a water condenser that connected to a N₂ system. Magnesium chips (151.3 g, 6.23 mol) was charged into the flask and heated under vacuum using an IR bulb for 1 h. The flask was then cooled down to room temperature and re-pressurized to 1 atmosphere under N₂. Next, 300 mL of diethyl ether was added, followed by 1,2-dibromoethane (5.57 g, 0.03 mol). The mixture was stirred until a mild exotherm and the release of bubbles were observed. Meanwhile, 1-chloro-1-methylcyclopentane (700 g, 5.93 mol) prepared in Example E1 and 7800 mL of diethyl ether were charged to two separating addition funnels. Stirring was turned off, and 5% of 1-chloro-1-methylcyclopentane was added dropwise to the pot. An exothermic initiation was observed after 5 minutes (monitored by the boiling of diethyl ether). The stirring was turned back on, followed by the duo addition of 1-chloro-1-methylcyclopentane and diethyl ether. The rate of addition was adjusted to control the exotherm and resultant reflux. After the addition was completed, the mixture was kept at refluxing temperature using an IR bulb for 2 h. After 2 h the reaction was cooled down to room temperature and a sample was taken for Grignard acid-base titration, which gave a result of 0.49 M solution in diethyl ether.

### Example E3: Preparation of 1-methylcyclopentyltris(dimethylamino)Tin using Tetra(tert-butylalkynyl)tin

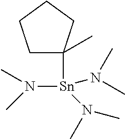

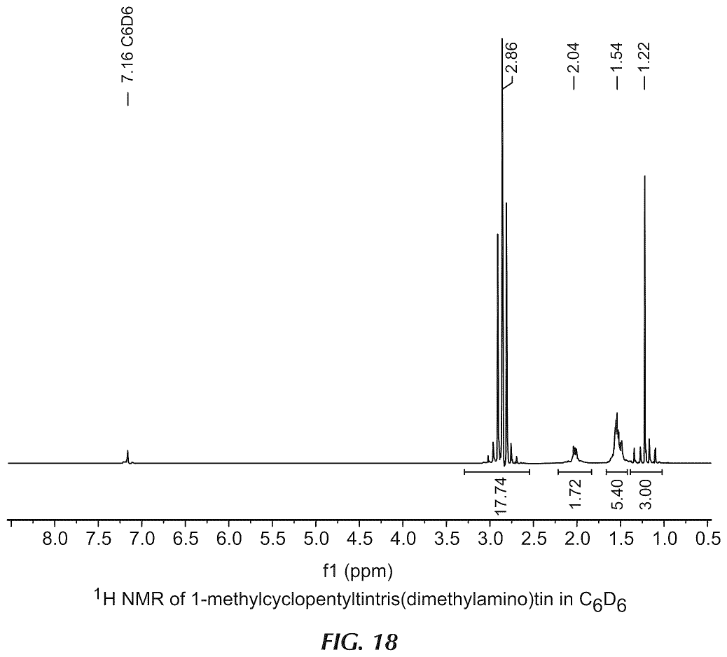

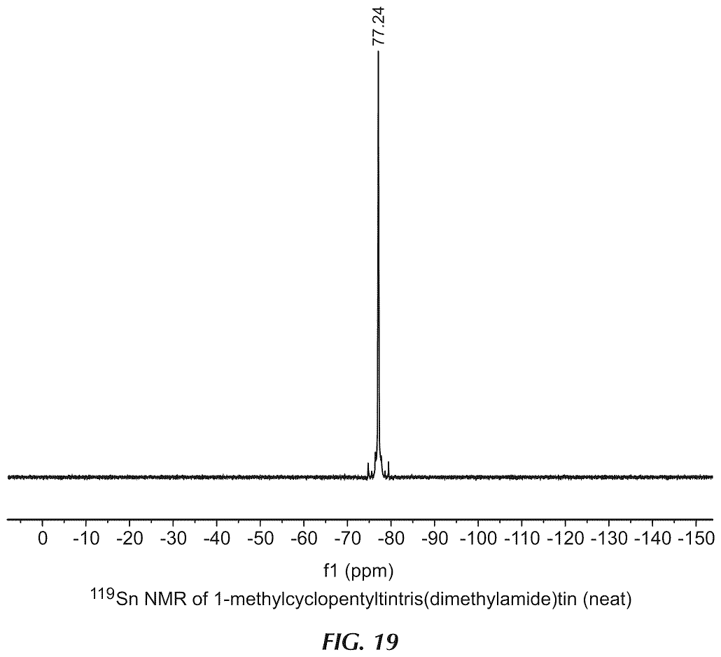

Tetra(tert-butylalkynyl)tin was prepared according to the method of Pant, et al. (Journal of Organometallic Chemistry, 15(1), pp. 65-68 (1968)). 44 g (0.10 mol) of tetra(tert-butylalkynyl)tin and 100 mL THF were charged to a 1 L flask under N₂. To this mixture was added 240 g of 1-methylcyclopentylmagnesium chloride (6% w/w in diethyl ether). The mixture was heated to reflux for 96 h during which time formation of 1-methylcyclopentyl-tris(tertbutylalkynyl)tin was observed by ¹¹⁹Sn NMR spectroscopy. Once complete consumption of the starting material was observed, methanol was added to the reaction mixture. The reaction mixture was heated to 60° C. and diethyl ether and tert-butylalkyne were removed from the mixture by distillation. The resulting oily solids were suspended in toluene and a solution of 5.2 g (0.1 mol) LiNMe₂ in toluene/hexanes was added to the suspension at 0° C. and the mixture was stirred at room temperature for 12 h. The reaction mixture was filtered to remove LiOMe and toluene/hexanes were removed from the filtrate under vacuum giving the crude product as an oily liquid. The crude product was further purified by distillation (b.p.=78° C. at 0.5 mmHg). ¹H NMR (400 MHz, 25° C., C₆D₆): 1.22 ppm (s, 3H, CH₃), 1.54 ppm (m, 6H, CH₂), 2.04 ppm (m, 2H, CH₂), 2. ppm (s, 18H, N(CH₃)₂) (FIG. 18). ¹¹⁹Sn NMR (119 MHz, 25° C., neat): −77 ppm. (FIG. 19).

### Example E4: Preparation of 1-Methylcyclopentyltris(dimethylamino)tin using Tetrakis(dimethylamino)tin

A 12 L flask was equipped with a pot thermometer, an addition funnel, mechanical stirring and a water condenser that connected to a N₂ system. At room temperature, tetrakis(dimethylamino)tin (705 g, 2.39 mol) and 1800 mL of hexane were charged to the flask. The mixture was cooled down to −10° C. and chloro(1-methylcyclopentyl)magnesium solution in diethyl ether (0.37 M, 5456 g, 2.39 mol) was added through addition funnel. After addition, the mixture was warmed up to room temperature and stirred for an additional 8 hour. Then the mixture was filtered through a pressure filter under nitrogen. The solid was washed with 500 mL hexane. The filtrate was stripped at a maximum pot temperature of 40° C. at 10 Torr to remove solvents. The crude material was then flashed over a bridge, followed by distillation (b.p.=78° C. at 0.5 mmHg) to yield the desired product. ¹H NMR (400 MHz, 25° C., C₆D₆): 1.22 ppm (s, 3H, CH₃), 1.54 ppm (m, 6H, CH₂), 2.04 ppm (m, 2H, CH₂), 2. ppm (s, 18H, N(CH₃)₂). ¹¹⁹Sn NMR (119 MHz, 25° C., neat): −77 ppm.

### Example E5: Preparation of 1-Methylcyclopentyltris(tert-butoxy)tin

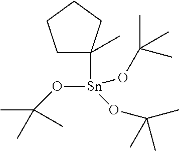 [SMILES: CC(C)(C)[O][Sn]([O]C(C)(C)C)([O]C(C)(C)C)[C]1(C)CCCC1]

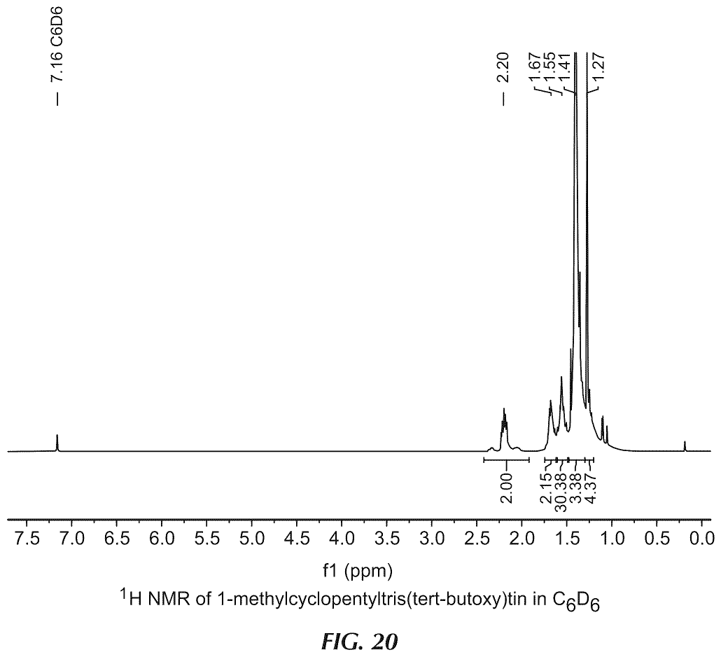

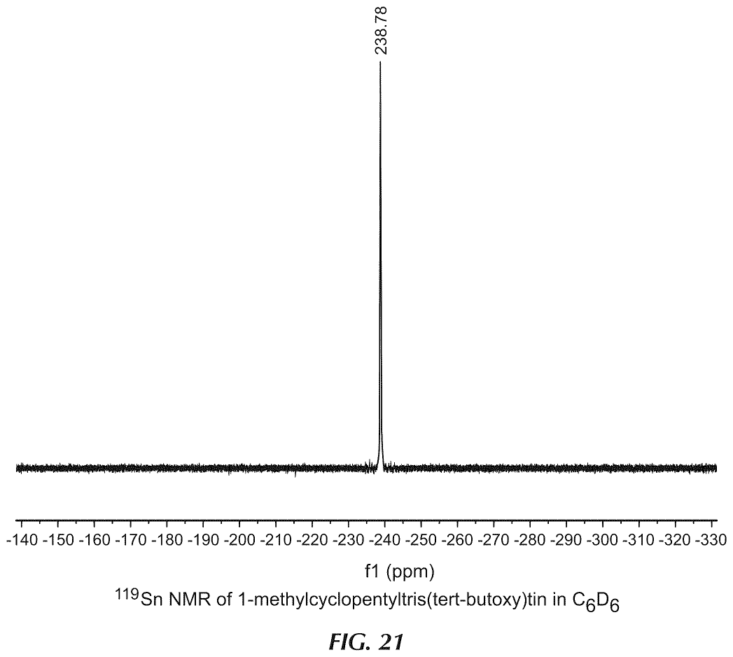

A 500 mL flask was equipped with a pot thermometer, an addition funnel, mechanical stirring and a water condenser that connected to a N₂ system. At room temperature, 1-methylcyclopentyltris(dimethylamino)tin (180 g, 0.51 mol) was charged to the flask, followed by cooling to 0° C. Dried tert-butyl alcohol (113 g, 1.53 mol) was dissolved in 100 mL of toluene and added dropwise to the pot through an addition funnel. After addition, the reaction was allowed to warm to room temperature and was stirred for an additional 8 h. The solvent was removed at maximum pot temperature of 40° C. at 5 mmHg. The crude product was flashed over, followed by distillation (b.p.=5° C. at 0.073 mmHg). ¹H NMR (400 MHz, 25° C., C₆D₆): 1.27 ppm (s, 3H, CH₃), 1.41 ppm (s, 27H, OC(CH₃)₃), 1.55 ppm (m, 2H, CH₂), 1.67 ppm (m, 2H, CH₂) (FIG. 20). ¹¹⁹Sn NMR (119 MHz, 25° C., neat): −283.8 ppm (FIG. 21).

### Example E6: Preparation of α-Methylbenzyl Tin Trimethoxide

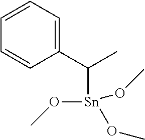

A 3 L flask was equipped with a pot thermometer, an addition funnel, mechanical stirring and a water condenser that connected to a N₂ system. 193.0 g (0.44 mol) of bis[bis(trimethylsilyl)amino]tin and 450 mL toluene were charged into the flask and cooled to 0° C. 81.3 g (0.44 mol) of 1-bromoethylbenzene was added dropwise through an addition funnel while maintaining a reaction temperature below 30° C. The reaction mixture was stirred at room temperature for 1 h, followed by addition of 100 mL of 25% sodium methoxide in methanol. The reaction was gently refluxed at 65° C. for 8 hr. The excess methanol was distilled to obtain methylbenzyl tin trimethoxide in toluene solution. The mixture was direct used in Example E7.

### Example E7: Preparation of Methylbenzyltris(dimethylamino)tin Using Lithium Dimethylamide

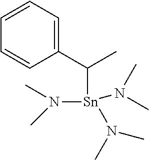 [SMILES: C[CH](c1ccccc1)[Sn]([N](C)C)([N](C)C)[N](C)C]

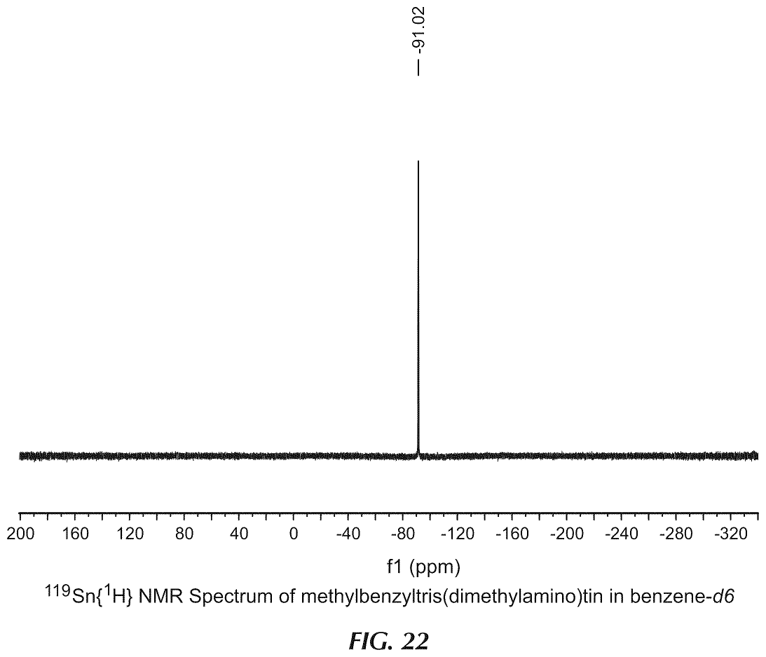

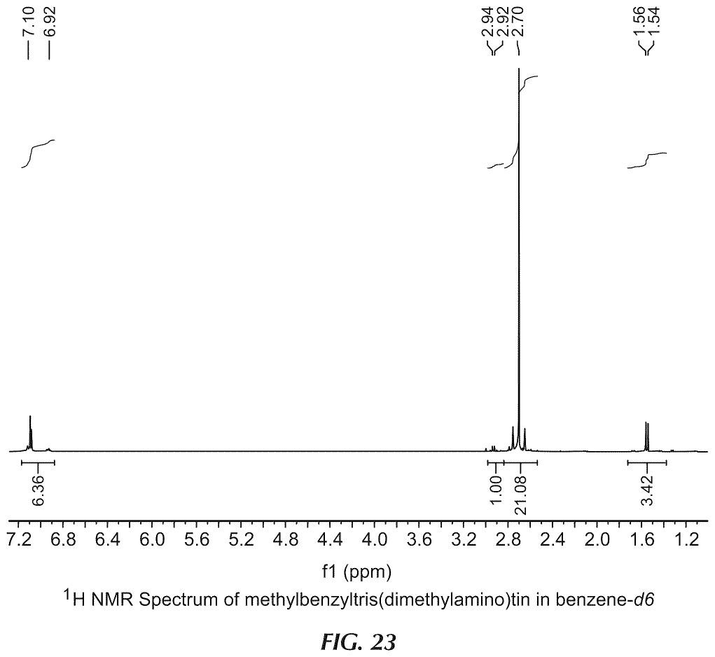

The reaction solution from Example E6 was added into a flask containing 69.36 g (1.35 mol) of lithium dimethylamide in hexane at 0° C. under N₂. The reaction mixture was allowed to warm to room temperature and then stirred overnight. The reaction mixture was then filtered, and solvent was removed under vacuum. The desired product was obtained by distillation (b.p.=110° C. at 0.75 mmHg). ¹¹⁹Sn{¹H}NMR (20° C.): 6-91 (FIG. 22). ¹H NMR (C₆D₆, 20° C.): δ 1.55 (d, ³J_{HH}=7.8 Hz, 3H, CH₃), 2.70 (s, 18H, NMe₂), 2.93 (q, ³J_{HH}=Hz, 1H, CH), 6.93 (m, 1H, C₆H₅), 7.09 (m, 4H, C₆H₅), FIG. 23.

### Example E8: Preparation of α-Methylbenzyltris(dimethylamino)tin Using (N,N-dimethylamino)trimethylsilane

A 3 L flask was equipped with a pot thermometer, stirring bar and distillation column. The reaction solution from Example E6 was added to a flask, followed by adding 103.2 g of (N,N-dimethylamino)trimethylsilane and heating the reaction mixture to 70-85 C until no by-product trimethylmethoxysilane observed. The crude product was flashed over, followed by distillation to obtain the desired product.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. A monoorgano tin compound having formula (1) having a purity of at least about 95 mol % and containing less than about 5 mol % of a diorgano tin compound having formula (2): 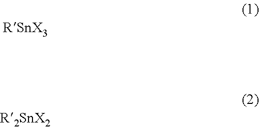
wherein R′ has formula [I] or [II], and X is selected from NR₂ and OR, wherein each R is independently a linear or branched alkyl group having about 1 to about 10 carbon atoms which is optionally substituted with one or more halogen atoms;
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.

2. The monoorgano tin compound according to claim 1, wherein a content of a compound having formula (5) is less than about 5 mol %:

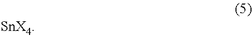

3. The monoorgano tin compound according to claim 1, wherein R′ is selected from the group consisting of: 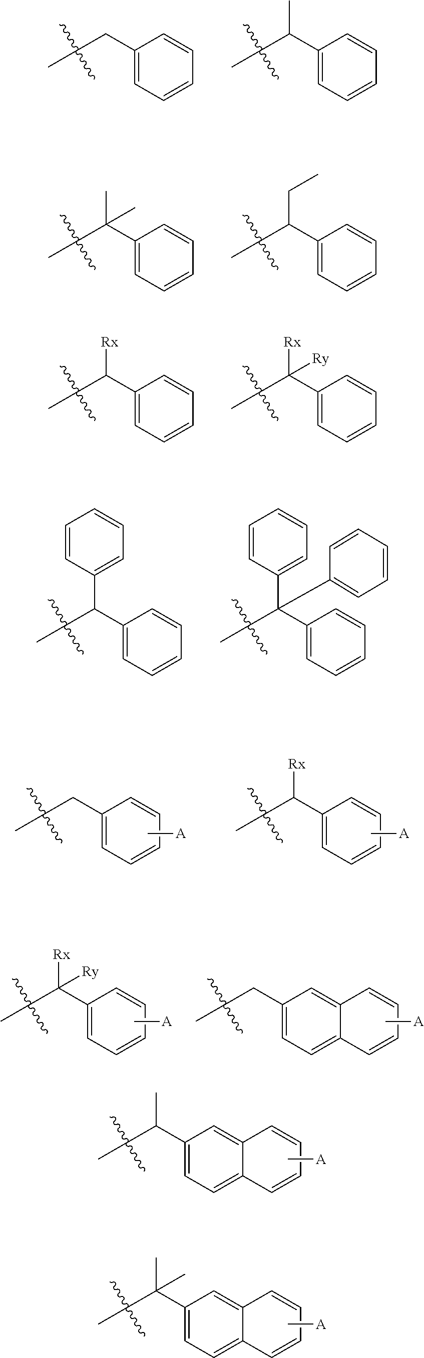 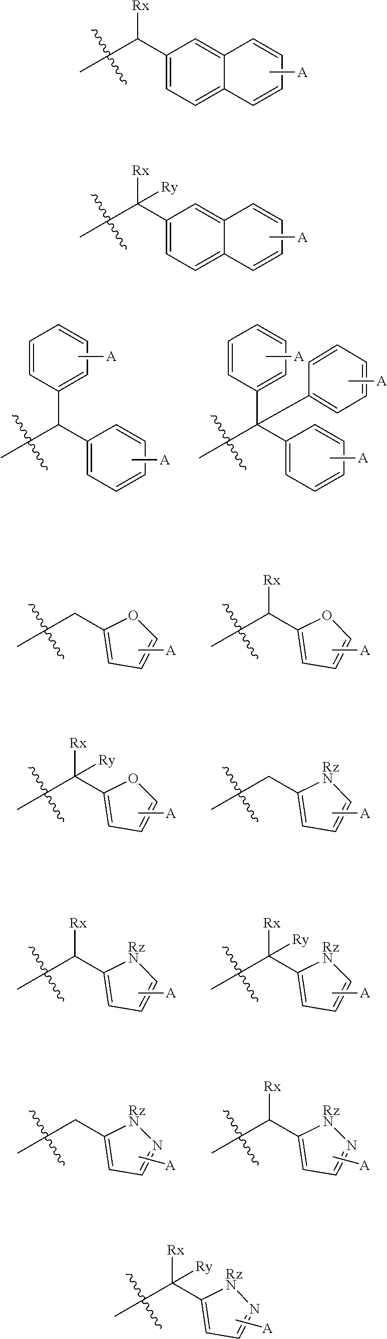
wherein each A substituent is independently hydrogen, a halogen, or a hydrocarbyl substituent having about 1 to about 5 carbon atoms which is optionally substituted with one or more oxygen, halogen, or nitrogen atoms; and wherein Rx, Ry, and Rz are each independently a halogen or a hydrocarbyl substituent having about 1 to about 5 carbon atoms which is optionally substituted with one or more oxygen or nitrogen atoms, or

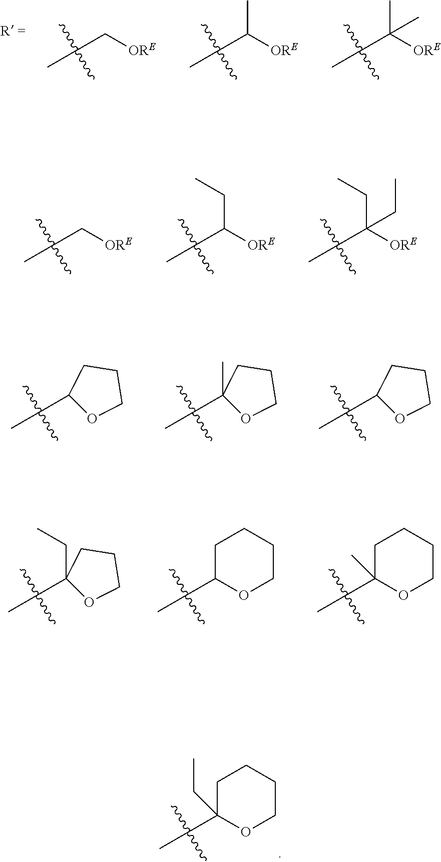

4. The monoorganotin compound according to claim 1, wherein the carbon atom in R′ bonded to tin is a secondary or tertiary carbon.

5. The monoorganotin compound according to claim 1, wherein Ra is a phenyl group.

6. The monoorganotin compound according to claim 1, wherein R^{A} in R′ is OR^{E} and wherein R^{E} and at least one of R^{B} and R^{C} optionally form a 3 to 8-membered ring containing an ether linkage.

7. The monoorganotin compound according to claim 1, wherein R^{E} is a methyl group.

8. The monoorgano tin compound according to claim 1, wherein X═NMe₂.

9. A method of synthesizing a monoorgano tin compound having formula (1) having a purity of at least about 95 mol % and containing less than about 5 mol % of a diorgano tin compound having formula (2): 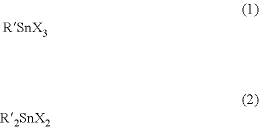
wherein R′ has formula [I] or [II], and X is selected from NR₂ and OR, wherein each R is independently a linear or branched alkyl group having about 1 to about 10 carbon atoms which is optionally substituted with one or more halogen atoms, the method comprising reacting a compound containing an R′ group with a compound having formula SnX₄;
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.

10. A method of synthesizing a monoorgano tin compound having formula (1) having a purity of at least about 95 mol % and containing less than about 5 mol % of a diorgano tin compound having formula (2): 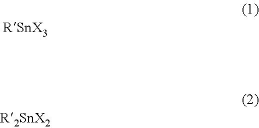
wherein R′ has formula [I] or [II], and X is selected from NR₂ and OR, wherein each R is independently a linear or branched alkyl group having about 1 to about 10 carbon atoms which is optionally substituted with one or more halogen atoms, the method comprising reacting a compound containing an OR or NR₂ group with a compound having formula R′SnY₃, where Y is a reactive ligand;
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.

11. A method of synthesizing a monoorgano tin compound having formula (1) having a purity of at least about 95 mol % and containing less than about 5 mol % of a diorgano tin compound having formula (2): 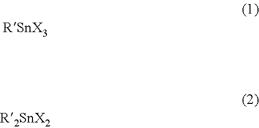
wherein R′ has formula [I] or [II], and X is selected from NR₂ and OR, wherein each R is independently a linear or branched alkyl group having about 1 to about 10 carbon atoms which is optionally substituted with one or more halogen atoms, the method comprising reacting a compound containing an OR or NR₂ group with a compound having formula R′SnY₃, where Y is a reactive ligand, the method comprising: (a) reacting a metal compound comprising an alkali metal M and a ligand X with a compound having formula SnY₂ to form a compound having formula MSnX₃; and (b) reacting the compound having formula MSnX₃ with a compound R′Z, wherein Z is a halogen atom and Y is a reactive ligand;
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.

12-15. (canceled)

16. A method of synthesizing a monoorgano tin compound having formula (1′) having a purity of at least about 95 mol % and containing less than about 5 mol % of a diorgano tin compound having formula (2′) and less than about 5 mol % of a compound having formula (5′): 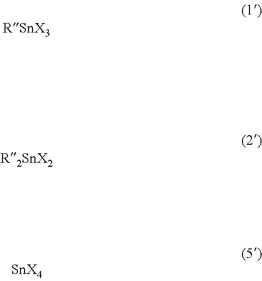
wherein R″ has formula [III], and X is selected from NR₂ and OR, wherein each R is independently a linear or branched alkyl group having about 1 to about 10 carbon atoms which is optionally substituted with one or more halogen atoms, the method comprising reacting a compound containing an R″ group with a compound having formula SnX₄;
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20.

17. A method of synthesizing a monoorgano tin compound having formula (1′) having a purity of at least about 95 mol % and containing less than about 5 mol % of a diorgano tin compound having formula (2′) and less than about 5 mol % of a compound having formula (5′): 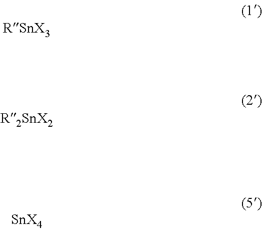
wherein R″ has formula [III], and X is selected from NR₂ and OR, wherein each R is independently a linear or branched alkyl group having about 1 to about 10 carbon atoms which is optionally substituted with one or more halogen atoms, the method comprising reacting a compound containing an OR or NR₂ group with a compound having formula R″SnY₃, where Y is a reactive ligand;
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20.

18. A method of synthesizing a monoorgano tin compound having formula (1′) having a purity of at least about 95 mol % and containing less than about 5 mol % of a diorgano tin compound having formula (2′) and less than about 5 mol % of a compound having formula (5′): 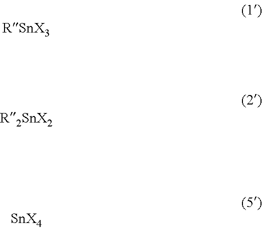
wherein R″ has formula [III], and X is selected from NR₂ and OR, wherein each R is independently a linear or branched alkyl group having about 1 to about 10 carbon atoms which is optionally substituted with one or more halogen atoms, the method comprising: (a) reacting a metal compound comprising an alkali metal M and a ligand X with a compound having formula SnY₂ to form a compound having formula MSnX₃; and (b) reacting the compound having formula MSnX₃ with a compound R″Z, wherein Z is a halogen atom and Y is a reactive ligand;
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″ is about 2 to about 20.

19. A method of storing a sample of the monoorgano tin compound having formula (1) according to claim 1, the method comprising storing the sample of the monoorgano tin compound having formula (1) substantively without light exposure and at a temperature of less than about 30° C.

20. (canceled)

21. The method according to claim 19, comprising storing the compound having formula (1) in a container in an inert atmosphere.

22. An organotin compound having formula (6): 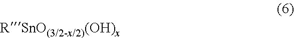
wherein 0<x≤3 and R″′ has formula [I], [II], or [III],
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage;
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″′ is about 2 to about 20.

23. A solution comprising the organotin compound having formula (6) according to claim 22 and an organic solvent.

24. A film comprising the organotin compound having formula (6) according to claim 22.

25. A composition comprising the monoorgano tin compound having formula (1) according to claim 1, and a R^{iv}SnY₃ compound, wherein Y is a reactive ligand selected from a halogen atom, NR₂, and OR and R^{iv} is an optionally substituted hydrocarbon group having about 2 to 20 carbon atoms which is different from R′.

26. (canceled)

27. A composition comprising iPrSn(NMe₂)₃ and R″SnX₃, wherein R″ is a 1-methyl-1-cyclopentyl group and X is a t-butoxy group or a dimethylamino group.

28. A composition comprising an organotin compound having formula (6) and an organotin compound having formula (7): 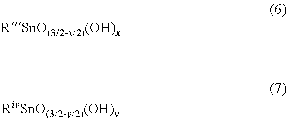
wherein 0<x≤3, 0<y≤3, wherein R″′ has formula [I], [II], or [III] and R^{iv} is an optionally substituted hydrocarbon group having about 2 to 20 carbon atoms which is different from R″′;
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage;
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″′ is about 2 to about 20.

29. A solution comprising the composition according to claim 25 and an organic solvent.

30. A film comprising the composition according to claim 25.

31. A method for producing a monoalkyltin triamide having formula (11) by reacting an alkylmagnesium reagent having formula (8) or (9) with a tin tetraamide having formula (10) in the presence of a first solvent containing an ether solvent having a boiling point of at least 40° C., comprising a step of distilling off the ether solvent in the presence of a second solvent having an octanol/water partition coefficient greater than the ether solvent and greater than 1.0; 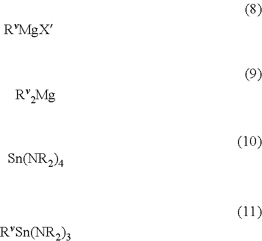
wherein R is a linear, branched, or cyclic hydrocarbyl group having 1 to 30 carbon atoms which may contain oxygen atoms, nitrogen atoms, silicon atoms, or sulfur atoms, each R is an alkyl group having 1 to 10 carbon atoms which may contain halogen atoms and multiple R groups may be bonded to each other to form a cyclic structure, and X′ is chlorine, bromine, or iodine.

32. The method for producing a monoalkyl tin triamide (11) according to claim 31, further comprising removing magnesium salts by filtration from a reaction mixture produced by reacting the alkyl magnesium reagent with the tin tetraamide.

33. The method for producing monoalkyl tin triamide (11) according to claim 31, wherein the second solvent has a boiling point higher than the boiling point of the ether solvent by 10° C. or higher.

34. The method for producing a monoalkyl tin triamide (11) according to claim 31, wherein R is a tertiary hydrocarbon group.

35. The method for producing a monoalkyl tin triamide (11) according to claim 31, wherein R has a cyclic structure.

36. The method for producing a monoalkyl tin triamide (11) according to claim 35, wherein R is a 1-alkyl-1-cycloalkyl group.

37. A method for a producing monoorgano tin trialkoxide compound having formula (1″′), comprising:
i) reacting a tetraalkynyl tin compound having formula (14) with a magnesium reagent having formula (8′); and
ii) reacting the product of step i) with an alcohol having formula (15): 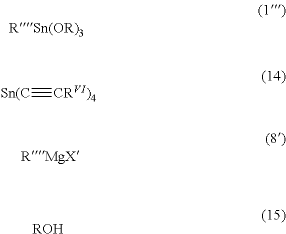
wherein each R is each independently a linear or branched alkyl group having about 1 to about 10 carbon atoms and each R^{VI} is independently a linear or branched alkyl group having about 1 to about 10 carbon atoms, or an aryl group having about 6 to 10 carbon atoms, X′ is chlorine, bromine, or iodine, and R″″ is a hydrocarbon group having about 1 to 30 carbon atoms which may contain one or more, oxygen atoms, nitrogen atoms, silicon atoms, or sulfur atoms.

38. The method for producing a monoorgano tin trialkoxide compound according to claim 37, wherein R^{VI} is a tertiary alkyl group.

39. The method for producing a monoorgano tin trialkoxide compound according to claim 37, wherein R is a primary alkyl group.

40. The method for producing a monoorgano tin trialkoxide compounds according to claim 37, wherein R″″ has formula [I], [II], or [III]:
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″″ is about 2 to about 20.

41. A method for producing a monoorgano tin triamide compounds having formula (1″), comprising, producing a monoorgano tin trialkoxide compound having formula (1″′) according to claim 37, and
(iii) reacting the monoorgano tin trialkoxide compound having formula (1″′) with a lithium amide having formula (16) or a (N,N-dialkylamino)trialkylsilane having formula (19):

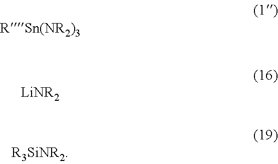

42. A method for producing a monoorgano tin trialkoxide compound having formula (1″′), comprising:
i) reacting a bis[bis(trialkylsilylamino)]tin(II) compound having formula (17) with a hydrocarbyl halide compound having formula (18); and
ii) reacting the product of step i) with an alkali metal alkoxide having formula (15′) and an alcohol having formula (15): 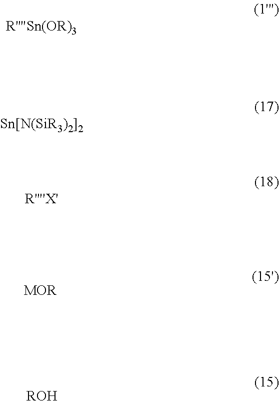
wherein each R is independently a linear or branched alkyl group having about 1 to about 10 carbon atoms, X′ is chlorine, bromine, or iodine, M is an alkali metal, and R″″ is a hydrocarbon group having about 1 to 30 carbon atoms which may contain one or more oxygen atoms, nitrogen atoms, silicon atoms, or sulfur atoms.

43. The method for producing monoorgano tin trialkoxide compounds according to claim 42, wherein R is a primary alkyl group.

44. The method for producing monoorgano tin trialkoxide compounds according to claim 42, wherein R″″ has formula [I], [II], or [III].
[I] CRaRbRc, wherein Ra is an aromatic ring having about 3 to about 10 carbon atoms which is optionally substituted with one or more oxygen, nitrogen, and/or halogen atoms, Rb and Rc are each independently hydrogen or a hydrocarbyl substituent having about 1 to about 10 carbon atoms, wherein each hydrocarbyl substituent is optionally substituted with one or more oxygen, nitrogen, and/or halogen atoms;
[II] CR^{A}R^{B}R^{C}, wherein R^{A} is (CH₂)ₙOR^{E}, n is 0, 1, or 2, R^{E} is a saturated hydrocarbon group having 1 to about 10 carbon atoms, R^{B} and R^{C} are each independently hydrogen or a saturated hydrocarbon group having about 1 to about 10 carbon atoms, wherein R′ contains about 2 to about 20 carbon atoms, wherein R^{A} and one of R^{B} and R^{C} optionally form a 3 to 8-membered ring containing an ether linkage.
[III] a 3 to 5-membered optionally substituted cyclic hydrocarbon or an optionally substituted 3 to 5-membered heterocyclic hydrocarbon ring containing at least one Sulfur, oxygen, or nitrogen atom, wherein a total number of carbon atoms in R″″ is about 2 to about 20.

45. A method for producing a monoorgano tin triamide compounds having formula (1″), comprising, producing a monoorgano tin trialkoxide compound having formula (1″′) according to claim 42, and
(iii) reacting the monoorgano tin trialkoxide compound having formula (1″′) with a lithium amide having formula (16) or a (N,N-dialkylamino)trialkylsilane having formula (19): [chemical structure]
